(19) United States
(12) Patent Application Publication
(10) Pub. No.: US 2022/0326526 A1
(43) Pub. Date: Oct. 13, 2022

(54) IMAGE DISPLAY APPARATUS, HEAD-MOUNTED DISPLAY, IMAGE DISPLAY SYSTEM, AND PATTERNED POLARIZER

(71) Applicant: FUJIFILM Corporation, Tokyo (JP)

(72) Inventors: Makoto KAMO, Kanagawa (JP); Mayumi NOJIRI, Kanagawa (JP); Yukito SAITOH, Kanagawa (JP)

(73) Assignee: FUJIFILM Corporation, Tokyo (JP)

(21) Appl. No.: 17/708,606

(22) Filed: Mar. 30, 2022

(30) Foreign Application Priority Data
Apr. 9, 2021 (JP) 2021-066757
Nov. 30, 2021 (JP) 2021-194536
Feb. 8, 2022 (JP) 2022-017879

(51) Int. Cl. G02B 27/01; G02B 5/30; H01L 51/52; G06V 40/13; G06V 10/14

(52) U.S. Cl. CPC G02B 27/0172; G02B 5/3016; G02B 27/0179; H01L 51/5281; G06V 40/1318; G06V 10/14; G02B 2027/0187

(57) ABSTRACT

Provided are an image display apparatus; an image display system; a head-mounted display, and a patterned polarizer. The image display apparatus includes a light receiving section having sensitivity in an invisible range; an image display panel having a substrate and a plurality of pixels disposed thereon; and an emission surface that emits a luminous flux in a visible range, in which the light receiving section receives only invisible light in light incident into the image display apparatus through the emission surface, and is provided between the emission surface and the image display panel, on the image display panel, or on a side of the image display panel opposite the emission surface, and disposed at a position overlapping the image display panel viewed from a direction perpendicular to the emission surface, and a near infrared polarizer is provided between the light receiving section and the emission surface.

### CROSS-REFERENCE TO RELATED APPLICATIONS

This application claims priority under 35 U.S.C. § 119(a) to Japanese Patent Application No. 2021-066757, filed on Apr. 9, 2021, Japanese Patent Application No. 2021-194536, filed on Nov. 30, 2021, and, Japanese Patent Application No. 2022-017879, filed on Feb. 8, 2022. Each of the above applications is hereby expressly incorporated by reference, in its entirety, into the present application.

### BACKGROUND OF THE INVENTION

### 1. Field of the Invention

The present invention relates to an image display apparatus, a head-mounted display, an image display system, and a patterned polarizer. In addition, the present invention further relates to a patterned polarizer used for the display device.

### 2. Description of the Related Art

An image display apparatus that observes a state of an object using an optical action is disclosed.

Examples of the sensor system include a sensor (JP2010-525394A) for example, for, for example, detecting an object and measuring the distance to an object and a sensor (for example, Patent Document 2) for, for example, measuring a surface state or an internal state of an object by detecting reflected light or transmitted light.

Information obtained from the sensor is provided to a user in a state where it is calculated in the device. Therefore, the sensor system is used as a subsystem configuring a security system for allowing the device itself to control the state of the device or giving various authorities to a user using a measurement target as an authentication key. In addition, as the fifth generation mobile communication system (5G) is widely used, information acquired by the device is instantly shared via a network and is used for providing various services.

The device with a sensor is mounted on various apparatuses including a portable device such as a smartphone, a smart watch, or smart glasses, a stationary device such as a television or a smart speaker, an automobile, a drone, a building, or a transportation infrastructure.

### SUMMARY OF THE INVENTION

Incidentally, in the portable device or the stationary device or the in-vehicle device mainly for an indoor environment, there is a restriction on a space assigned to the image display apparatus due to the weight, the size, or the design. In a device where a large space is required for a light emitting system such as a display system or a lighting system, the restriction is particularly severe.

On the other hand, in order to increase the detection accuracy or the amount of information acquired in the image display apparatus, it is desirable that, in particular, the system portion relating to the optical action is separated from another optical system to reduce noise, and a sufficient space is ensured, and an optical system having high accuracy is mounted. The restriction on the space and the requirement for the detection accuracy or the amount of information acquired are contradictory to each other and are difficult to achieve simultaneously.

An object of the present invention is to solve the above-described problem of the related art and to provide: an image display apparatus where the detection accuracy and the amount of information acquired are excellent using an optical action while a structure thereof has a small weight or size and is suitable for a design; a head-mounted display; and an image display system. In addition, another object of the present invention is to provide a patterned polarizer that contributes to the provision of the image display apparatus.

In order to achieve the object, the present invention has the following configurations.

[1] An image display apparatus comprising:

a light receiving section having sensitivity in an invisible range;

an image display panel that includes a substrate and a plurality of pixels disposed on the substrate; and

an emission surface that emits a luminous flux in a visible range formed from the plurality of pixels,

in which the light receiving section receives only invisible light in light incident into the image display apparatus through the emission surface,

the light receiving section is provided between the emission surface and the image display panel, on the image display panel, or on a side of the image display panel opposite to the emission surface,

the light receiving section is disposed at a position overlapping the image display panel in a view from a direction perpendicular to the emission surface, and

a near infrared polarizer having polarization selectivity in a near infrared range is provided between the light receiving section and the emission surface.

[2] The image display apparatus according to [1],

in which the light receiving section has sensitivity in a near infrared range.

[3] The image display apparatus according to [1] or [2],

in which the light receiving section receives invisible light reflected from a detection target, and

as the target detected by the light receiving section, the light receiving section detects a three-dimensional shape of an object, a surface state of the object, and at least one selected from an eye movement, an eye position, a facial expression, a face shape, a vein pattern, a blood flow, a pulse, a blood oxygen saturation level, a fingerprint, or an iris of a user.

[4] The image display apparatus according to any one of [1] to [3],

in which in the near infrared polarizer having polarization selectivity in a near infrared range, a single plate transmittance at a wavelength of 850 nm is less than 55%.

[5] A head-mounted display comprising:

the image display apparatus according to any one of [1] to [4];

an eyepiece that is disposed between the image display apparatus and an eyeball of an observer;

a light source that is capable of emitting near infrared light to the eyeball; and

an eye tracking system that detects reflected light obtained by causing the near infrared light emitted from the light source to be reflected from the eyeball using the light receiving section through the near infrared polarizer.

[6] The head-mounted display according to [5],

in which the eyepiece has near infrared transmittance.

[7] The head-mounted display according to [5] or [6],

in which the eyepiece includes a half mirror having near infrared transmittance and a reflective polarizer having near infrared transmittance.

[8] The head-mounted display according to any one of [5] to [7], further comprising:

a visible light polarizer that has a polarization property in visible light and is provided between the eyepiece and the plurality of pixels of the image display apparatus,

in which the visible light polarizer has transmittance in a near infrared range.

[9] The head-mounted display according to any one of [5] to [8],

in which the near infrared polarizer does not have a polarization property in a visible range or has transmittance in a visible range.

[10] The head-mounted display according to any one of [5] to [8],

in which the near infrared polarizer is a patterned polarizer including a near infrared polarizer region having polarization selectivity to near infrared light and a visible light linear polarizer region having polarization selectivity to visible light in the same plane.

[11] The head-mounted display according to [9],

in which in the near infrared polarizer region having polarization selectivity to near infrared light, a single plate transmittance at a wavelength of 850 nm is less than 55%.

[12] An image display system comprising:

the image display apparatus according to any one of [1] to [4];

a light source that is capable of emitting near infrared light to a face of a user; and

a face recognition system or a facial expression recognition system that detects reflected light obtained by causing the near infrared light emitted from the light source to be reflected from a face of an observer using the light receiving section through the near infrared polarizer.

[13] The image display system according to [12],

in which the image display panel includes an OLED display panel and a light emitting panel selected from a LED array, a micro LED panel, or a mini LED panel,

the image display apparatus includes a circular polarization plate that is provided on the emission surface to reduce external light reflection,

the circular polarization plate is a laminate in which a visible light polarizer and a retardation plate are laminated, and

the image display apparatus includes the visible light polarizer, the retardation plate, and the substrate in this order from the emission surface to the substrate.

[14] The image display system according to [13],

in which the near infrared polarizer is provided between the visible light polarizer and the retardation plate,

the near infrared polarizer has transmittance in a visible range, and

a laminate including the retardation plate and the near infrared polarizer has an action of a ¼ wave plate with respect to light having a wavelength of 550 nm.

[15] The image display system according to [14],

in which a transmission axis of the near infrared polarizer is disposed parallel to or perpendicular to a transmission axis of the visible light polarizer, or

the transmission axis of the near infrared polarizer is disposed at 45′ or 135° with respect to the transmission axis of the visible light polarizer and a phase difference Re(550) of the near infrared polarizer in a visible range is ½ wavelength.

[16] The image display system according to [14],

in which a transmission axis of the near infrared polarizer is at 75°±10° with respect to a transmission axis of the visible light polarizer and a phase difference Re(550) of the near infrared polarizer in a visible range is in a range from 180 nm to 360 nm, and

a slow axis of the retardation plate is at 15°±10° with respect to a transmission axis of the visible light polarizer and a phase difference Re(550) of the retardation plate is in a range from 115 nm to 155 nm.

[17] The image display system according to [13],

in which the visible light polarizer, the retardation plate, and the near infrared polarizer are provided in this order,

the near infrared polarizer has transmittance in a visible range,

a slow axis of the retardation plate is at 75°±10° with respect to a transmission axis of the visible light polarizer,

a phase difference Re(550) of the retardation plate is in a range from 180 nm to 360 nm,

a slow axis of the near infrared polarizer is at 15°±10° with respect to the transmission axis of the visible light polarizer, and

a phase difference Re(550) of the near infrared polarizer in a visible range is in a range from 115 nm to 155 nm.

[18] An image display system comprising:

the image display apparatus according to any one of [1] to [4];

a light source that is capable of emitting near infrared light to a measurement target; and

a distance measurement system or an object recognition system that detects reflected light obtained by causing the near infrared light emitted from the light source to be reflected from the measurement target using the light receiving section through the near infrared polarizer.

[19] The image display system according to [18],

in which the image display panel includes an OLED display panel and a light emitting panel selected from a LED array, a micro LED panel, or a mini LED panel,

the image display apparatus includes a circular polarization plate that is provided on the emission surface to reduce external light reflection,

the circular polarization plate is a laminate in which a visible light polarizer and a retardation plate are laminated, and

the image display apparatus includes the visible light polarizer, the retardation plate, and the substrate in this order from the emission surface to the substrate.

[20] The image display system according to [19],

in which the near infrared polarizer is provided between the visible light polarizer and the retardation plate,

the near infrared polarizer has transmittance in a visible range, and

a laminate including the retardation plate and the near infrared polarizer has an action of a ¼ wave plate with respect to light having a wavelength of 550 nm.

[21] The image display system according to [20],

in which a transmission axis of the near infrared polarizer is disposed parallel to or perpendicular to a transmission axis of the visible light polarizer, or

the transmission axis of the near infrared polarizer is disposed at 45° or 135° with respect to the transmission axis of the visible light polarizer and a phase difference Re(550) of the near infrared polarizer in a visible range is ½ wavelength.

[22] An image display system comprising:

the image display apparatus according to any one of [1] to [4];

a light source that is capable of emitting near infrared light to a portion of a biological body selected from a hand, a finger, a palm, or a skin; and

a fingerprint recognition system, a vein recognition system, or a biometric system that detects reflected light obtained by causing the near infrared light emitted from the light source to be reflected from the portion of the biological body selected from a hand, a finger, a palm, or a skin using the light receiving section through the near infrared polarizer.

[23] The image display system according to [22], further comprising:

a light guide plate that guides the near infrared light emitted from the light source; and

a fingerprint recognition system that detects the scattered near infrared light obtained by causing the near infrared light propagating in the light guide plate to be scattered from an interface between a finger and the light guide plate using the light receiving section.

[24] The image display system according to [22], further comprising:

a light guide plate that guides the near infrared light emitted from the light source,

wherein the light guide plate is provided with a scattering layer or a diffraction function layer and includes a vein recognition system or a biometric system that emits a part of the guided near infrared light from the emission surface to a measurement target and receives reflected light from the measurement target using the light receiving section.

[25] An image display system comprising:

a light receiving section having sensitivity in an invisible range; and

an image display apparatus including an image display panel and an emission surface, the image display panel including a substrate and a plurality of pixels, and the emission surface emitting a luminous flux formed from the plurality of pixels,

in which the plurality of pixels include a pixel group that forms a luminous flux in a visible range and a pixel that forms a luminous flux in an invisible range to which the light receiving section has sensitivity,

the plurality of pixels are disposed at positions overlapping the substrate in a view from a direction perpendicular to the emission surface,

the light receiving section is disposed to receive the invisible light that is emitted from the pixel forming the luminous flux in an invisible range to a detection target through the emission surface and is reflected or scattered from the target, and receives only the luminous flux in an invisible range, and

the image display apparatus includes a near infrared polarizer having polarization selectivity in a near infrared range that is provided between the pixel forming the luminous flux in an invisible range and the emission surface.

[26] The image display system according to [25],

in which the light receiving section has sensitivity in a near infrared range.

[27] The image display system according to [25] or [26],

in which the light receiving section receives invisible light reflected from a detection target, and

as the target detected by the light receiving section, the light receiving section detects a three-dimensional shape of an object, a surface state of the object, and at least one selected from an eye movement, an eye position, a facial expression, a face shape, a vein pattern, a blood flow, a pulse, a blood oxygen saturation level, a fingerprint, or an iris of a user.

[28] The image display system according to any one of [25] to [27],

in which in the near infrared polarizer having polarization selectivity in a near infrared range, a single plate transmittance at a wavelength of 850 nm is less than 55%.

[29] The image display system according to any one of [25] to [28],

in which the near infrared polarizer does not have a polarization property in a visible range or has transmittance in a visible range.

[30] A head-mounted display comprising:

the image display system according to any one of [25] to [29];

an eyepiece; and

an eye tracking system that detects near infrared light emitted from the image display apparatus an eyeball of an observer and reflected from the eyeball using the light receiving section.

[31] The head-mounted display according to [30],

in which the eyepiece includes a half mirror and a reflective polarizer.

[32] The head-mounted display according to [31],

in which a single plate transmittance of each of the reflective polarizer and the half mirror at 850 nm is 80% or more.

[33] The head-mounted display according to any one of [30] to [32], further comprising:

a near infrared polarizer that is provided on an eyeball side surface of the eyepiece,

wherein a single plate transmittance of the near infrared polarizer at 850 nm is less than 55%.

[34] The image display system according to any one of [25] to [29], further comprising:

a face recognition system or a facial expression recognition system that detects reflected light obtained by causing a luminous flux in a near infrared range emitted from the image display apparatus to be reflected from a face of a user using the light receiving section.

[35] The image display system according to any one of [25] to [29] and [34],

in which the image display apparatus includes the near infrared polarizer, a visible light polarizer, and a retardation plate as a ¼ wave plate having a slow axis that is 45° or 135° with respect to a transmission axis of the visible light polarizer in this order from the emission surface to the substrate.

[36] The image display system according to [35],

in which the near infrared polarizer is a patterned polarizer where regions having different transmission axes are distributed in a patterned manner.

[37] The image display system according to any one of [25] to [29], further comprising:

a light detection and ranging system or an object recognition system that detects reflected light obtained by causing invisible light emitted from the image display apparatus to be reflected from a measurement target using the light receiving section.

[38] The image display system according to [37],

in which the image display apparatus includes the near infrared polarizer, a visible light polarizer, and a retardation plate as a ¼ wave plate having a slow axis that is 45° or 135° with respect to a transmission axis of the visible light polarizer in this order from the emission surface to the substrate.

[39] The image display system according to [38],

in which the near infrared polarizer is a patterned polarizer where regions having different transmission axes are distributed in a patterned manner.

[40] A head-mounted display comprising:

the image display system according to any one of [25] to [29],

in which the image display apparatus includes a light guide element and emits the luminous flux in a visible range and the luminous flux in an invisible range emitted from the image display panel to an observer from an emission surface provided in the light guide element through the light guide element, and

eyeball sensing is performed by detecting near infrared light emitted from the image display apparatus to an eyeball of the observer and reflected from the eyeball of the observer using the light receiving section.

[41] The head-mounted display according to [40], further comprising:

near infrared polarizers that are provided between the emission surface of the light guide element and the eyeball of the observer and between the light receiving section and the eyeball of the observer, respectively.

[42] The head-mounted display according to [41],

in which in the near infrared polarizer that is provided between the emission surface of the light guide element and the eyeball of the observer among the near infrared polarizers, an average transmittance of the near infrared polarizer in a visible range is 90% or more.

[43] The head-mounted display according to claim [41] or [42],

in which in the near infrared polarizer that is provided between the emission surface of the light guide element and the eyeball of the observer among the near infrared polarizers, a polarization degree of the near infrared polarizer at 850 nm is 90% or more.

[44] The head-mounted display according to any one of [41] to [43],

in which in the near infrared polarizer that is provided between the light receiving section and the eyeball of the observer among the near infrared polarizers, a polarization degree of the near infrared polarizer at 850 nm is 90% or more.

[45] The head-mounted display according to any one of [41] to [44],

in which in a case where an eyeball surface is a reflecting surface, the near infrared polarizer provided between the emission surface of the light guide element and the eyeball of the observer and the near infrared polarizer provided between the light receiving section and the eyeball of the observer are disposed in a crossed nicols relationship.

[46] An image display apparatus comprising:

a light receiving section having sensitivity in an invisible range;

an image display panel including a substrate and a plurality of pixels; and

an emission surface that emits a luminous flux in a visible range formed from the plurality of pixels,

in which the light receiving section is provided between the emission surface and the image display panel, on the image display panel, or on a side of the image display panel opposite to the emission surface,

the plurality of pixels include a pixel group that forms a luminous flux in a visible range and a pixel that forms a luminous flux in an invisible range to which the light receiving section has sensitivity,

the light receiving section is disposed at a position overlapping the image display panel in a view from a direction perpendicular to the emission surface,

the light receiving section receives only invisible light in light incident into the image display apparatus through the emission surface, and

a near infrared polarizer having polarization selectivity in a near infrared range is provided between the pixel forming the luminous flux in an invisible range and the emission surface.

[47] The image display apparatus according to [46],

in which the pixel that forms the luminous flux of invisible light has an emission band in near infrared light,

the light receiving section has sensitivity to near infrared light, and

the pixel group that forms the luminous flux of visible light performs image display.

[48] The image display apparatus according to [46] or [47],

in which a single plate transmittance of the near infrared polarizer at 850 nm is less than 55%.

[49] The image display apparatus according to any one of [46] to [48],

in which the near infrared polarizer does not have a polarization property in a visible range or has transmittance in a visible range.

[50] A head-mounted display comprising:

the image display apparatus according to any one of [46] to [49]; and

an eyepiece,

in which eye tracking is performed by performing emission of near infrared light to an eyeball and detection of the near infrared light using the image display apparatus.

[51] The head-mounted display according to [50],

in which the near infrared polarizer is a patterned polarizer where regions having different transmission axes or different types of polarization selectivity for corresponding pixels are disposed in a patterned manner.

[52] The head-mounted display according to [50] or [51],

in which the eyepiece includes a half mirror and a reflective polarizer.

[53] The head-mounted display according to [52],

in which the reflective polarizer and the half mirror have transmittance in a near infrared range, and

a single plate transmittance of each of the reflective polarizer and the half mirror at 850 nm is 80% or more.

[54] The image display apparatus according to any one of [46] to [49], which is used as a face recognition system or a facial expression recognition system that detects reflected light obtained by causing the invisible light emitted from the pixel forming the luminous flux of invisible light to be reflected from a user a face of a user using the light receiving section.

[55] The image display apparatus according to [54],

in which the near infrared polarizer is a patterned polarizer where regions having different transmission axes are distributed in a patterned manner.

[56] The image display apparatus according to any one of [46] to [49], further comprising:

a light detection and ranging system or an object recognition system that detects reflected light obtained by causing invisible light emitted from the image display apparatus to be reflected from a measurement target using the light receiving section.

[57] The image display apparatus according to [56],

in which a patterned polarizer where regions having different transmission axes are distributed in a patterned manner is provided as the near infrared polarizer.

[58] The image display apparatus according to any one of [46] to [49], which is used as any one of a fingerprint sensor, a vein recognition system, or a blood flow sensor that detects light obtained by causing the invisible light emitted from the image display apparatus to transmit through or to be reflected from a portion of a biological body of a user selected from a hand, a finger, a palm, or a skin using the light receiving section through the near infrared polarizer.

[59] The image display apparatus according to [58],

in which the near infrared polarizer is a patterned polarizer including a plurality of regions having different types of polarization selectivity in a patterned manner.

[60] A patterned polarizer comprising:

a layer having polarization selectivity to light in a near infrared range,

in which the layer includes at least a region having polarization selectivity in a near infrared range, and

the layer includes a plurality of regions having different types of polarization selectivity in a near infrared range in a patterned manner in a plane.

[61] The patterned polarizer according to [60],

in which the patterned polarizer has a structure selected from at least one of

a patterned polarizer where a first region having a first polarization selectivity and a second region not having polarization selectivity that is provided to be surrounded by the region having the first polarization selectivity are provided in a plane of the layer having polarization selectivity or

a patterned polarizer where a first region having at least a first polarization selectivity and a second region having a second polarization selectivity are provided in a plane of the layer having polarization selectivity.

[62] The patterned polarizer according to [60] or [61],

in which in the region having polarization selectivity, a single plate transmittance at a wavelength of 850 nm is less than 50%.

[63] The patterned polarizer according to any one of [60] to [62],

in which a thickness of the layer having polarization selectivity in a near infrared range is 0.1 μm to 5 μm.

[64] The patterned polarizer according to any one of [60] to [63],

in which the layer having polarization selectivity in a near infrared range is obtained by dissolving or dispersing a dichroic dye having absorption in a near infrared range in a liquid crystal composition to form an alignment state and immobilizing the alignment state.

According to an aspect of the present invention, it is possible to provide an image display apparatus that uses an optical action, is space-saving, and has high detection sensitivity, a head-mounted display, and an image display system. In addition, it is possible to provide a patterned polarizer that contributes to the provision of the image display apparatus.

### BRIEF DESCRIPTION OF THE DRAWINGS

FIG. 1 is a conceptual diagram showing one example of a first embodiment of the present invention.

FIG. 2 is a conceptual diagram showing another example of the first embodiment of the present invention.

FIG. 3 is a conceptual diagram showing still another example of the first embodiment of the present invention.

FIG. 4 is a diagram showing a specific example of a display device relating to the first embodiment of the present invention.

FIG. 5 is a top view showing the display device of FIG. 4.

FIG. 6 is a diagram showing a specific example of another display device relating to the first embodiment of the present invention.

FIG. 7 is a diagram showing a specific example of still another display device relating to the first embodiment of the present invention.

FIG. 8 is a conceptual diagram showing an effect relating to the first embodiment of the present invention.

FIG. 9 is a conceptual diagram showing a head-mounted display that is one example of the first embodiment of the present invention.

FIG. 10 is a conceptual diagram showing a head-mounted display that is one example of the first embodiment of the present invention.

FIG. 11 is a conceptual diagram showing the optical system in the head-mounted display that is one example of the first embodiment of the present invention.

FIG. 12a is a conceptual diagram showing an optical system in a head-mounted display that is one example of the first embodiment of the present invention.

FIG. 12b is a conceptual diagram showing the optical system in the head-mounted display that is one example of the first embodiment of the present invention.

FIG. 12c is a conceptual diagram showing the optical system in the head-mounted display that is one example of the first embodiment of the present invention.

FIG. 13 is a conceptual diagram showing another optical system in the head-mounted display that is one example of the first embodiment of the present invention.

FIG. 14 is a conceptual diagram showing an image display system including a face recognition system or a facial expression recognition system that is one example of the first embodiment of the present invention.

FIG. 15 is a conceptual diagram showing an image display system including a face recognition system or a facial expression recognition system that is one example of the first embodiment of the present invention.

FIG. 16 is a conceptual diagram showing an image display system including a face recognition system or a facial expression recognition system that is one example of the first embodiment of the present invention.

FIG. 17 is a conceptual diagram showing an image display system including a face recognition system or a facial expression recognition system that is one example of the first embodiment of the present invention.

FIG. 18 is a conceptual diagram showing an image display system including a LIDAR system or an object recognition system that is one example of the first embodiment of the present invention.

FIG. 19 is a conceptual diagram showing an operation of the LIDAR system or the object recognition system that is one example of the first embodiment of the present invention.

FIG. 20 is a conceptual diagram showing an image display system including a fingerprint sensor, a vein recognition system, or a blood flow sensor that is one example of the first embodiment of the present invention.

FIG. 21 is a conceptual diagram showing an image display system including a fingerprint recognition system that is one example of the first embodiment of the present invention.

FIG. 22 is a conceptual diagram showing an image display system including a vein recognition system or a blood flow sensor that is one example of the first embodiment of the present invention.

FIG. 23 is a conceptual diagram showing a second embodiment of the present invention.

FIG. 24 is a conceptual diagram showing the second embodiment of the present invention.

FIG. 25 is a conceptual diagram showing the second embodiment of the present invention.

FIG. 26 is a diagram showing a specific example of an image display system relating to the second embodiment of the present invention.

FIG. 27 is a top view showing a display device in the image display system of FIG. 26.

FIG. 28 is a diagram showing a specific example of another image display system relating to the second embodiment of the present invention.

FIG. 29 is a conceptual diagram showing an action relating to the second embodiment of the present invention.

FIG. 30 is a conceptual diagram showing a head-mounted display that is one example of the second embodiment of the present invention.

FIG. 31 is a conceptual diagram showing a head-mounted display in another aspect that is one example of the second embodiment of the present invention.

FIG. 32 is a conceptual diagram showing an image display system including a face recognition system or a facial expression recognition system that is one example of the second embodiment of the present invention.

FIG. 33 is a conceptual diagram showing an image display system including a face recognition system or a facial expression recognition system that is one example of the second embodiment of the present invention.

FIG. 34 is another conceptual diagram showing the image display system including the face recognition system or the facial expression recognition system that is one example of the second embodiment of the present invention.

FIG. 35 is a conceptual diagram showing an image display system including a LIDAR system or an object recognition system that is one example of the second embodiment of the present invention.

FIG. 36 is a conceptual diagram showing a third embodiment of the present invention.

FIG. 37 is a conceptual diagram showing the third embodiment of the present invention.

FIG. 38 is a conceptual diagram showing the third embodiment of the present invention.

FIG. 39 is a diagram showing a specific example of a display device relating to the third embodiment of the present invention.

FIG. 40 is a conceptual diagram showing an action relating to the third embodiment of the present invention.

FIG. 41 is a conceptual diagram showing a head-mounted display that is one example of the third embodiment of the present invention.

FIG. 42 is a conceptual diagram showing a head-mounted display in another aspect that is one example of the third embodiment of the present invention.

FIG. 43 is a conceptual diagram showing an image display system including a face recognition system or a facial expression recognition system that is one example of the third embodiment of the present invention.

FIG. 44 is a conceptual diagram showing an optical system of an image display system including a face recognition system or a facial expression recognition system that is one example of the third embodiment of the present invention.

FIG. 45 is a conceptual diagram showing an image display system including a LIDAR system or an object recognition system that is one example of the third embodiment of the present invention.

FIG. 46 is a conceptual diagram showing an image display system including a fingerprint sensor, a vein recognition system, or a blood flow sensor that is one example of the third embodiment of the present invention.

FIG. 47 is a conceptual diagram showing one preferable aspect of the head-mounted display including the image display apparatus according to the second embodiment of the present invention.

FIG. 48 is a conceptual diagram showing one preferable aspect of the head-mounted display including the image display apparatus according to the second embodiment of the present invention.

FIG. 49 is a conceptual diagram showing one preferable aspect of the head-mounted display including the image display apparatus according to the second embodiment of the present invention.

### DESCRIPTION OF THE PREFERRED EMBODIMENTS

Hereinafter, an image display apparatus, a head-mounted display, an image display system, and a patterned polarizer according to the present invention will be described in detail based on a preferable embodiment illustrated in the accompanying drawings.

In the present specification, numerical ranges represented by “to” include numerical values before and after “to” as lower limit values and upper limit values.

In the present specification, “(meth)acrylate” represents “either or both of acrylate and methacrylate”.

In the present specification, visible light refers to light which can be observed by human eyes among electromagnetic waves and refers to light in a wavelength range of 380 to 780 nm. Invisible light refers to light in a wavelength range of shorter than 380 nm and longer than 780 nm. In the invisible light, near infrared light refers to light in a wavelength range of longer than 780 nm and 2500 nm or shorter and will also be simply referred to as “infrared light” in the present specification.

In the present specification, Re(λ) represents an in-plane retardation at a wavelength λ. Unless specified otherwise, the wavelength λ refers to 550 nm.

In the present specification, Re(λ) is a value measured at the wavelength λ using AxoScan (manufactured by Axometrics, Inc.). By inputting an average refractive index ((nx+ny+nz)/3) and a film thickness (d (μm)) to AxoScan, the following expressions can be calculated.

Slow Axis Direction (°)

Re(%)=R0(λ) is calculated.

R0(λ) is expressed as a numerical value calculated by AxoScan and represents Re(λ).

In the present specification, P(λ) represents a polarization degree at the wavelength.

The polarization degree is calculated in the following way with respect to normal incidence light at the wavelength λ.

P(λ)=[(MD−TD)/(MD+TD)]×100

MD: a transmittance of a layer having polarization selectivity with respect to linearly polarized light in a direction perpendicular to a direction in which the transmission amount is the maximum

TD: a transmittance of the layer having polarization selectivity with respect to linearly polarized light in the direction in which the transmission amount is the maximum

The transmittance with respect to linearly polarized light can be measured by using the polarized light in the direction as measurement light in a spectrophotometer.

### First Embodiment

An image display apparatus according to a first embodiment of the present invention includes: a light receiving section having sensitivity in an invisible range; an image display panel that includes a substrate and a plurality of pixels disposed on the substrate; and an emission surface that emits a luminous flux in a visible range formed from the plurality of pixels, in which the light receiving section receives only invisible light in light incident into the image display apparatus through the emission surface, the light receiving section is provided between the emission surface and the image display panel, on the image display panel, or on a side of the image display panel opposite to the emission surface, the light receiving section is disposed at a position overlapping the image display panel in a view from a direction perpendicular to the emission surface, and a near infrared polarizer having polarization selectivity in a near infrared range is provided between the light receiving section and the emission surface.

By using the external light source that emits invisible light in combination, the image display apparatus is used as an image display system including a sensor.

In the related art, in general, an emission region where visible light is emitted and a light receiving section for sensing are separately provided. However, in order to simultaneously achieve a reduction in the size of the device and extension of the emission region (that may be reworded with a display region, in particular, in a display device), a region other than the emission region needs to be minimized, which causes deterioration in detection accuracy or a decrease in amount of information acquired along with a decrease in the size of the image display apparatus.

Specifically, for example, in a head-mounted display, in a case where the image display apparatus emits invisible light to an eye of a user, receives reflected light from the eye of the user using the light receiving section, and detects a direction or the like in which the eye of the user is looking, in a case where the light receiving section is disposed on the outside (the outside in the plane direction) of a display surface of the image display apparatus, the display surface of the image display apparatus is disposed in front of the eye of the user. Therefore, the reflected light from the eye of the user is incident into the light receiving section from an oblique direction. In a case where the reflected light from the eye of the user is incident into the light receiving section from an oblique direction, the detection accuracy and the amount of information acquired may decrease.

On the other hand, by applying the image display apparatus according to the embodiment of the present invention, the light receiving section can be provided in a sufficient area of the image display apparatus while minimizing a space other than the emission region. Therefore, a device (image display system) including the image display apparatus having excellent detection accuracy and amount of information acquired can be provided.

Specifically, the light receiving section is disposed at a position overlapping the image display panel in a view (that is, in the plane direction) from a direction perpendicular to the emission surface. Therefore, the reflected light from the eye of the user is incident into the light receiving section from a front direction, and thus the detection accuracy and the amount of information acquired can be improved.

Here, in a case where the light receiving section is disposed at a position overlapping the image display panel, the light receiving section receives visible light, and the detection accuracy may decrease. On the other hand, in the present invention, the light receiving section receives only invisible light and does not have sensitivity to visible light. Therefore, the detection accuracy and the amount of information acquired can be improved without detecting visible light.

In addition, the near infrared polarizer having polarization selectivity in a near infrared range is provided between the light receiving section and the emission surface. Therefore, a part of external near infrared light as a noise can be cut such that the ratio of the light reflected from the eye of the user can increase. Thus, the SN ratio can be improved, and the detection accuracy and the amount of information acquired can be improved without detecting visible light.

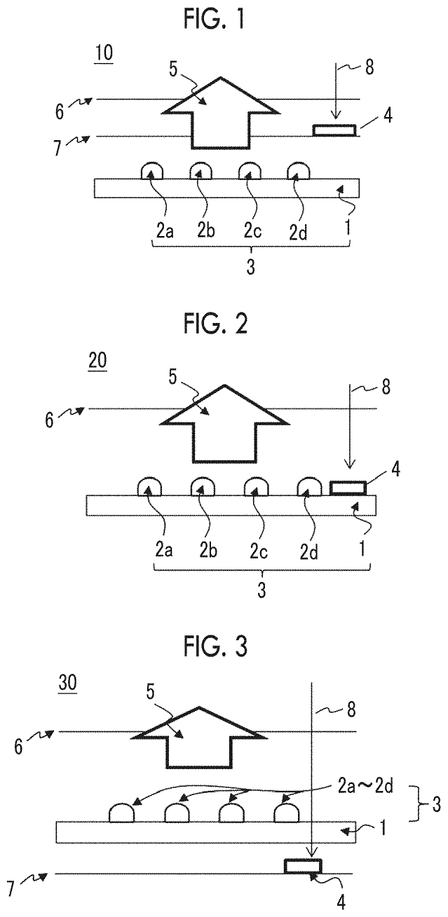

One preferable aspect of the first embodiment will be described using FIG. 1. An image display apparatus 10 includes: an image display panel 3 that includes a substrate 1 and a plurality of pixels 2a to 2d disposed on the substrate 1; and a light receiving section 4, in which a luminous flux 5 in a visible range is formed from the pixels 2a to 2d. The luminous flux 5 in a visible range is emitted from an emission surface 6 to be recognized as image light by a user or to irradiate an object.

Here, the light receiving section 4 having sensitivity only in an invisible range can be provided between the emission surface 6 and the image display panel 3. In addition, as shown in FIG. 1, the light receiving section 4 is disposed at a position overlapping the image display panel 3 in the plane direction. The light receiving section 4 may be provided on, for example, a substrate 7 having transmittance to the luminous flux 5. The light receiving section 4 receives and converts invisible light 8 incident from the outside into an electrical signal, and can output information detected through an arithmetic circuit (not shown).

In the image display apparatus 10 shown in FIG. 1, the near infrared polarizer is not shown. Regarding this point, the same can also be applied to FIGS. 2 and 3.

In addition, another preferable aspect of the first embodiment will be described using FIG. 2. The image display panel 3 and the emission surface 6 in an image display apparatus 20 are the same as those of FIG. 1. The light receiving section 4 having sensitivity in an invisible range is provided on the image display panel 3. “Being provided on the image display panel 3” described herein is not limited to being simply provided on the emission surface 6 side of the image display panel 3, and represents being integrated with the light emitting panel by being provided over or below an electrode layer, a passivation layer, an insulating layer, or the like provided in the light emitting panel.

Still another preferable aspect of the first embodiment will be described using FIG. 3. The image display panel 3 and the emission surface 6 in an image display apparatus 30 are the same as those of FIG. 1. The light receiving section 4 having sensitivity in an invisible range is provided on a surface of the image display panel 3 opposite to the emission surface 6. The light receiving section 4 may be provided on the substrate 7 that is provided separately from the image display panel 3, or may be provided adjacent to the surface of the image display panel 3 opposite to the emission surface 6 side.

Here, the substrate 1 of the image display panel 3 allows transmission of the invisible light 8 to which the light receiving section 4 has sensitivity. The transmission described herein may represent that invisible light as a target reaches the light receiving section 4 through a void or a pore provided in the substrate without being blocked. In addition, the substrate itself may have transmittance in a wavelength range of invisible light as a target.

In addition, as in the example shown in FIGS. 2 and 3, the light receiving section 4 is disposed at a position overlapping the image display panel 3 in the plane direction.

As the image display panel, a light emitting panel such as a light emitting diode (LED) array, an organic light emitting diode (OLED) display panel, a micro LED panel, or a mini LED panel can be applied. In addition, the image display panel may be a combination of a transmission type liquid crystal panel and a backlight unit.

The substrate in the image display panel is not particularly limited as long as the shape of the image display panel can be maintained and a transistor element, a light emitting layer, an electrode, a conductive layer, an insulating layer, a bank, a passivation layer, a smoothing layer, or the like forming the image display panel can be provided and maintained, and a sheet, a film, or the like formed of glass or a polymer material can be used. As the polymer material, a well-known material can be used, and examples thereof include polyester, polyimide, polyamide, cycloolefin, and an epoxy resin.

In the LED array, the OLED panel, the micro LED panel, the mini LED panel, or the like, the pixels provided on the substrate are light emitting elements. In the combination of the transmission type liquid crystal panel and the backlight unit, the pixels provided on the substrate are regions of the respective colors divided by a driving electrode and a color filter layer or a black matrix.

A luminous flux in a visible range is directly formed from the light emitting elements in the LED array, the OLED panel, the micro LED panel, the mini LED panel, or the like. In addition, in the combination of the transmission type liquid crystal panel and the backlight unit, a luminous flux formed in the backlight unit transmits through pixels of the transmission type liquid crystal panel to form a luminous flux in a visible range.

The luminous flux of visible light formed as described above is released to the outside of the image display apparatus through the emission surface. This emission surface is the outermost surface on the emission side of the image display apparatus, and may be, for example, a surface of a front protective plate of the image display apparatus, an outer surface of a color filter substrate, or a visible side surface of a visible-side polarizing plate. The luminous flux released to the outside of the system is used, for example, for illuminating an object and provides visual information to an observer. In one preferable aspect of the present invention, by displaying an image or information using the luminous flux in a visible range emitted from the image display panel, the image display apparatus according to the embodiment of the present invention can be constructed.

As the light receiving section, a photodetection element such as a photodiode or a phototransistor having sensitivity in an invisible range and not having sensitivity to visible light can be applied. It is preferable that the light receiving section is a photodiode or a phototransistor having sensitivity only in a near infrared range and not having sensitivity in a visible range. As the photodetection element, an organic photodiode (OPD) or an organic phototransistor (OPT) may be applied.

The light receiving section is provided between the emission surface and the image display panel, on the image display panel, or on a side of the image display panel opposite to the emission surface. In addition, as described above, the light receiving section is disposed at a position overlapping the image display panel in the plane direction. The light receiving section detects information regarding a target by receiving invisible light reflected from a detection target. As the target detected by the light receiving section, the light receiving section can detect a three-dimensional shape of an object, a surface state of the object, and at least one selected from an eye movement, an eye position, a facial expression, a face shape, a vein pattern, a blood flow, a pulse, a blood oxygen saturation level, a fingerprint, or an iris of a user. That is, the image display apparatus according to the embodiment of the present invention can detect or recognize a three-dimensional shape of an object, a surface state of the object, and an eye movement, an eye position, a facial expression, a face shape, a vein pattern, a blood flow, a pulse, a blood oxygen saturation level, a fingerprint, or an iris of a user.

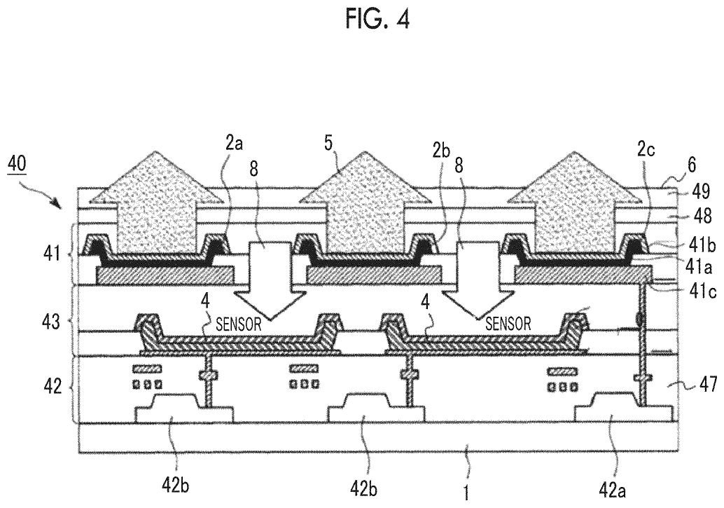

As one more specific example of the image display apparatus according to the first embodiment of the present invention, FIG. 4 shows an OLED display device 40 including a light emitting panel where pixels and a light receiving section are provided on a substrate.

The OLED display device 40 includes: a light emitting panel consisting of a driving unit 42, a sensor unit 43, and an OLED unit 41 that are provided on the substrate 1; and an interlayer 48 and a cover plate 49 that are optionally provided. In the configuration shown in FIG. 4, a surface of the cover plate 49 is the emission surface 6 of the luminous flux 5.

The driving unit 42 is formed on the substrate 1, and includes: a variety of transistor arrays (42a, 42b) for inputting and outputting electrical signals of the sensor unit 43 and the OLED unit 41 provided above the driving unit 42; and an interlayer insulating film 47 where a multilayer wiring layer is formed.

The transistor arrays and the multilayer wiring layer are generally formed of a metallic material or a semiconductor material. Therefore, it is preferable that the transistor arrays and the multilayer wiring layer are disposed on the substrate side so as not to interfere the incidence and emission of light into and from the sensor unit 43 and the OLED unit 41.

The sensor unit 43 includes an organic photodiode as the light receiving section 4, and this organic diode is driven by being connected to a wiring line drawn from the driving unit 42. Examples of a material of a light absorbing layer of the organic photodiode include squaraine materials, D-π-A materials, Bodipy materials, and phthalocyanine materials, and various appropriate materials for receiving light in a desired invisible range are used. As a substrate side electrode of the organic diode, a reflecting electrode may be used in order to improve the sensor sensitivity. As the material of the electrode, for example, the electrode on the substrate 1 side is formed of Al, Ag, Mo, AlNd, Mo/Al/Mo, TiN, ITO/Ag/ITO, ITO/Al/ITO, or ITO/Mo/ITO. From the viewpoint of ensuring transparency, the electrode on the emission surface 6 side is formed of ITO, IZO, AlZO, Ag nanowires, graphene, CNT, or the like.

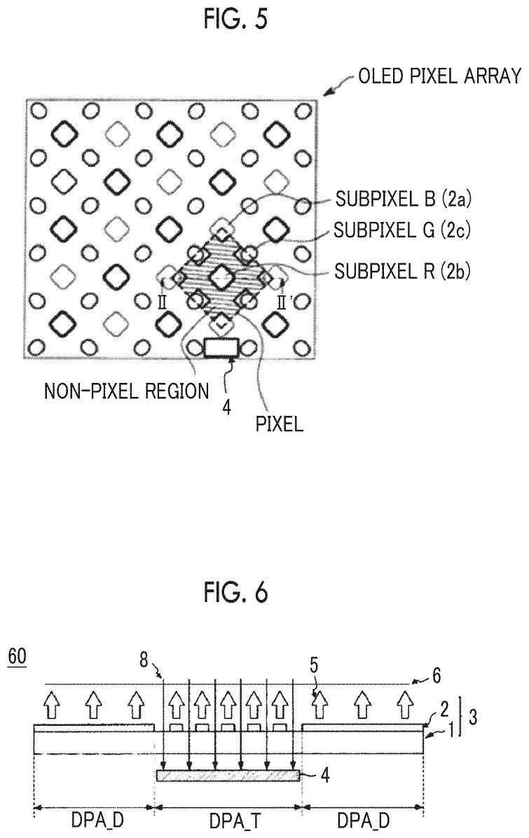

In the OLED unit 41, an aggregate of subpixels (2a, 2b, 2c) that emit colors (R, G, B) having different wavelengths form one pixel, and a plurality of the pixels are repeatedly arranged in a pattern such as a matrix. The pixel patterns are arranged in a so-called pentile matrix, for example, as shown in the top view such as FIG. 5. By arranging a non-pixel region perpendicular to the light receiving section 4 of the sensor unit, the incident invisible light 8 arrives at the light receiving section 4 and can be detected without interfering with a lower electrode 41c, an organic light emitting layer 41a, and an upper electrode 41b forming the pixel.

As the lower electrode 41c, a reflecting electrode may be used in order to improve the emission efficiency. As the material of the electrode, for example, the electrode on the substrate 1 side is formed of Al, Ag, Mo, AlNd, Mo/Al/Mo, TiN, ITO/Ag/ITO, ITO/Al/ITO, or ITO/Mo/ITO. The upper electrode 41b is formed of a transparent material such as ITO, IZO, AlZO, Ag nanowires, graphene, or CNT. The transmittance of the upper electrode 41b with respect to visible light is preferably 80% or more.

The organic light emitting layer 41a includes a well-known light emitting material that emits visible light in a predetermined wavelength range and includes, for example, a fluorescent material, a phosphorescent material, or thermally activated delayed fluorescence (TADF). The well-known light emitting material includes a metal complex compound such as an Ir complex compound, a Pt complex compound, an Os complex compound, or a Pd complex compound, anthracene (blue), Alq3 (green), DCM (red), or a combination thereof and is not limited thereto.

The interlayer 48 is optionally provided. The interlayer 48 connects the cover plate 49 and the OLED unit described below to each other. Optionally, a touch sensor, an optical functional layer such as a brightness improvement layer or a directivity control layer, a polarizing plate, a design layer, an electrode exposed from the emission surface side of the driving unit 42, or a black layer for hiding a wiring line may be provided.

The cover plate 49 may be optionally provided. The cover plate can be provided in order to protect the OLED unit or the sensor unit from damages or external wet heat or in order to efficiently emit light from the pixels to the outside by providing a surface antireflection layer on the emission surface.

Although not shown in the drawing, a barrier layer, a touch sensor layer, an index matching layer, an adhesive layer, a diffusion layer, a directivity control layer, a visible light absorbing layer, a near infrared light absorbing layer, or the like may be optionally provided to any position of the OLED display device 40.

As another example of the image display apparatus according to the embodiment of the present invention, the summary of an OLED display device 60 will be described using FIG. 6, the OLED display device 60 including: a light emitting panel 3 including pixels on a substrate; and the light receiving section 4 that is provided on a side of the light emitting panel 3 opposite to the emission surface 6.

The light emitting panel 3 includes pixels 2 on the substrate 1. In the pixel 2, the subpixels of the respective colors are disposed in a patterned manner as shown in FIG. 5 but are continuously shown for simplicity in the drawing. The light receiving section 4 is provided on the side of the substrate 1 opposite to the emission surface 6. The light emitted from the pixel 2 is emitted from the display device through the emission surface 6. Invisible light incident from an external invisible light source (not shown) into the emission surface 6 of the OLED display device 60 transmits through the non-pixel region on the substrate, is incident into the light receiving section 4, and brings about information of the object.

Here, the substrate 1 is shown in FIG. 6 to have transmittance to the incident invisible light 8. By providing a hole in the substrate 1, the invisible light 8 may transmit through the substrate 1. In addition, a driving thin film transistor (TFT) element, a wiring line, and various functional layers (not shown) are laminated on the actual substrate 1, and thus are disposed such that the invisible light 8 avoids these elements and arrives at the light receiving section 4. It is preferable that these elements have transmittance to the invisible light 8.

In addition, the light receiving section 4 is shown to be sufficiently large for the width of the non-pixel region such that a non-sensor region DPA_D (refer to FIG. 6) is provided. The present invention is not limited to this example, and the light receiving section 4 can be provided in any size in any region. For example, the size for the non-pixel region is not limited and may be provided to be smaller or larger. In addition, as the light receiving section 4, a plurality of unit light-receiving elements may be provided to be spaced from each other, and an integrated element such as a complementary metal oxide semiconductor (CMOS) chip or a charge coupled device (CCD) chip may be provided only at one position. In addition, the non-sensor region DPA_D may or may not be provided, a sensor region DPA_T (refer to FIG. 6) may be provided in most of the entire substrate 1, and a plurality of sensor regions DPA_T may be dividedly provided such that a gap between the sensor regions DPA_T is covered with the non-sensor region DPA_D.

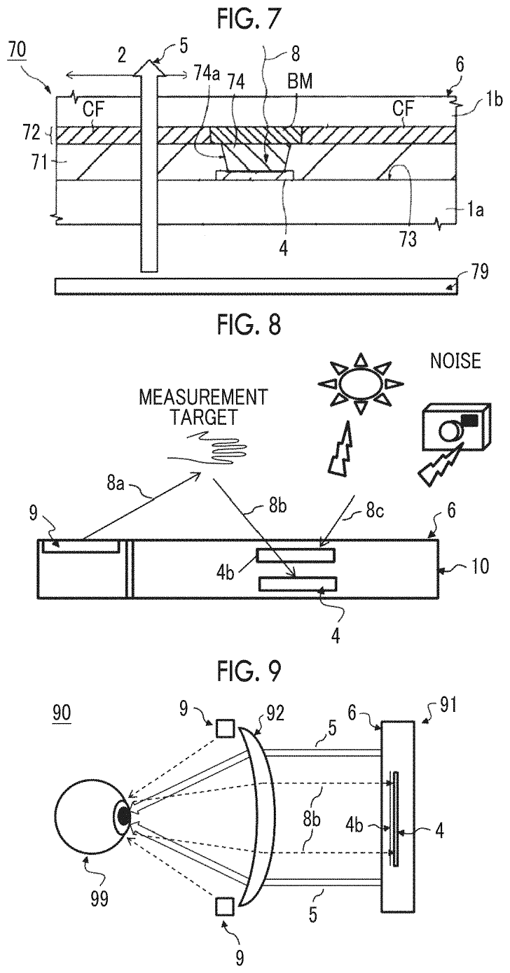

In addition, as one example of the image display apparatus according to the first embodiment of the present invention, FIG. 7 shows a display device 70 including: a substrate 1a; a liquid crystal layer 71 that is provided between the substrate 1a and a color filter substrate 1b; a liquid crystal panel that is driven by an electrode (not shown); the light receiving section 4 that is provided on the substrate 1a of the liquid crystal panel; and a backlight unit 79.

The luminous flux 5 of visible light emitted from the backlight unit 79 is converted into light having a specific color by a color filter CF defining each of the pixels of the color filter layer 72 and emitted from the emission surface 6 (in the example shown in the drawing, the surface of the color filter substrate 1b) after modulation of the liquid crystal layer 71 by the electrode formed on a surface 73 of the substrate of the liquid crystal panel and switching between transmission and non-transmission by a pair of upper and lower polarizing plates.

The pixel 2 in the liquid crystal panel is defined by the color filters CF of the respective colors and a black matrix BM that separates the color filters CF.

By allowing the black matrix BM to have transmittance to invisible light, the invisible light 8 that is emitted from a light source (not shown) to a detection target to be incident into the display device 70 transmits through the black matrix unit and arrives at the light receiving section 4. A gap between the black matrix BM and the light-receiving surface of the light receiving section 4 may be filled with the liquid crystal layer 71, and a light guide member 74 may be provided in order to make the invisible light 8 efficiently arrive at the light receiving section 4. A side surface 74a of the light guide member 74 may be formed in a reverse tapered shape in order to improve the light collecting property of the light receiving section 4.

FIG. 7 shows the case where the light receiving section is provided on the substrate 1a. However, as described above, the light receiving section may be provided between the emission surface 6 and the substrate 1a, on the substrate 1a, or on a side of the substrate 1a opposite to the emission surface 6 or, for example, may be provided to be integrated with the backlight unit 79 in FIG. 7.

In the image display apparatus according to the embodiment of the present invention, a polarizer that acts on invisible light is provided between the light receiving section and the emission surface in order to control polarization of invisible light arriving at the light receiving section to improve the detection accuracy, to increase the amount of information acquired, or to achieve both of the objects. In one preferable aspect, a specific example of an image display system will be described using FIG. 8, the image display apparatus including: the above-described display device; and a polarizer that is disposed between the light receiving section and the emission surface in the image display apparatus, in which the polarizer is a near infrared polarizer having polarization selectivity in a near infrared range.

The image display system shown in FIG. 8 includes a near infrared polarizer 4b having polarization selectivity in a near infrared range that is provided between the light receiving section 4 having sensitivity in a near infrared range and the emission surface 6 in the image display apparatus 10. In FIG. 8, the image display panel is not shown.

The image display system shown in FIG. 8 further includes a light source 9 that emits near infrared polarized light to the outside of an image display region. In the example shown in the drawing, the light source 9 is attached to a side surface of the image display apparatus 10. Light (invisible light) 8a emitted from the light source 9 that is attached to the image display apparatus 10 and emits near infrared polarized light is reflected from a measurement target to be incident into the image display apparatus 10 as incidence light 8b. In this case, the incidence light 8b includes a large amount of specific polarized light. Incidentally, sunlight present in an environment or near infrared light noise 8c from the other apparatus may become noise for the image display apparatus (image display system) according to the embodiment of the present invention. However, in a case where the near infrared light noise 8c is in a polarized state different from that of the incidence light 8b or is in an unpolarized state, the near infrared polarizer 4b is a polarizer that allows transmission of only a large amount of polarized light in the incidence light 8b such that most of the near infrared light noise 8c is absorbed by the near infrared polarizer 4b, and the light receiving section 4 can accurately detect only the incidence light 8b.

FIG. 8 shows that light 8a as near infrared light (hereinafter, also referred to as “near infrared light”) and the incidence light 8b are shown to have a relationship of reflection with respect to a measurement target. The image display system according to the embodiment of the present invention is not limited only to the reflection system. The light source 9 may be provided separately from the image display apparatus according to the embodiment of the present invention such that the near infrared light 8a and the incidence light 8b have a relationship of transmission with respect to a measurement target. In addition, the measurement target may be any target. Examples of the measurement target include a portion of a biological body of a user such as a hand, a finger, a palm, or a skin, a vein pattern, a face, an eyeball, a lip, and a limb of a user, motions or gestures thereof, an object such as a specific interface device or a surrounding object, and a state of a surrounding environment such as a temperature, a humidity, or a composition of particles or gas. In the present invention, the hand refers to a portion including all of a finger and a palm, the finger refers to a portion from a base of the palm to the tip of the finger, and the palm refers to a portion from the base of the finger to a wrist.

As the light source 9 that emits polarized light of invisible light (infrared light), any light source can be applied. Typically, an IR emitting LED device, an IR laser, or various lamps having an emission band in a near infrared range can be used. In addition, in order to improve the polarization degree of the light source, another polarizer having a polarization property in a near infrared range may be further provided adjacent to the light source.

As the near infrared polarizer having polarization selectivity in a near infrared range, for example, a polarizer obtained by adsorbing and aligning a dichroic dye having absorption in a near infrared range to a polyvinyl alcohol resin film, a polarizer obtained by dissolving or dispersing a dichroic dye having absorption in a near infrared range in a liquid crystal composition to form an alignment state and immobilizing the alignment state, a polarizer obtained by polyene formation with an iodine polarizing plate, a polarizer obtained by application of a wire grid, a reflective polarizer formed of a cholesteric liquid crystal or a dielectric multi-layer film, or a polarizer having a surface microstructure such as a metasurface can be applied.

In the near infrared polarizer having polarization selectivity in a near infrared range, a single plate transmittance at a wavelength of 850 nm is preferably less than 50% and more preferably less than 47%. In addition, a single plate transmittance at a wavelength of 950 nm is preferably less than 55%, more preferably less than 50%, and still more preferably less than 47%. In addition, regarding the polarization degree, P(850) is preferably 0.80 or more, more preferably 0.85 or more, still more preferably 0.90 or more, and still more preferably 0.95 or more. In addition, P(950) is preferably 0.80 or more, more preferably 0.85 or more, still more preferably 0.90 or more, and still more preferably 0.95 or more. The upper limits of P(850) and P(950) are theoretically 1.00 and are in a range of less than 1.00 in practice.

In this range, the noise can be sufficiently removed, and the detection accuracy can be improved.

The single plate transmittance can be measured using a measuring method using a spectrophotometer (for example, product name: VAP-7070 (manufactured by JASCO Corporation) or product name: VAP-7200 (manufactured by JASCO Corporation)). In one example of the measurement, a single plate transmittance in a visible range is measured assuming that the measurement wavelength is in a range of 400 to 700 nm. In addition, in another example, a single plate transmittance of invisible light, in particular, near infrared light is measured assuming that the measurement wavelength is 800 to 1500 nm. In order to remove the effect of interface reflection of the polarizer surface, it is preferable that the measurement is performed in a state where interface reflection is removed by dipping in matching oil. In addition, “single plate transmittance at wavelength a nm” refers to a transmittance at the dedicated wavelength a nm.

Regarding a method of measuring a polarization degree, a parallel transmittance (H0) and an orthogonal transmittance (H90) of a polarizer are measured using an analyzer, and the polarization degree can be obtained from the expression: Polarization Degree (%)={(H0−H90)/(H0+H90)}½×100. The polarization degree in a visible range can be measured assuming that the measurement wavelength is in a range of 400 to 700 nm, and the polarization degree in an invisible range can be measured assuming that the measurement wavelength is in a range of 800 to 1500 nm. In addition, the polarization degree of a specific wavelength can also be defined. For example, the polarization degree at a wavelength of 850 nm can be obtained by measuring a parallel transmittance (H0-850) and an orthogonal transmittance (H90-850) of a polarizer with respect to light at a wavelength of 850 nm and fitting the measured values into the expression for obtaining the polarization degree.

In addition, in the display device and the image display apparatus according to the first embodiment of the present invention, in order to implement image display or to improve the image quality, a visible light polarizer having polarization selectivity in a visible range can be further provided.

In the image display apparatus including the OLED display panel and the LED array, the micro LED panel, or the mini LED panel shown in FIGS. 4 and 6, in order to improve display contrast at the time of non-emission (at the time of black display) and under strong external light, a circular polarization plate that acts in a visible range can be provided on the emission surface side of the light emitting panel or as the emission surface itself. This circular polarization plate can be configured to be a laminate in which a visible light polarizer and a retardation plate are laminated, and can include a visible light polarizer as a linear polarizer having polarization selectivity in a visible range and a ¼ wave plate as a retardation layer in this order from the emission surface side.

In addition, the display device 70 shown in FIG. 7 includes two upper and lower polarizers (not shown), and these two polarizers have polarization selectivity in a visible range. These two polarizers are essential for implementing image display in the display device 70 of FIG. 7. Further, in order to improve the display contrast and to improve viewing angle characteristics in an oblique direction, an optically-anisotropic layer can be provided between the polarizers and the liquid crystal panel.

As the polarizer (visible light polarizer) having polarization selectivity in a visible range, a commercially available product can be used. For example, a polarizer obtained by adsorbing and aligning iodine or a dichroic dye having absorption in a visible range to a polyvinyl alcohol resin film, a polarizer obtained by dissolving or dispersing a dichroic dye having absorption in a visible range in a liquid crystal composition to form an alignment state and immobilizing the alignment state, a polarizer obtained by application of a wire grid, a reflective polarizer formed of a cholesteric liquid crystal or a dielectric multi-layer film, or a polarizer having a surface microstructure such as a metasurface can be applied.

The actions of the near infrared polarizer having polarization selectivity in a near infrared range and the visible light polarizer having polarization selectivity in a visible range may interfere with each other in order to design the image display apparatus, the image display system, or the head-mounted display according to the embodiment of the present invention. In order to reduce the effect of the interference, it is preferable that the near infrared polarizer having polarization selectivity in a near infrared range does not have a polarization property in a visible range or has transmittance in a visible range. In addition, from the same viewpoint, it is preferable that the visible light polarizer having polarization selectivity in a visible range does not have a polarization property in a near infrared range or has transmittance in a near infrared range.

As the near infrared polarizer having polarization selectivity in a near infrared range and having transmittance in a visible range, for example, a polarizer obtained by adsorbing and aligning a dichroic dye having absorption in a near infrared range and having transmittance in a visible range to a polyvinyl alcohol resin film, a polarizer obtained by dissolving or dispersing a dichroic dye having absorption in a near infrared range and having transmittance in a visible range in a liquid crystal composition to form an alignment state and immobilizing the alignment state, a polarizer having a reflection band in a near infrared range among reflective polarizers formed of a cholesteric liquid crystal or a dielectric multi-layer film, or a polarizer having a polarization selectivity action in a near infrared range among polarizers having a surface microstructure such as a metasurface can be applied.

In the near infrared polarizer having polarization selectivity in a near infrared range and having transmittance in a visible range, a single plate transmittance at a wavelength of 850 nm is preferably less than 55%, more preferably less than 50%, and still more preferably less than 47%. In addition, a single plate transmittance at a wavelength of 700 nm is preferably 58% or more, more preferably 75% or more, and still more preferably 80% or more. In addition, regarding the polarization degree, P(850) is preferably 0.80 or more, more preferably 0.85 or more, still more preferably 0.90 or more, and still more preferably 0.95 or more. In addition, P(950) is preferably 0.80 or more, more preferably 0.85 or more, still more preferably 0.90 or more, and still more preferably 0.95 or more. The upper limits of P(850) and P(950) are theoretically 1.00 and are in a range of less than 1.00 in practice.

As the visible light polarizer having polarization selectivity in a visible range and having transmittance in a near infrared range, for example, an iodine polarizer having reduced absorption properties in a near infrared range, a polarizer obtained by adsorbing and aligning a dichroic dye having absorption in a visible range and having transmittance in a near infrared range to a polyvinyl alcohol resin film, a polarizer obtained by dissolving or dispersing a dichroic dye having absorption in a visible range and having transmittance in a near infrared range in a liquid crystal composition to form an alignment state and immobilizing the alignment state, a polarizer having a reflection band in a visible range among reflective polarizers formed of a cholesteric liquid crystal or a dielectric multi-layer film, or a polarizer having a polarization selectivity action in a visible range among polarizers having a surface microstructure such as a metasurface can be applied.

In the visible light polarizer having polarization selectivity in a visible range and having transmittance in a near infrared range, a single plate transmittance at a wavelength of 850 nm is preferably 75% or more, more preferably 80% or more, and still more preferably 85% or more. In addition, a single plate transmittance at a wavelength of 700 nm is preferably less than 55%, more preferably less than 50%, and still more preferably less than 47%.

In addition, regarding the polarization degree, P(550) is preferably 0.90 or more, more preferably 0.95 or more, still more preferably 0.98 or more, and still more preferably 0.99 or more. The upper limit of P(550) is theoretically 1.00 and is in a range of less than 1.00 in practice.

In addition, as one preferable aspect of the image display apparatus, the image display system, or the head-mounted display according to the first embodiment of the present invention, the image display apparatus, the image display system, or the head-mounted display shown in FIGS. 1, 2, 3, 4, 6, and 7 where the invisible light (near infrared flux) 8 and the luminous flux in a visible range (hereinafter also referred to as visible flux) 5 do not interfere with each other can be used. Specifically, by designing the luminous flux 5 in a visible range and the near infrared flux 8 to transmit through microscopically different optical paths, layers having polarization selectivity that are suitable for the optical paths are provided in a patterned manner. In addition, in another specific example, one polarizer having polarization selectivity in both of a visible range and a near infrared range may be provided such that the polarization selectivity to the luminous flux 5 in a visible range and the polarization selectivity to the near infrared flux 8 match with each other on the polarizer.

As the polarizer where the layers having polarization selectivity that are suitable for the optical paths of the near infrared flux 8 and the visible flux 5 are provided in a patterned manner, for example, a polarizer including a pattern that includes a plurality of regions obtained by dissolving or dispersing a dichroic dye having absorption and transmission properties in both of the ranges in a liquid crystal composition to form an alignment state and immobilizing the alignment state, a polarizer including a pattern that includes a plurality of regions having different reflection bands among reflective polarizers formed of a cholesteric liquid crystal or a dielectric multi-layer film, or a polarizer including a pattern that includes a plurality of regions having different action bands in a near infrared range among polarizers having a surface microstructure such as a metasurface can be applied.

In addition, as the polarizer having the same polarization selectivity in both of a visible range and a near infrared range, for example, a polarizer obtained by adsorbing and aligning iodine or a dichroic dye having absorption properties in a visible range to a near infrared range to a polyvinyl alcohol resin film, a polarizer obtained by dissolving or dispersing a dichroic dye having absorption properties in a visible range to a near infrared range in a liquid crystal composition to form an alignment state and immobilizing the alignment state, a polarizer obtained by application of a wire grid, or a polarizer having a reflection band in a visible range to a near infrared range among reflective polarizers formed of a cholesteric liquid crystal or a dielectric multi-layer film can be applied.

In addition, as the polarizer having the same polarization selectivity in both of a visible range and a near infrared range, it is preferable that a single plate transmittance at both wavelengths of 750 nm and 850 nm is less than 55%, it is more preferable that a single plate transmittance at at least one of a wavelength of 750 nm or 850 nm is less than 50%, and it is still more preferable that a single plate transmittance at at least one of a wavelength of 750 or 850 nm is less than 47%.

The image display apparatus and the image display system can be applied to, for example, a wearable device such as a head-mounted display, a mobile display device such as a smartphone or a tablet, or a stationary display device such as a television or a lighting.

Preferable aspects of the devices will be described using the following specific examples.

As a head-mounted display including the image display apparatus according to the first embodiment of the present invention, a head-mounted display 90 will be described, the head-mounted display 90 including, as shown in FIG. 9, an image display apparatus 91 according to the embodiment of the present invention, an eyepiece 92, a light source (hereinafter, also referred to as “near infrared light source” 9 that is capable of emitting near infrared light, and an eye tracking system that detects the near infrared light 8b (incidence light) emitted from the near infrared light source 9 to an eyeball 99 and reflected from the eyeball 99 using the light receiving section 4 through the eyepiece 92. In the drawing, the image display panel in the image display apparatus 91 is not shown. The eyepiece 92 has a function of projecting the luminous flux 5 in a visible range as an image emitted from the emission surface 6 of the image display apparatus 91 to the eyeball, provides a wide field of view (FOV) to the observer, and implements outstanding immersive image display. Information regarding an eye position and a visual line obtained from the eye tracking can be used for rendering the projected image or for an operation of a graphic interface embedded in a display image. The image display apparatus 91 includes the near infrared polarizer 4b that is provided between the light receiving section 4 and the emission surface 6. Therefore, stray light in the optical system and near infrared light noise from the outside of the head-mounted display or from another member forming the head-mounted display can be reduced. In addition, it is preferable that the eyepiece 92 has near infrared transmittance from the viewpoint of maintaining the intensity of the incidence light 8b as the near infrared light reflected from the eyeball 99. In addition, it is preferable that near infrared antireflection coating is performed on the surface of the eyepiece 92, and the surface reflectivity thereof is preferably less than 4% and more preferably less than 2%.

In the related art, an eye tracking system of a head-mounted display is provided not to overlap a display optical system. Therefore, a restriction on a space is severe, it is necessary to perform sensing at a large angle with respect to an eyeball, in particular, an eye direction, and the improvement of the detection accuracy is required. With the sensing system according to the embodiment of the present invention, the display optical system and the eye tracking optical system can be housed in a common space, and eye tracking having excellent detection accuracy can be performed compactly at an appropriate beam angle.

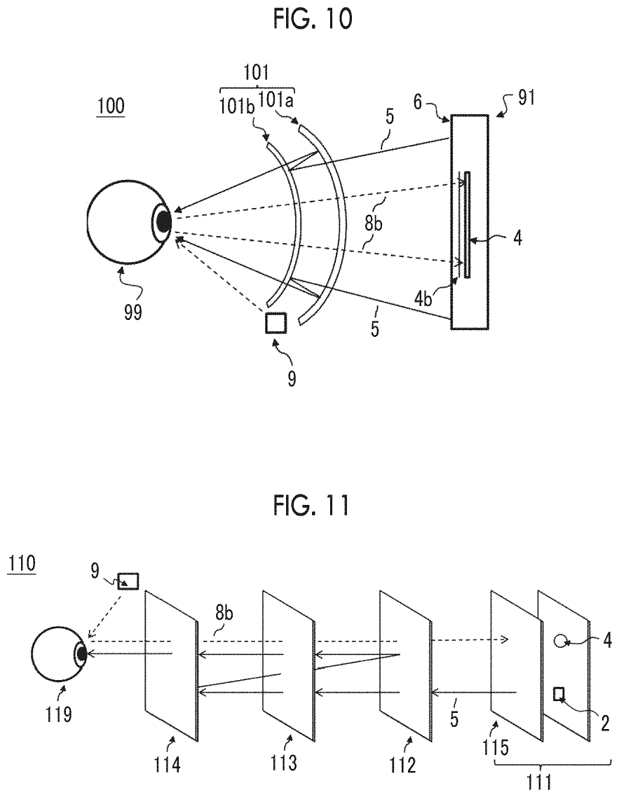

In addition, a case where a so-called pancake lens including a half mirror and a reflective polarizer is used as the eyepiece will be described using FIG. 10. The pancake lens 101 is a member that exhibits an action of a lens as a catadioptric system by either or both of the half mirror 101a and the reflective polarizer 101b to have a curved surface. Monochromatic aberration or chromatic aberration is more likely to be controlled as compared to a lens using a refraction action of glass or a resin that is typically used, and the weight and the thickness are less than that of a resin lens having the same monochromatic aberration or chromatic aberration. Therefore, the pancake lens 101 can be preferably used as the eyepiece of the head-mounted display.

A state where this optical system acts as a lens will be described as an example. In a head-mounted display 100, as shown in FIG. 10, the visible flux 5 emitted from the image display apparatus 91 is repeated once from each of the reflective polarizer 101b and the half mirror 101a and arrives at the eyeball 99. In this case, the reflective polarizer 101b has circularly polarized light selectivity, the reflective polarizer 101b has linearly polarized light selectivity, a ¼ wave plate (not shown) is provided between the reflective polarizer 101b and the half mirror 101a, and the luminous flux 5 that is incident from the half mirror into the ¼ wave plate is converted into linearly polarized light where a polarization direction forms 45° with respect to a slow axis of the ¼ wave plate. As a result, the light that is reflected from the reflective polarizer 101b, returns to the half mirror 101a side again, and is reflected from the half mirror 101a changes into a polarized state where the light transmits through the reflective polarizer 101b. The series of actions exhibit the same optical action as a lens using refraction, and the pancake lens 101 can be used as the eyepiece of the head-mounted display.

The above-described description is a preferable example, and as long as the action as a so-called pancake lens can be exhibited, characteristics of the half mirror 101a, the reflective polarizer 101b, and various wave plates that are used in combination can be combined in various ways. In addition, an absorption type visible light polarizer and another retardation plate may be additionally provided on the eyeball side of the pancake lens 101 in order to reduce the effect of ghosting caused by leakage of unintended polarized light from the reflective polarizer 101b in the light incident from the reflective polarizer 101b into the eyeball and the effect of stray light caused in a case where the luminous flux 5 as an image incident into the eyeball is reflected from the eyeball surface and the eyeball side surface of the pancake lens 101.

In one preferable aspect of the first embodiment of the present invention, the reflective polarizer 101b and the half mirror 101a can have transmittance in a near infrared range. With this configuration, the incidence light 8b that is emitted from the near infrared light source 9 to the eyeball 99 to be incident into the light receiving section 4 can arrive at the light receiving section 4 without being reflected from the pancake lens 101. In this case, for example, in a case where the pancake lens system includes a ¼ wave plate, even in a case where the near infrared light emitted from the near infrared light source 9 is polarized light, the incidence light 8b having passed through the emission surface 6 of the image display apparatus 91 may change in polarized state due to the effect of the ¼ wave plate or the like. In order to improve the detection accuracy, an additional retardation layer may be provided at any position on the optical path of the incidence light 8b such that this change in polarized state is compensated for to improve the transmittance of the near infrared polarizer 4b with respect to the incidence light 8b.

As the above-described half mirror, a metal deposited film, a dielectric multi-layer film, a multi-layer polymer reflective polarizer (for example, APF or DBEF), a cholesteric mirror, a reflective wire grid polarizer, or a metasurface polarizer can be used.

As the above-described reflective polarizer, a metal deposited film, a dielectric multi-layer film, a multi-layer polymer reflective polarizer (for example, APF or DBEF), a cholesteric mirror, a reflective wire grid polarizer, or a metasurface polarizer can be used. In general, the multi-layer polymer reflective polarizer and the reflective wire grid polarizer have linearly polarized light selectivity, and the cholesteric mirror has circularly polarized light selectivity. In the present invention, it is preferable that the reflective polarizer has wavelength selectivity.

The above-described ¼ wave plate can be used without any particular limitation as long as it is a retardation element having a phase delay amount corresponding to ¼ wavelength in a predetermined wavelength range, and examples thereof include an inorganic retardation plate, a polymer drawn retardation plate, a liquid crystal retardation plate obtained by immobilizing a liquid crystal compound or a polymerizable liquid crystal compound in an alignment state, and a metasurface retardation plate. Having the phase delay amount corresponding to ¼ wavelength represents that Re(550) is in a range of 120 nm to 160 nm. In order to act on a visible flux, it is preferable that ¼ wavelength properties are exhibited in a wide band, and it is preferable that so-called reverse wavelength dispersibility where the wavelength dispersibility satisfies a relationship of Re(450)<Re(550)<Re(650).

The ¼ wave plate may be a single-layer film or sheet or a laminate in which a plurality of films or sheets are laminated to exhibit the properties. In addition, by using a retardation plate formed of twisted liquid crystal or hybrid aligned liquid crystal in combination, properties of the ¼ wave plate may be exhibited for specific polarized light.

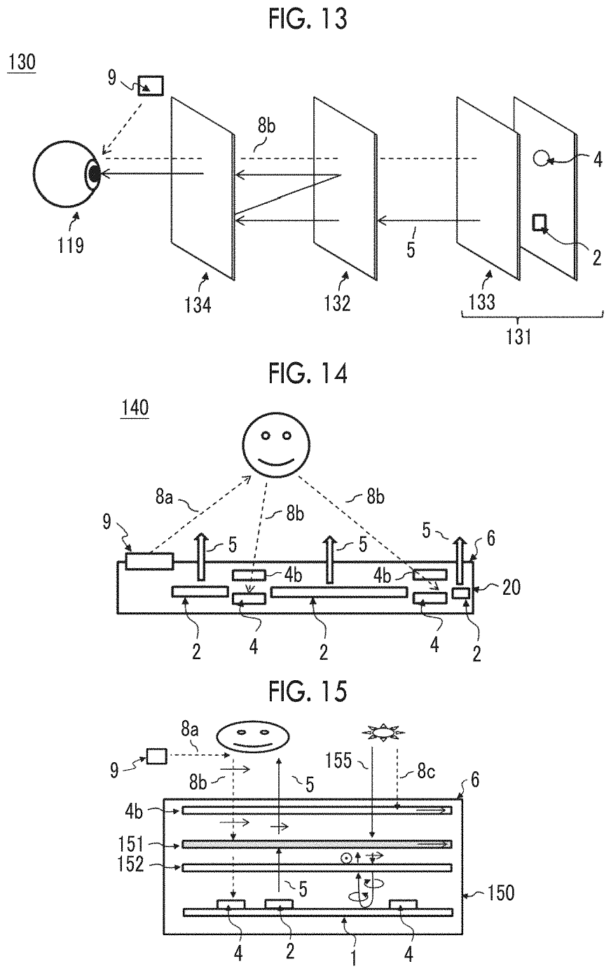

Characteristics and gains of the optical system will be described in more detail using FIGS. 11 and 13 conceptually showing the example of the head-mounted display 100 of FIG. 10.

As one preferable aspect of the head-mounted display according to the first embodiment of the present invention, FIG. 11 shows a head-mounted display 110 including: an image display apparatus 111 that includes the light receiving section 4 and the pixels 2; and a polarizer 115, a half mirror 112, a ¼ wave plate 113, and a reflective linear polarizer (in the present invention, a reflective polarizer) 114 that are provided in this order on a surface of the image display apparatus 111, in which image display is performed by projecting the visible flux 5 to an eye 119 of an observer, and eye tracking is performed by detecting the incidence light 8b obtained by causing the near infrared light emitted from the near infrared light source 9 to be reflected from the eye 119 of the observer using the light receiving section 4. In FIG. 11, the half mirror 112 side surface of the polarizer 115 is the emission surface 6 of the display device. A near infrared polarizer (not shown) may be provided between the polarizer 115 and the light receiving section 4 or may be integrated with the polarizer 115. In addition, the near infrared polarizer may be provided between the polarizer 115 and the half mirror 112. In this case, the emission surface 6 is the half mirror 112 side surface of the near infrared polarizer.

By appropriately designing the arrangement of the polarizer 115, the half mirror 112, the ¼ wave plate 113, and the reflective linear polarizer 114 in this order and the shapes thereof, an action as an eyepiece can be exhibited. FIG. 11 is a conceptual diagram and shows that the half mirror 112 and the reflective linear polarizer 114 have a planar shape for simplicity although it is preferable at least either or both of the half mirror 112 and the reflective linear polarizer 114 to have a curved surface shape. In addition, the optical paths of the visible flux 5 and the near infrared light 8a and the incidence light 8b are shown to be different from the original optical path for illustration.

Here, the incidence light 8b as the near infrared light reflected from the eye 119 transmits through the reflective linear polarizer 114, the ¼ wave plate 113, the half mirror 112, and polarizer 115 in this order and arrives at the light receiving section 4. In this case, a part of the incidence light 8b is scattered or reflected from one or a plurality of surfaces of the reflective linear polarizer 114, the ¼ wave plate 113, the half mirror 112, and the polarizer 115 such that a ghost image or noise is generated. By using a polarized light source as the near infrared light source 9 and providing the near infrared polarizer 4b between the emission surface 6 and the light receiving section 4, the ghost image and the noise can be reduced.

For example, the near infrared light that travels to the light receiving section 4 through an optical path shown in the drawing as the incidence light 8b undergoes a change in phase difference depending on phase differences of the reflective linear polarizer 114, the ¼ wave plate 113, the half mirror 112 and the polarizer 115 with respect to near infrared light. Regarding the luminous flux that arrives at the light receiving section 4 through an optical path other than the optical path shown in the drawing as the incidence light 8b, the incidence angle or number of times of incidence into each of the above-described members varies. Therefore, the amount of change in phase difference is different from the original amount of change in phase difference. Accordingly, by disposing the near infrared polarizer 4b and an optionally provided retardation plate such that transmission of only the incidence light 8b having a predetermined amount of change in phase difference is allowed and near infrared light having a different amount of change from that of the incidence light 8b is absorbed, information regarding an eye of an observer can be acquired, and the detection accuracy can be improved.

As the above-described retardation plate, a well-known retardation plate can be used without any particular limitation, and examples thereof include an inorganic retardation plate, a polymer drawn retardation plate, a liquid crystal retardation plate obtained by immobilizing a liquid crystal compound or a polymerizable liquid crystal compound in an alignment state, and a metasurface retardation plate.

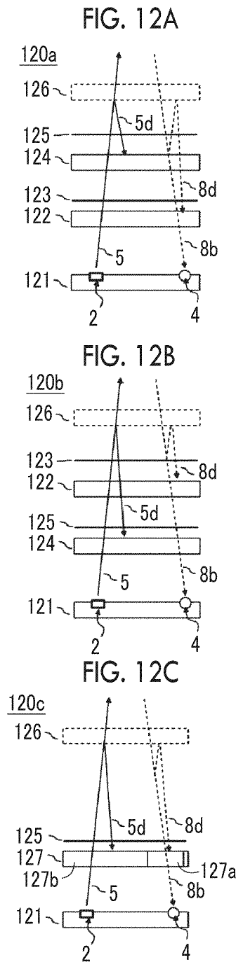

Regarding the image display apparatus 111 in FIG. 11, a configuration including the polarizer 115 that can exhibit the above-described effect of improving the detection accuracy will be described using FIGS. 12a to 12c.

For example, as one preferable aspect, FIG. 12a shows a display device (image display apparatus) 120a where a first retardation plate 125, a visible light polarizer 124 as a linear polarizer having polarization selectivity to visible light, a second retardation plate 123 that is optionally provided, a near infrared polarizer 122 having polarization selectivity to near infrared light, and a light emitting panel (image display panel) 121 including the pixels 2 and the light receiving section 4 are disposed in this order from a half mirror 126 side. In this case, the emission surface of the display device 120a can be a half mirror 126 side surface of the first retardation plate 125 or a half mirror 126 side surface of the visible light polarizer 124. In addition, the polarizer 115 in FIG. 11 can be the visible light polarizer 124.

The incidence light 8b as near infrared light reflected from the eyeball of the observer transmits through the half mirror 126, the first retardation plate 125, the visible light polarizer 124 having polarization selectivity to visible light, the second retardation plate 123 that is optionally provided, and the near infrared polarizer 122 having polarization selectivity to near infrared light in this order and arrives at the light receiving section 4. Here, it is preferable that the second retardation plate 123 that is optionally provided has a phase difference such that the polarized state of the incidence light 8b substantially matches with a transmission axis of the near infrared polarizer 122. As a result, the incidence light 8b can arrive at the light receiving section 4.

Here, a part of the near infrared flux 8d reflected from the visible light polarizer 124 is reflected again from the half mirror 126 and travels again to the light receiving section 4. This near infrared flux 8d causes a ghost image or stray light, which can lead to a decrease in the detection accuracy or the amount of information acquired in the image display apparatus according to the embodiment of the present invention. However, since the incidence light 8b transmits through the first retardation plate 125 twice, the polarized state thereof is different from that of the incidence light 8b, and is converted by the second retardation plate 123 into linearly polarized light or elliptically polarized light that does not match with the transmission axis of the near infrared polarizer 122. Thus, most of the light amount is removed by the near infrared polarizer 122. Therefore, with the configuration of FIG. 12a, the detection accuracy or the amount of information acquired in the image display apparatus according to the embodiment of the present invention can be improved. The near infrared flux 8d is an example of the luminous flux that transmits through an unintended optical path, and actually a ghost image and stray light that may be caused by unintended reflection can be reduced due to the same effect, the unintended reflection occurring on an interface or a reflecting surface present between the eyeball (measurement target) and the near infrared polarizer.

On the other hand, the visible flux 5 emitted from the pixels 2 is converted into polarized light through the near infrared polarizer 122, the second retardation plate 123 that is optionally provided, the visible light polarizer 124, and the first retardation plate 125 and is incident into the half mirror 126. It is preferable that the first retardation plate 125 is a ¼ wave plate having a slow axis disposed at 450 or 135° with respect to the transmission axis of the visible light polarizer 124. With this configuration, circularly polarized light is incident into the half mirror 126. A part of the circularly polarized light incident into the half mirror 126 is incident into the visible light polarizer 124. In this case, a visible flux 5d reflected from the half mirror 126 is converted into circularly polarized light having a direction opposite to that of the incident circularly polarized light. Therefore, the circularly polarized light is converted by the first retardation plate as a ¼ wave plate into linearly polarized light perpendicular to a transmission axis of the visible light polarizer 124 and is absorbed by the visible light polarizer 124. Accordingly, a decrease in display contrast caused by a ghost image or stray light generated in a display image can be suppressed.

It is preferable that the visible light polarizer 124 as a linear polarizer having polarization selectivity to visible light has transmittance to the incidence light 8b as near infrared light.

In addition, in the visible light polarizer 124, the polarization degree P(550) is preferably 0.90 or more, more preferably 0.95 or more, still more preferably 0.98 or more, and still more preferably 0.99 or more. In addition, a single plate transmittance at a wavelength of 850 nm is preferably 75% or more, more preferably 80% or more, and still more preferably 90% or more.

In addition, it is preferable that the near infrared polarizer 122 has transmittance in a visible range.

In the near infrared polarizer 122, a single plate transmittance at a wavelength of 850 nm is preferably less than 50% and more preferably less than 47%. In addition, a single plate transmittance at a wavelength of 950 nm is preferably less than 55%, more preferably less than 50%, and still more preferably less than 47%. In addition, regarding the polarization degree, P(850) is preferably 0.80 or more, more preferably 0.85 or more, still more preferably 0.90 or more, and still more preferably 0.95 or more. In addition, P(950) is preferably 0.80 or more, more preferably 0.85 or more, still more preferably 0.90 or more, and still more preferably 0.95 or more. The upper limits of P(850) and P(950) are theoretically 1.00 and are in a range of less than 1.00 in practice.

In addition, in another preferable aspect, FIG. 12b shows a display device (image display apparatus) 120b in which the second retardation plate 123 that is optionally provided, the near infrared polarizer 122 having polarization selectivity to near infrared light, the first retardation plate 125 that is optionally provided, the visible light polarizer 124 having polarization selectivity to visible light, and the light emitting panel 121 including the pixels 2 and the light receiving section 4 are disposed in this order from the half mirror 126. In this case, the emission surface of the display device 120b can be a half mirror 126 side surface of the second retardation plate 123 or a half mirror 126 side surface of the near infrared polarizer 122. In addition, the polarizer 115 in FIG. 11 can be the visible light polarizer 124.

The incidence light 8b as near infrared light reflected from the eyeball of the observer transmits through the half mirror 126, the second retardation plate 123 that is optionally provided, the near infrared polarizer 122 having polarization selectivity to near infrared light, the first retardation plate 125 that is optionally provided, and the visible light polarizer 124 having polarization selectivity to visible light in this order and arrives at the light receiving section 4. Here, it is preferable that the second retardation plate 123 that is optionally provided has a phase difference such that the polarized state of the incidence light 8b substantially matches with a transmission axis of the near infrared polarizer 122. As a result, the incidence light 8b can arrive at the light receiving section 4. In addition, due to the same action as described above using the display device of FIG. 12a, the near infrared flux 8d that transmits through an unintended optical path is removed, and the detection accuracy and the amount of information acquired can be improved.

In addition, the visible flux 5 emitted from the pixels 2 is converted into polarized light by the visible light polarizer 124 having polarization selectivity in a visible range and is incident into the half mirror 126. In this case, the first retardation plate 125, the near infrared polarizer 122, and the second retardation plate 123 change in polarized state depending on the phase differences thereof. By adjusting the phase difference values and the slow axis arrangement of the first retardation plate 125, the near infrared polarizer 122, and the second retardation plate 123 such that the change in polarized state is a change corresponding to ¼ wavelength, the visible flux 5 incident into the half mirror is converted into circularly polarized light, and the visible flux 5d is reflected from the half mirror and travels to the light emitting panel 121 side is converted into linearly polarized light perpendicular to the transmission axis of the visible light polarizer 124 and is removed by the visible light polarizer 124. As a result, a decrease in display contrast caused by a ghost image or stray light generated in a display image can be suppressed.

In still another preferable aspect, FIG. 12c shows a display device (image display apparatus) 120c in which the first retardation plate 125, a patterned polarizer 127, and the light emitting panel 121 including the pixels 2 and the light receiving section 4 are disposed in this order from the half mirror 126, the patterned polarizer 127 including a near infrared polarizer region 127a having polarization selectivity to near infrared light and a visible light linear polarizer region 127b having polarization selectivity to visible light in a patterned manner. In this case, the emission surface of the display device 120c can be a half mirror 126 side surface of the first retardation plate 125 or a half mirror 126 side surface of the patterned polarizer 127. The patterned polarizer 127 corresponds to the near infrared polarizer according to the embodiment of the present invention. In other words, the patterned polarizer 127 has a region where the near infrared polarizer according to the embodiment of the present invention is formed. In addition, the patterned polarizer 127 also has a function as the visible light polarizer.

The mechanism for the separation between the incidence light 8b as near infrared light reflected from the eyeball and incident into the light receiving section 4 and the near infrared flux 8d transmitted through an unintended optical path and the mechanism for the removal of the visible flux 5d obtained by causing the visible flux 5 emitted from the pixel 2 to be reflected from the half mirror and to travel to the light emitting panel 121 are the same as those of the display device shown in FIGS. 12a and 12b. Thus, the detection accuracy and the amount of information acquired in the image display apparatus can be improved, and ghosting and contrast reduction of a display image can be suppressed.

The patterned polarizer may be a polarizer where the near infrared polarizer region 127a having polarization selectivity to near infrared light and the visible light linear polarizer region 127b having polarization selectivity to visible light are provided in the same plane, or may be a laminate including: a near infrared patterned polarization element a near infrared polarizer region having polarization selectivity to near infrared light and a near infrared non-polarization region not having polarization selectivity in a near infrared range are provided in the same plane; and a visible light patterned polarization element where a visible light linear polarizer region having polarization selectivity to visible light and a visible light non-polarization region not having polarization selectivity in a visible range are provided in the same plane.

Instead of the near infrared patterned polarization element, an optical element including, in the same plane, a region where anisotropy of absorption in a near infrared range is aligned in an in-plane direction and a region where anisotropy of absorption in a near infrared range is aligned in a thickness direction may be used. In addition, instead of the visible light patterned polarization element, an optical element including, in the same plane, a region where anisotropy of absorption in a visible range is aligned in an in-plane direction and a region where anisotropy of absorption in a visible range is aligned in a thickness direction may be used.

In the near infrared polarizer region, as in the near infrared polarizer, a single plate transmittance at a wavelength of 850 nm is preferably less than 50% and more preferably less than 47%. In addition, a single plate transmittance at a wavelength of 950 nm is preferably less than 55%, more preferably less than 50%, and still more preferably less than 47%. In addition, regarding the polarization degree, P(850) is preferably 0.80 or more, more preferably 0.85 or more, still more preferably 0.90 or more, and still more preferably 0.95 or more. In addition, P(950) is preferably 0.80 or more, more preferably 0.85 or more, still more preferably 0.90 or more, and still more preferably 0.95 or more. The upper limits of P(850) and P(950) are theoretically 1.00 and are in a range of less than 1.00 in practice.

In this range, the noise can be sufficiently removed, and the detection accuracy can be improved.

The first retardation plate 125 is a ¼ wave plate having a slow axis disposed at 45° or 135° with respect to a transmission axis of the visible light linear polarizer region 127b. It is preferable that the first retardation plate 125 further has properties in which the polarized state of the incidence light 8b is converted into a polarized state where the near infrared polarizer region 127a has selective transmittance. The first retardation plate 125 may be a patterned retardation plate where a region where a ¼ wave plate acts in a visible range and a region having properties in which the polarized state of the incidence light 8b is converted into a polarized state where the near infrared polarizer region 127a has selective transmittance are disposed in a patterned manner. In this pattern, a ¼ wave plate acts in a visible range in the region corresponding to the visible light linear polarizer region 127b of the above-described patterned polarizer. At a position corresponding to the near infrared polarizer region 127a, the near infrared polarizer region 127a can be disposed to have properties in which the polarized state of the incidence light 8b is converted into a polarized state where the infrared polarizer region 127a has selective transmittance.

In addition, in another preferable aspect of the first embodiment of the present invention, FIG. 13 shows a head-mounted display 130 including: a display device (image display apparatus) 131 that includes the light receiving section 4 and the pixels 2; and a linear polarizer, a ¼ wave plate (that is, a circular polarization plate) 133, a half mirror 132, and a circularly polarized light selectivity reflective polarizer 134 that are provided in this order on a surface of the display device 131, in which image display is performed by projecting the visible flux 5 to an eye 119 of an observer, and eye tracking is performed by detecting reflected light obtained by causing the near infrared light emitted from the near infrared light source 9 to be reflected from the eye 119 of the observer using the light receiving section 4.

By appropriately designing the arrangement of the polarizer, the half mirror 132, and the circularly polarized light selectivity reflective polarizer 134 in this order and the shapes thereof, an action as an eyepiece can be exhibited. FIG. 13 is also a conceptual diagram and schematically shows the actual shapes of the members and the path of the luminous flux.

As the above-described circularly polarized light selectivity reflective polarizer, a cholesteric mirror or a laminate in which a wide band ¼ wave plate is laminated on the above-described linear reflective polarizer is preferable. From the viewpoint that it can be formed of a single layer and an optical interface is small or the viewpoint that the amount of phase difference applied to near infrared light is small, it is more preferable that a cholesteric mirror is used.

As the display device 131 including the half mirror 132, the circular polarization plate (the linear polarizer+the retardation plate) 133, the light receiving section 4, the pixels 2, and the near infrared polarizer (not shown), the display devices described above using FIG. 11 and FIGS. 12a to 12c can be used.

As one aspect of the image display system including the image display apparatus according to the first embodiment of the present invention, an example of the image display system including facial expression sensing (facial expression recognition system) or a face recognition system will be described using FIG. 14.

One preferable aspect of the image display system according to the first embodiment of the present invention is an image display system 140 including: the display device (image display apparatus) 20 including the sensor system according to the embodiment of the present invention; the light source 9 that is capable of emitting the near infrared light 8a to a face of a user; and a face recognition system or a facial expression recognition system that detects the incidence light 8b obtained by causing the near infrared light 8a emitted from the light source 9 to be reflected from a face of an observer using the light receiving section 4 through the near infrared polarizer 4b. The observer can use the above-described face recognition system or the facial expression recognition system while watching an image that is formed of the luminous flux 5 of visible light formed from the plurality of pixels 2, and the obtained information is processed using an arithmetic circuit (not shown) and can be used for releasing a security lock of a device or a service, recognizing a user, or providing a service corresponding to the state of the detected facial expression and/or face or for active control of the device.

As facial expression sensing or face recognition system in the related art, an imaging element provided in a side edge portion of a mobile display is used. In this imaging element, the field of view (FOV) per element is narrow, and in order to obtain the amount of information acquired required for recognition, the user needs to move the face largely multiple times for the imaging element. In a case where the imaging element is provided in a plurality of side edge portions of a mobile display in order to solve this problem, the space for the imaging elements causes a problem in device size and design.

However, with the image display apparatus according to the first embodiment of the present invention, a plurality of light receiving sections can be provided to be integrated with the display screen. Therefore, there is no problem in size and design, a necessary number of light receiving sections including a necessary number of pixels can be provided, and a sufficient amount of information can be acquired.

Examples of the image display panel in the display device 20 to be used include the OLED display panel shown in FIGS. 4 and 6, a light emitting panel such as a LED array, a micro LED panel, or a mini LED panel, and the display device formed of a liquid crystal cell shown in FIG. 7.

As described above, the image display panel can include a polarizer in order to form an image or to improve the image quality.

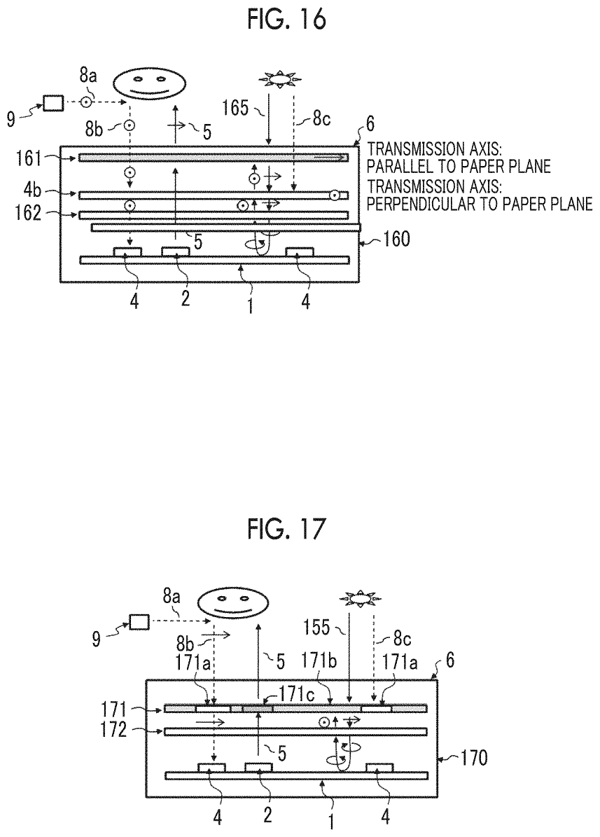

As the image display panel, regarding a configuration including the OLED display panel and a circular polarization plate that is provided on a surface of the OLED display panel to reduce external light reflection, a configuration for reducing interference between the incidence light 8b as near infrared light and the visible flux 5 will be described using a conceptual diagram shown in each of FIGS. 15 and 16.

FIG. 15 shows the image display system of FIG. 14 in more detail.

A display device (image display apparatus) 150 includes the near infrared polarizer 4b, a visible light polarizer 151, a retardation plate 152, and the substrate 1 including the pixels 2 and the light receiving section 4 in this order from the emission surface 6 to the substrate 1.

The near infrared light 8a emitted from the near infrared light source 9 having polarization emission properties is reflected from a face of a user to become the incidence light 8b, and the incidence light 8b is incident from the emission surface 6 into the display device 20. The visible light polarizer 151 has transmittance to light in a near infrared range and allows transmission of the incidence light 8b as near infrared light irrespective of a transmission axis thereof. The near infrared polarizer 4b has a transmission axis that matches with a polarization direction including a large amount of the incidence light 8b, and the light transmitted through the near infrared polarizer 4b arrives at the light receiving section 4 through the visible light polarizer 151 and the retardation plate 152. It is preferable that the visible light polarizer 151 and the retardation plate 152 have transmittance to near infrared light. The visible light polarizer 151 and the retardation plate 152 may have a phase difference in a near infrared range. However, the element forming the light receiving section 4 does not have polarization selectivity, and thus the incidence light 8b can be detected without any effect. On the other hand, in a case where the external near infrared light noise 8c in sunlight or the like is incident into the near infrared polarizer 4b, the external near infrared light noise 8c is in a polarized state different from that of the incidence light 8b or is in an unpolarized state. Therefore, most of the external near infrared light noise 8c is absorbed by the near infrared polarizer 4b and does not reach the light receiving section 4. Accordingly, noise generated from external near infrared light can be reduced, and a high detection accuracy can be obtained.

Regarding the visible flux 5 and external light 155, in a case where the visible light polarizer 151 and the retardation plate 152 form a circular polarization plate, the effect of improving contrast can be obtained according to the principle of the OLED panel antireflection principle that is known in the related art. The near infrared polarizer 4b is present on the visible side further than the visible light polarizer 151, and thus is not affected by this principle. In addition, the transmission axis of each of the near infrared polarizer 4b and the visible light polarizer 151 can be freely designed.

FIG. 16 also shows the image display system of FIG. 14 in more detail.

A display device (image display apparatus) 160 includes a visible light polarizer 161, the near infrared polarizer 4b, a retardation plate 162, and the substrate 1 including the pixels 2 and the light receiving section 4 in this order from the emission surface 6 to the substrate 1. As the near infrared polarizer 4b approaches the light receiving section 4, the effect of reducing noise or stray light can be exhibited. Therefore, in order to improve the detection sensitivity or the amount of information acquired, the configuration shown in FIG. 16 is preferable to the configuration of FIG. 15.

The near infrared light 8a emitted from the near infrared light source 9 having polarization emission properties is reflected from a face of a user to become the incidence light 8b, and the incidence light 8b is incident from the emission surface 6 into the display device 160. The visible light polarizer 161 has transmittance to light in a near infrared range and allows transmission of the incidence light 8b as near infrared light irrespective of a transmission axis thereof. The near infrared polarizer 4b has a transmission axis that matches with a polarization direction including a large amount of the incidence light 8b, and the light transmitted through the near infrared polarizer 4b transmits through the retardation plate 162 and arrives at the light receiving section 4. It is preferable that the retardation plate 162 has near infrared transmittance. In a case where the incidence light 8b transmits through the retardation plate 162, the polarized state of the incidence light 8b may change. However, the element forming the light receiving section 4 does not have polarization selectivity, and thus the incidence light 8b can be detected without any effect.

The external near infrared light noise 8c in sunlight or the like transmits through the visible light polarizer 161 to be incident into the near infrared polarizer 4b as in the incidence light 8b. In this case, the external near infrared light noise 8c is in a polarized state different from that of the incidence light 8b or is in an unpolarized state. Therefore, most of the external near infrared light noise 8c is absorbed by the near infrared polarizer 4b and does not reach the light receiving section 4. Accordingly, noise generated from external near infrared light can be reduced, and a high detection accuracy can be obtained.

The visible flux 5 formed from the pixels 2 is in a unpolarized light and does not change in polarized state even after transmitting through the retardation plate 162. The near infrared polarizer 4b has transmittance in a visible range. The near infrared polarizer 4b has a phase difference in a visible range. The polarized state of the visible flux 5 does not change as in the retardation plate 162. In the visible light polarizer 161, only a part of polarized light is transmitted, is emitted from the emission surface 6, and is observed as image light.

On the other hand, in a case where external visible light 165 is incident from the emission surface 6 and transmits through the visible light polarizer 161, only a linearly polarized light component parallel to the paper plane can be made to be incident into the visible light polarizer 161. Further, the light is reflected from the substrate 1 or from a wiring line, an electrode or the like formed on the substrate 1 through the near infrared polarizer 4b and the retardation plate 162. In this case, by disposing the near infrared polarizer to have an absorption axis perpendicular to the paper plane as shown in the drawing, a slow axis of a phase difference of the near infrared polarizer in a visible range is also perpendicular to or parallel to the paper plane. Therefore, the external visible light transmitted through the near infrared polarizer is maintained as linearly polarized light. By adjusting the phase difference Re(550) of the retardation plate 162 such that the ¼ wavelength and the slow axis is at 45° or 135° with respect to the visible light polarizer 161, the external visible light 165 that arrives at the substrate 1 or the wiring line, the electrode, or the like formed on the substrate 1 is circularly polarized light and is converted into circularly polarized light in an opposite direction by reflection. Next, the circularly polarized light is converted by the retardation plate 152 into linearly polarized light perpendicular to the paper plane, and is incident into and absorbed by the visible light polarizer 161 while the polarized state does not change in the near infrared polarizer 4b. This way, an internal reflection component of the external visible light is removed, and image display having excellent contrast can be performed.

A laminate including the retardation plate 152 and the near infrared polarizer may have an action of a ¼ wave plate with respect to light having a wavelength of 550 nm.

FIG. 16 shows an example, the transmission axis of the near infrared polarizer is disposed perpendicular to the transmission axis of the visible light polarizer. Examples of a configuration in which the same effect can be obtained include:
a case where the transmission axis of the near infrared polarizer is disposed parallel to the transmission axis of the visible light polarizer, and
a case where the transmission axis of the near infrared polarizer is disposed at 45° or 135° with respect to the transmission axis of the visible light polarizer and a phase difference Re(550) of the near infrared polarizer in a visible range is ½ wavelength.

In this case, as the retardation plate that can be used in combination, any retardation plate can be used as long as it exhibits ¼ wave plate characteristics, and examples thereof include a polymer drawn retardation plate, a liquid crystal retardation plate formed by immobilizing a liquid crystal compound in an alignment state, and a structural birefringence plate. In addition, an optical compensation layer may be further provided in order to obtain sufficient internal antireflection properties for the external visible light 165 incident from an oblique direction.

With the above-described configuration, the transmission axis of the near infrared polarizer can be limited to be parallel to, perpendicular to, or 45° (135°) with respect to the transmission axis direction of the visible light polarizer. Here, in a case where the transmission axis of the near infrared polarizing plate needs to be provided at another angle due to restrictions on the device, or in order to further improve the detection accuracy and the amount of information acquired, the transmission axis of the near infrared polarizing plate can also be provided at an angle other than the above-described angles with respect to the transmission axis direction of the visible light polarizing plate.

In this configuration, for example, the transmission axis of the near infrared polarizer can be disposed at 75°±10° with respect to the transmission axis of the visible light polarizer, and the phase difference Re(550) of the near infrared polarizer in a visible range can be in a range of 180 nm to 360 nm. In this case, in the retardation plate, a slow axis can be disposed at 15°±10° with respect to the transmission axis of the visible light polarizer, and a phase difference Re(550) can be in a range of 115 nm to 155 nm.

In addition, in a case where the near infrared polarizer 4b further approaches the light receiving section 4 to improve the detection accuracy and the amount of information acquired, regarding the visible light polarizer 161, the near infrared polarizer 4b, and the retardation plate 162 in FIG. 16, the visible light polarizer, the retardation plate, and the near infrared polarizer can be disposed in this order from the visible side.

In this case, in order to exhibit the same optical action for each of the luminous fluxes shown in FIG. 16, the following configuration can be adopted in which a slow axis of the retardation plate is at 75°±10° with respect to a transmission axis of the visible light polarizer, a phase difference Re(550) of the retardation plate is in a range from 180 nm to 360 nm, a slow axis of the near infrared polarizer is at 15°±10° with respect to the transmission axis of the visible light polarizer, and a phase difference Re(550) of the near infrared polarizer in a visible range is in a range from 115 nm to 155 nm.

In addition, the retardation plate can also be a twisted liquid crystal layer having a helical axis in a thickness direction. By appropriately adjusting the product of the refractive index anisotropy Δn per unit thickness and the thickness, the twisted angle, and the direction of a surface director in the retardation plate depending on the phase difference in a visible range and the transmission axis direction in the near infrared polarizer used in combination, a laminate including the retardation plate and the near infrared polarizer can be a laminate that functions as a wide band ¼ wave plate in a visible range.

In addition, in another preferable aspect, FIG. 17 shows a display device (image display apparatus) 170 including a patterned polarizer 171, a retardation plate 172, the light receiving section 4, and the pixels 2 in this order from the emission surface 6 to the substrate 1, an image display system including the display device 170, the patterned polarizer 171 including a near infrared polarizer region 171a having polarization selectivity to near infrared light and a visible light linear polarizer region 171b having polarization selectivity to visible light in a patterned manner.

It is preferable that the near infrared polarizer region 171a is provided at a position corresponding to the light receiving section 4, transmission of the incidence light 8b as near infrared light incident from the face of the target is allowed, and the external near infrared light noise 8c is absorbed and removed. As a result, the detection accuracy or the amount of information acquired in the image display apparatus according to the embodiment of the present invention can be improved. The visible light linear polarizer region 171b forms a circular polarization plate that acts in a visible range together with the retardation plate 172, internal reflected light from the substrate or the like can be removed, and the display contrast can be improved.

Optionally, a visible light transmitting unit 171c is provided at a position corresponding to the pixels 2, and the visible flux 5 released from the pixels 2 may be transmitted without being absorbed. By providing visible light transmitting unit 171c at the position corresponding to the pixels 2, the display brightness of the display device 170 can be improved, and higher display contrast can be obtained.

This way, by applying the patterned polarizer 171, the interference of each of the optical elements between the visible flux and the near infrared light can be minimized, which is preferable. As the patterned polarizer, the patterned polarizer described above using FIG. 12c can be applied.

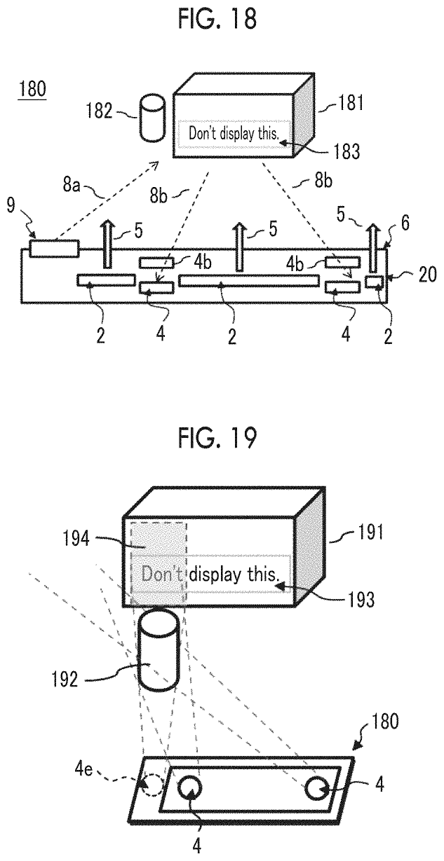

As shown in FIG. 18, one preferable aspect of the image display system including the image display apparatus according to the first embodiment of the present invention is an image display system 180 including: the display device 20 according to the embodiment of the present invention; the light source 9 that is capable of emitting the near infrared light 8a to measurement targets 181 and 182; and a light detection and ranging (LIDAR) system or an object recognition system that detects the incidence light 8b obtained by causing the near infrared light 8a emitted from the light source 9 to be reflected from measurement targets 181 and 182 using the light receiving section 4 through the near infrared polarizer 4b. The user can use the above-described LIDAR system or the object recognition system while watching an image that is formed of the luminous flux 5 of visible light formed from the plurality of pixels 2, the obtained information is processed through an arithmetic circuit (not shown), and two-way communication where the acquired information is mounted on the display image in real time or various services using an invisible marking 183 given to the measurement target can be provided.

As in the problem of the above-described facial expression sensing or the face recognition system, in the image display system including the LIDAR system or the object recognition system, an imaging element provided in a side edge portion is used. In this imaging element, the field of view (FOV) per element is narrow, a plurality of imaging elements needs to be provided at different positions in order to obtain a necessary amount of information acquired for recognition, and there is a problem in size, weight, and design.

However, with the image display system according to the embodiment of the present invention, a plurality of light receiving sections can be provided to be integrated with the display screen. Therefore, there is no problem in size and design, a necessary number of light receiving sections including a necessary number of pixels can be provided, and a sufficient amount of information can be acquired.

For example, as shown in FIG. 19, a case where object recognition is performed on a second measurement target 192 that is laid behind a first measurement target 191 will be discussed. In the related art, in the image display system 180 including the LIDAR system or the object recognition system, an image that is acquired by an imaging element 4e provided in the side edge portion is calculated to grasp each of the positions. However, in a blocked region 194 of the second measurement target 192 that is blocked by the first measurement target 191, information cannot be obtained. In a case where an invisible marking 193 given to the first measurement target 191 is covered with the blocked region 194, an invisible marking 193 is meaningless on the system.

On the other hand, in the image display system including the LIDAR system or the object recognition system, by applying the image display system 180 according to the embodiment of the present invention, a plurality of light receiving sections 4 can be provided to be spaced from each other by the maximum width of the screen. Therefore, the blocked region 194 can be reduced, and a larger amount of the information of the first measurement target 191 can be obtained.

As the image display panel in the display device 20 to be used, various light emitting panels used in the image display system including the face recognition system or the facial expression recognition system can be used. In addition, an element that is necessary for forming an image in the light emitting panel or a visible light polarizer can be further provided to improve the display contrast. Regarding the arrangement, the retardation plate that is optionally provided, and the specific aspect thereof, the configuration and the members described in the image display system including the face recognition system or the facial expression recognition system can be applied. For example, the image display apparatus can include a circular polarization plate that is provided on the emission surface to reduce external light reflection. The circular polarization plate is a laminate in which a visible light polarizer and a retardation plate are laminated, and includes the visible light polarizer, the retardation plate, and the substrate in this order from the emission surface to the substrate.

Alternatively, as in the example shown in FIG. 16, the image display apparatus may have a configuration in which the near infrared polarizer is provided between the visible light polarizer and the retardation plate, the near infrared polarizer has transmittance in a visible range, and a laminate including the retardation plate and the near infrared polarizer has an action of a ¼ wave plate with respect to light having a wavelength of 550 nm. Even in this case, an internal reflection component of the external visible light is removed, and image display having excellent contrast can be performed.

In addition, the description shows an example, the transmission axis of the near infrared polarizer is disposed perpendicular to the transmission axis of the visible light polarizer. Examples of a configuration in which the same effect can be obtained include:
a case where the transmission axis of the near infrared polarizer is disposed parallel to the transmission axis of the visible light polarizer; and
a case where the transmission axis of the near infrared polarizer is disposed at 45° or 135° with respect to the transmission axis of the visible light polarizer and a phase difference Re(550) of the near infrared polarizer in a visible range is ½ wavelength.

As the invisible markings 183 and 193, for example, a marking that absorbs only light in a near infrared range and is transparent to visible light, or a marking that reflects only light in a near infrared range and is transparent to visible light can be applied, and can be appropriately selected depending on the surface to which the marking is given has specular reflectivity, diffuse reflectivity, or absorption properties in a near infrared range. The marking can be a character or a symbol, and may be an encoded symbol such as a bar code or a two-dimensional bar code.

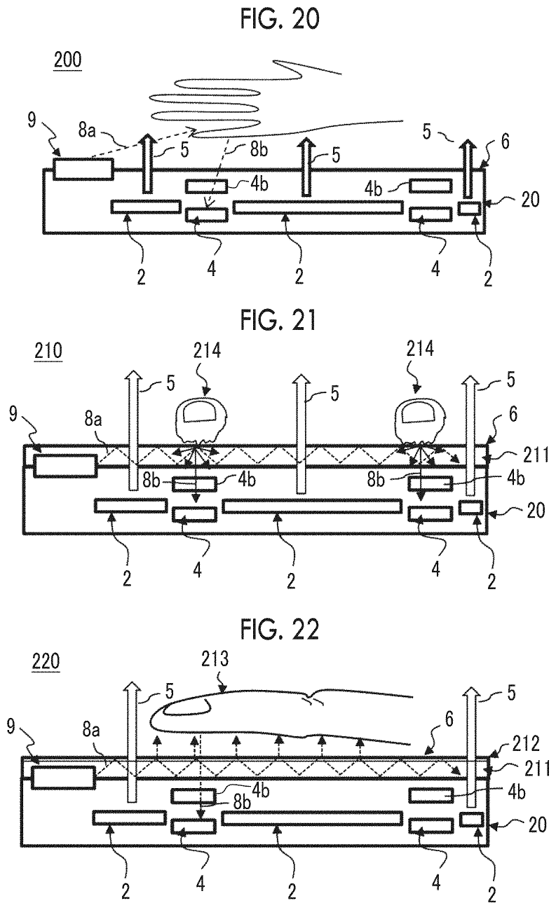

As one aspect of the image display system including the image display apparatus according to the first embodiment of the present invention, an image display system having a biological sensing function (biometric system) such as a fingerprint sensor (fingerprint recognition system), a vein recognition system, or a blood flow sensor will be described using FIG. 20.

One preferable aspect of the image display system including the image display apparatus according to the first embodiment of the present invention is an image display system 200 including: the display device 20 according to the embodiment of the present invention; a light source 9 that is capable of emitting the near infrared light 8a to a portion of a body of a user such as a hand, a finger, a palm, or a skin; and a biological sensing function (biometric system) such as a fingerprint sensor (fingerprint recognition system, a vein recognition system, and a blood flow sensor that detect the incidence light 8b obtained by causing the near infrared light 8a emitted from the light source 9 to transmit through or to be reflected from the portion of the body of the user using the light receiving section 4 through the near infrared polarizer 4b. The observer can use the fingerprint sensor, the vein recognition system, or the blood flow sensor by bringing the portion of body into contact with the emission surface 6 of the display device 20 or making the portion of the body approach the emission surface 6, and the obtained information is processed using an arithmetic circuit (not shown) and can be used for releasing a security lock of a device or a service or providing a service corresponding to the detected blood flow state or the state of the skin, or for active control of the device.

In the image display system having the biological sensing function in the related art, a dedicated detection element provided in a side edge portion of the device is used. However, since the measurement target is a portion of a body such as a finger, a palm, or a skin that requires a predetermined area or more, a space required for the element needs to be increased, and there is an unavoidable problem in device layout, weight, space, or design. In addition, for the fingerprint recognition, a system that recognizes a plurality of fingers at the same time in order to further improve the security level is disclosed. There is an unavoidable problem in weight, space, or design in that the dedicated detection element is provided at a plurality of positions for fingerprint recognition.

However, with the image display system according to the embodiment of the present invention, a plurality of light receiving sections can be provided to be integrated with the display screen. Therefore, there is no problem in size and design, and a sufficient area for facing or contacting the portion of the body can be secured. In addition, a plurality of contact portions can be provided can be provided at any positions on the display screen.

As the image display panel in the display device 20 to be used, various light emitting panels used in the image display system including the face recognition system or the facial expression recognition system can be used. In addition, an element that is necessary for forming an image in the light emitting panel or a visible light polarizing plate can be further provided to improve the display contrast. Regarding the arrangement, the retardation plate that is optionally provided, and the specific aspect thereof, the configuration and the members described in the image display system including the face recognition system or the facial expression recognition system can be applied.

In particular, regarding the light source 9, in a case where the measurement target is required to contact or approach the image display system, there is a restriction on a relative position between the near infrared light source and the measurement portion. An image display system including a fingerprint sensor, a vein recognition system, and a blood flow sensor that is one preferable aspect of the present invention can include: a near infrared light source; and a light guide plate that guides near infrared light emitted from the near infrared light source. As a preferable aspect, FIG. 21 shows an image display system 210 including a biological sensing function such as a fingerprint sensor, a vein recognition system, or a blood flow sensor that is provided such that a light guide plate 211 forms the emission surface 6 of the display device 20. In a case where a finger 214 touches the emission surface 6, the light guide state only in a portion that is touched by a convex portion of a fingerprint changes, the near infrared light Sa that is emitted from the near infrared light source 9 and propagates in the light guide plate 211 is scattered from an interface between the finger and the light guide plate, and a part thereof as the incidence light 8b travels to the light receiving section 4. By detecting this scattered light, a function as the fingerprint sensor can be exhibited. It is preferable that the light guide plate 211 has transmittance in a visible range. In addition, the light guide plate 211 may function as a cover plate of the display device 20 and may further include an antifouling layer, an antireflection layer to visible light, an antiglare layer, or a hard coat layer that is provided on a surface thereof. In addition, in order to reduce noise to suppress erroneous detection in a non-contact region, it is preferable that the near infrared light source 9 is a polarized light source. As the near infrared light source, a laser diode or a combination of a near infrared light emitting LED element and a polarization selection element can be preferably used.

In addition, in order to detect a part of the skin or the body that is adjacent to the device but is not in contact with the device or to emit near infrared light to a contact surface more actively than a change in light guide state caused by the surface contact, by providing a scattering layer or a diffraction function layer to the light guide plate, a larger amount of near infrared light can be emitted to the measurement target, and sensing relating to a vein pattern, a heart beat, a blood flow amount, and the surface state of the skin can be performed.

As a preferable aspect, FIG. 22 shows an image display system 220 including a biological sensing function such as a fingerprint sensor, a vein recognition system, or a blood flow sensor that is provided such that the light guide plate 211 on which a scattering layer or a diffraction function layer is provided forms the emission surface 6 of the display device 20. The scattering layer or the diffraction function layer 212 provided on the surface of the light guide plate 211 emits a part of the guided near infrared light 8a from the emission surface to a measurement target 213. The incidence light 8b as near infrared light having undergone reflection, absorption, scattering, or a combination thereof depending on the measurement target is incident from the emission surface 6 into the display device 20 and is detected by the light receiving section 4.

It is preferable that the scattering layer to be provided has a diffuse maximum in a near infrared range, and it is more preferable that the scattering layer that is provided has a diffuse maximum in 850 to 1000 nm. As the diffraction function layer to be provided, for example, a blazed hologram layer, a relief hologram layer, a volume hologram layer, a liquid crystal diffraction layer, or a dielectric multi-layer film layer is preferable, and a liquid crystal diffraction layer is more preferable from the viewpoint that it has polarization selectivity and can reduce noise generated from the incidence light 8b from the detection target.

The scattering layer or the diffraction function layer to be provided is provided on the emission surface side of the light guide plate 211 in FIG. 21. The preferable aspect of the present invention is not limited to this configuration, and the scattering layer or the diffraction function layer may be provided on a surface of the light guide plate 211 opposite to the emission surface or may be provided in the light guide plate 211. The scattering layer or the diffraction function layer may be provided in a combination of the above-described positions.

### Second Embodiment

An image display system according to a second embodiment of the present invention includes an image display apparatus including: a light receiving section having sensitivity in an invisible range; an image display panel that includes a substrate and a plurality of pixels disposed on the substrate; and an emission surface that emits a luminous flux formed from the plurality of pixels, in which the plurality of pixels include a pixel group that forms a luminous flux in a visible range and a pixel that forms a luminous flux in an invisible range to which the light receiving section has sensitivity, the plurality of pixels are disposed at positions overlapping the substrate in a view from a direction perpendicular to the emission surface, the light receiving section is disposed to receive the invisible light that is emitted from the pixel forming the luminous flux in an invisible range to a detection target through the emission surface and is reflected or scattered from the target, and receives only the luminous flux in an invisible range, and the image display apparatus includes a near infrared polarizer having polarization selectivity in a near infrared range that is provided between the pixel forming the luminous flux in an invisible range and the emission surface.

In the related art, in general, an invisible light source for sensing is provided separately from a visible light emitting section, and the size of the invisible light source for sensing is small due to the space and the weight of the device and the design. In this invisible light source that is close to a point light source, there is a limit in information that can be acquired even in a case where the performance of the light receiving section of the image display system is improved.

However, by applying the image display system according to the embodiment of the present invention, the light source unit can be provided in a sufficient area of the image display system while minimizing a space other than the emission region. Therefore, a device including the image display system having excellent detection accuracy or amount of information acquired can be provided.

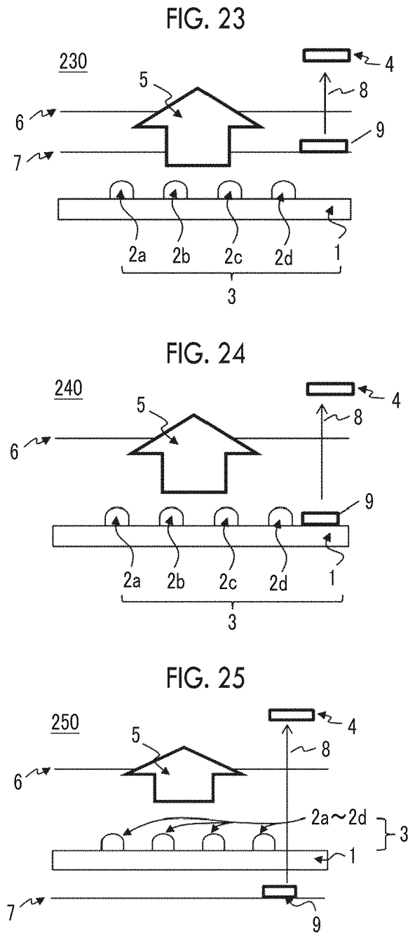

One preferable aspect of the above-described second embodiment will be described using FIG. 23. An image display system 230 includes an image display panel 3 including a plurality of pixels 2a to 2d disposed on a substrate 1, and a luminous flux 5 in a visible range is formed from the pixels 2a to 2d. The luminous flux 5 in a visible range is emitted from an emission surface 6 to be recognized as image light by a user or to irradiate an object. Here, the light source 9 that emits the invisible light 8 can be provided between the emission surface 6 and the image display panel 3. In addition, as shown in FIG. 23, the light source 9 is disposed at a position overlapping the image display panel 3 in the plane direction. The light source 9 that emits invisible light may be provided on, for example, a substrate 7 having transmittance to the luminous flux 5. The invisible light 8 emitted from the light source 9 is reflected from or transmits through the measurement target and is detected by the light receiving section 4. In FIG. 23, the measurement target is not shown, and the invisible light 8 is directly incident from the light source 9 into the light receiving section 4. Regarding this point, the same can also be applied to FIGS. 24, 25, 26, and 28. In addition, in the image display system 230 shown in FIG. 23, the near infrared polarizer is not shown. Regarding this point, the same can also be applied to FIGS. 24, 25, 26, and 28.

In addition, one preferable aspect of the second embodiment will be described using FIG. 24. The image display panel 3 and the emission surface 6 in an image display system 240 are the same as those of FIG. 23. The light source 9 that emits invisible light is provided on the image display panel 3. “Being provided on the image display panel 3” described herein is not limited to being simply provided on the emission surface 6 side of the image display panel 3, and represents being integrated with the image display panel by being provided over or below an electrode layer, a passivation layer, an insulating layer, or the like provided in the image display panel.

Still another preferable aspect of the second embodiment will be described using FIG. 25. The image display panel 3 and the emission surface 6 in an image display system 250 are the same as those of FIG. 1. The light source 9 that emits invisible light is provided on a surface of the image display panel 3 opposite to the emission surface 6. The light receiving section 4 may be provided on the substrate 7 that is provided separately from the image display panel 3, or may be provided adjacent to the surface of the image display panel 3 opposite to the emission surface 6 side.

Here, the substrate 1 of the image display panel 3 allows transmission of the invisible light 8 released from the light source 9 that emits invisible light. The transmission described herein may represent that invisible light as a target reaches an object from the light source 9 that emits invisible light through a void or a pore provided in the substrate without being blocked. In addition, the substrate itself may have transmittance in a wavelength range of invisible light as a target.

In addition, as in the example shown in FIGS. 24 and 25, the light source 9 is disposed at a position overlapping the image display panel 3 in the plane direction.

As the above-described image display panel, a light emitting panel such as a LED array, an OLED panel, a micro LED panel, or a mini LED panel can be applied. In addition, the image display panel may be a combination of a transmission type liquid crystal panel and a backlight unit.

As the light emitting panel and the substrate and the pixels in the image display panel, those described above in the first embodiment can be applied. In addition, as the examples of the emission surface 6, those described above in the first embodiment can be applied. The visible flux released to the outside of the system is used, for example, for illuminating an object and provides visual information to an observer. In one preferable aspect of the present invention, the image display apparatus displays an image and/or information using the luminous flux in a visible range emitted from the image display panel.

As the light receiving section, a photodetection element such as a photodiode or a phototransistor having sensitivity in an invisible range and not having sensitivity to visible light can be applied. It is preferable that the light receiving section is a photodiode or a phototransistor having sensitivity only in a near infrared range and not having sensitivity in a visible range. As the photodetection element, an organic photodiode (OPD) or an organic phototransistor (OPT) may be applied.

The light receiving section detects a target by receiving invisible light reflected from a detection target.

A position where the light receiving section is provided is not particularly limited, the light receiving section may be provided adjacent to the image display panel or to overlap the image display panel or may be provided an independent device. As the target detected by the light receiving section, the light receiving section can detect a three-dimensional shape of an object, a surface state of the object, and at least one selected from an eye movement, an eye position, a facial expression, a face shape, a vein pattern, a blood flow, a pulse, a blood oxygen saturation level, a fingerprint, or an iris of a user. It is preferable that the light receiving section is provided at a position suitable for the measurement target.

As the light source (light emitting section), any light source can be applied. Typically, a LED element, an OLED element, or a laser element having near infrared light emitting properties is preferably used. A surface-emitting laser, in particular, a vertical cavity surface-emitting laser is also preferably used. In a case where the surface-emitting layer is used as the light emitting section, the light emitting section may be used as a single element or as an array consisting of a plurality of elements. By providing surface-emitting layer as the array, the luminous flux having a controlled wave front or pattern can be formed. In addition, as the light emitting section, by providing a single element and linking the single element with a plurality of light emitting sections, the luminous flux having a controlled wave front or pattern may be formed. In order to improve the detection accuracy to increase the amount of information acquired, it is preferable that the invisible light release from the emission surface formed by a light emitting section has a controlled wave front, pattern, or the like.

As the near infrared polarizer having polarization selectivity in a near infrared range, those described in the first embodiment can be used. In addition, as in the first embodiment, in the near infrared polarizer having polarization selectivity in a near infrared range, a single plate transmittance at a wavelength of 850 nm is preferably less than 50%.

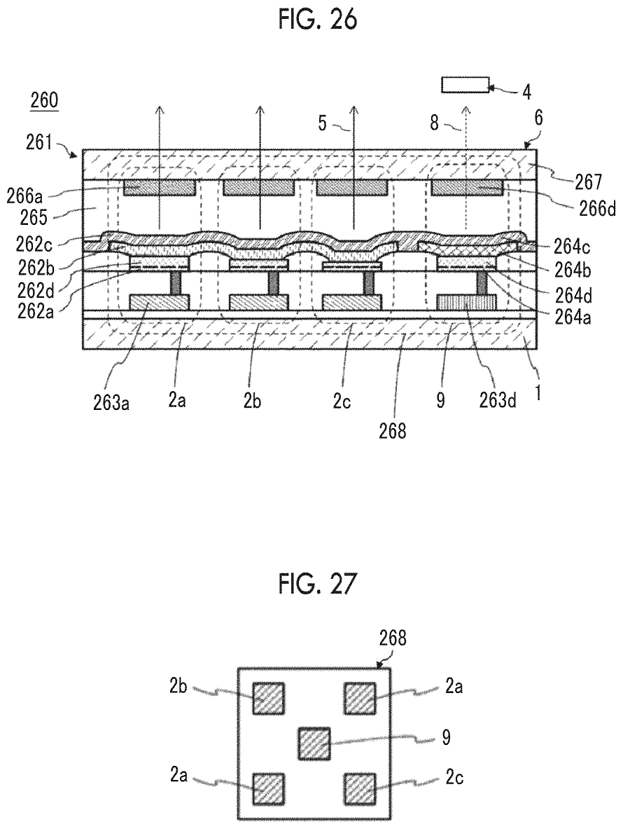

As an example of the image display system according to the second embodiment of the present invention, FIG. 26 shows an image display system 260 including an OLED display device (image display apparatus) 261 where the pixels 2 and the light emitting section 9 are provided on a substrate. It is preferable that the light emitting section (light source) 9 and the light receiving section 4 of the display device according to the embodiment of the present invention have an emission band and sensitivity to near infrared light. In the following description, it is assumed that the light emitting section 9 is a near infrared light emitting device and the light receiving section 4 is a near infrared light-receiving element.

Transistor layers 263a and 263d are provided on the substrate 1 and are connected to a lower electrode 262a of the pixel 2 and a lower electrode 264a of the light emitting section 9. A visible EL light emitting layer 262b and a transparent electrode 262c or a near infrared EL light emitting layer 264b and a transparent electrode 264c are laminated on the lower electrode 262a and the lower electrode 264a, respectively, and are connected to an electrode. Each of the lower electrodes may be a reflecting electrode to improve the light extraction efficiency. In addition, transparent conductive layers 262d and 264d may be provided between the visible EL light emitting layer and the lower electrode and between the near infrared EL light emitting layer and the lower electrode, respectively to further improve the light emitting layer using a resonance structure.

Further, a cover plate 267 is provided above the transparent conductive layers 262d and 264d through an insulating layer 265. Optionally, colored layers 266a and 266d may be provided on the substrate side of the cover plate 267. For example, by using a white light emitting material as the visible EL light emitting layer 262b and using the colored layer 266a as a color filter having transmittance to each of red, green and blue, full color display using the pixels 2a to 2c may be performed. In addition, by using a visible EL light emitting layer that emits each of red, green and blue as the visible EL light emitting layer 262b and allowing the colored layer 266a to act as a notch filter, the color reproducibility may be improved. In the description using FIG. 26, the emission surface 6 of the image display apparatus 261 is a visible side surface of the cover plate 267.

The visible flux 5 formed from the pixels 2a to 2c is recognized as a display image to an observer. The near infrared flux 8 released from the light emitting section 9 is emitted to a detection target (not shown) and is detected by the light receiving section 4 such that various kinds of sensing can be performed. The pixels 2a to 2c and the light emitting section 9 may form one pixel unit 268.

FIG. 27 is a conceptual diagram showing an example of the arrangement of the pixel unit 268 in a case where a part of the light emitting panel of FIG. 26 is observed from the top. By integrating the pixels 2a to 2c and the light emitting section 9 with each other, patterned light that is controlled as the display device can be emitted to a target. Therefore, the detection accuracy can be improved to increase the amount of information acquired.

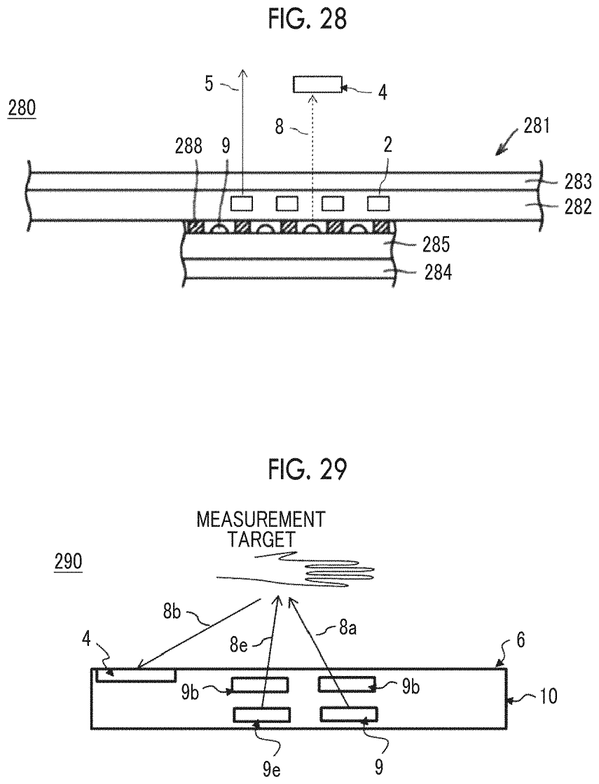

As another example of the image display system according to the second embodiment of the present invention, FIG. 28 shows an image display system 280 including: an OLED panel (light emitting panel) 282 including the pixels 2 on a substrate; an image display apparatus (OLED display device) 281 including the light emitting section 9 that is provided on the side of the substrate opposite to the emission surface 6; and the light receiving section 4.

A cover plate 283 is provided on the observer side of the OLED panel 282 including the pixels 2 on the substrate. In the configuration shown in FIG. 28, the observer side surface of the cover plate 283 is the emission surface 6. The OLED panel 282 can perform image display using visible light formed from the pixels 2.

The light emitting section 9 that emits near infrared light is provided on a circuit layer 285 provided on a second substrate 284, and is provided to be positioned on the side opposite to the emission surface 6 with respect to the substrate (not shown) of the OLED panel 282. In order to fix the relative position to the OLED panel 282 and to prevent the light emitting section 9 from interfering with each other, a light shielding spacer 288 can be provided.

The near infrared flux 8 released from the light emitting section 9 transmits through an opening portion or a transmitting portion of the OLED panel 282, is emitted from the emission surface 6 to a target, and is detected by the light receiving section 4. Therefore, in the OLED panel 282, it is preferable that each of the layers has transmittance to near infrared light or that a near infrared light transmission region or opening portion is provided in a non-pixel region.

As the light emitting section 9, the above-described various near infrared light emitting elements can be used. In this case, since it is not necessary to share a circuit with the OLED element forming the pixels 2, a strong and polarizable light source such as a laser diode or a surface-emitting laser can be applied. From the viewpoint of improving the detection accuracy to increase the amount of information acquired, it is preferable that the above-described laser diode, surface-emitting laser, or the like is used.

The action of the image display system according to the second embodiment of the present invention will be described using FIG. 29. A head-mounted display 290 shown in FIG. 29 includes the light emitting section 9 in the image display apparatus 10 or the image display system including the image display apparatus 10, in which the near infrared light 8a emitted from the emission surface 6 is polarized light. It is more preferable that the light receiving section 4 has polarization selectivity or polarization sensitivity.

The near infrared light 8a and near infrared light 8e as polarized light emitted from near infrared light emitting sections 9 and 9e in the image display system are emitted to a measurement target, are converted into the detection luminous flux (incidence light) 8b, and are incident into the light receiving section 4. Unlike a case where light is emitted from a single near infrared light source to a measurement target in the related art, the detection luminous flux 8b is emitted from a plurality of light sources such that the light amount can increase and the detection accuracy can be improved. In addition, by adjusting the polarized states of the near infrared light 8a and the near infrared light 8e to be different from each other, a difference in information from measurement targets depending on the difference between the polarized states can be acquired, and the amount of information acquired increases.

FIG. 29 shows that near infrared light components 8a and 8e and the detection luminous flux 8b are shown to have a relationship of reflection with respect to a measurement target. The image display system according to the embodiment of the present invention is not limited only to the reflection system. The light receiving section 4 may be provided separately from the image display apparatus 10 according to the embodiment of the present invention such that the near infrared light 8a or 8e and the detection luminous flux 8b have a relationship of transmission with respect to a measurement target. In addition, the measurement target may be any target. Examples of the measurement target include a portion of a biological body of a user such as a hand, a finger, a palm, or a skin, a vein pattern, a face, an eyeball, a lip, and a limb of a user, motions or gestures thereof, an object such as a specific interface device or a surrounding object, and a state of a surrounding environment such as a temperature, a humidity, or a composition of particles or gas.

As the light emitting section, as described above, typically, a LED element, an OLED element, or a laser element having near infrared light emitting properties is preferably used. A surface-emitting laser, in particular, a vertical cavity surface-emitting laser is also preferably used. The laser element has polarization emission properties and thus can be preferably used. In a case where the light emitting element is an element that does not emit polarized light, in order to polarize the near infrared light 8a emitted from the emission surface, a near infrared polarizer 9b having polarization selectivity in a near infrared range may be further provided between the light emitting sections 9 and 9e and the emission surface 6 or between the emission surface and a measurement target.

As the light receiving section 4, any light receiving section can be applied, and typically a photoelectric conversion element such as a photodiode having sensitivity in a near infrared range can be used. In addition, optionally, a near infrared polarizer having polarization selectivity in a near infrared range, a retardation element, or an active element where polarization selectivity or a phase difference can be electrically modulated may be provided on the light receiving section side.

As the near infrared polarizer having polarization selectivity in a near infrared range, various polarizers described in the first embodiment can be used. In addition, regarding the wavelength selectivity, various wavelength selectivity described in the first embodiment can be applied depending on the purposes.

In a case where the near infrared polarizer overlaps an optical path of visible light in the image display system, it is preferable that the near infrared polarizer does not have a polarization property in a visible range or has transmittance in a visible range. As this near infrared polarizer, those described in the first embodiment can also be adopted. By adopting this optical system, an optical system in which the paths of near infrared light and visible light do not overlap each other can be configured.

The image display system can be applied to, for example, a wearable device such as a head-mounted display, a mobile display device such as a smartphone or a tablet, or a stationary display device such as a television or a lighting.

Preferable aspects of the devices will be described using the following specific examples.

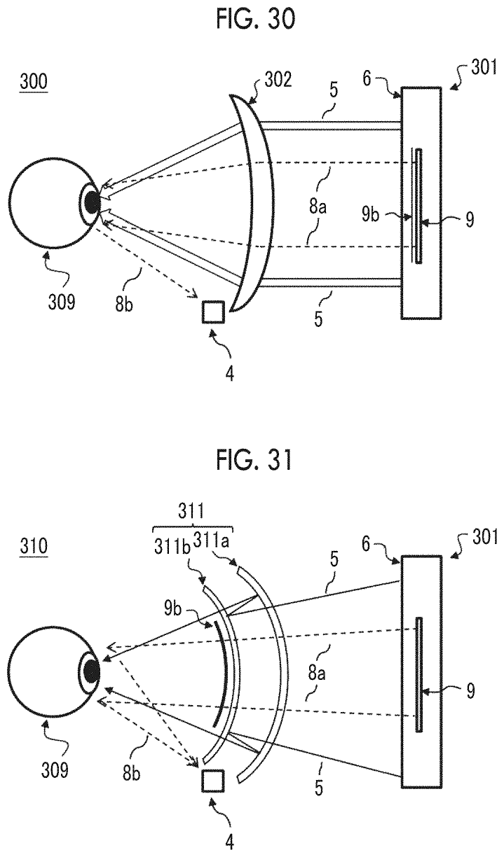

As shown in FIG. 30, one preferable aspect of the image display system according to the second embodiment of the present invention is a head-mounted display 300 including a display device (image display apparatus) 301 in the image display system according to the embodiment of the present invention, an eyepiece 302, the light receiving section 4, and an eye tracking system that detects the incidence light 8b as near infrared light emitted from the display device 301 to an eyeball 309 and reflected from the eyeball 309 using the light receiving section 4. An action of the eyepiece 302 is the same as described above in the first embodiment. Information regarding an eye position and a visual line obtained from the eye tracking can be used for rendering the projected image or for an operation of a graphic interface embedded in a display image.

In the related art, an eye tracking system of a head-mounted display is provided not to overlap a display optical system. Therefore, a restriction on a space is severe, and it is necessary to emit near infrared light at a large angle with respect to an eyeball, in particular, an eye direction and with a small number of light sources. Therefore, there are problems, for example, in that a sufficient amount of light does not reach the light receiving section, desired detection light cannot be obtained depending on polarization dependence of surface reflection even in a case where polarized light is emitted, and the information that can be acquired has a limit. With the image display system according to the embodiment of the present invention, the display optical system and the eye tracking optical system can be housed in a common space, and eye tracking having excellent detection accuracy can be performed compactly at an appropriate emitted beam angle with a large amount of information acquired.

In addition, a case where a so-called pancake lens including a half mirror and a reflective polarizer is used as the eyepiece will be described using FIG. 31. The structure, the action, and the gain of the pancake lens are the same as described above in the first embodiment.

In one preferable aspect of the second embodiment of the present invention, a reflective polarizer 311b and a half mirror 311a can have transmittance in a near infrared range. In the reflective polarizer 311b and the half mirror 311a, a single plate transmittance at 850 nm is preferably 80% or more, more preferably 85% or more, and still more preferably 90% or more. With this configuration, the incidence light 8b that is emitted from the near infrared light source 9 to the eyeball 309 to be incident into the light receiving section 4 can arrive at the light receiving section 4 without being reflected from the pancake lens 311.

This configuration is advantageous in that, for example, in a case where eye tracking is performed by emitting a predetermined near infrared light pattern to an eyeball using the light emitting section 9 and detecting deformation and loss of the pattern caused by reflection and/or absorption in the pupil or the cornea, the irradiation pattern can be designed irrespective of an eye box formed by the pancake lens. This advantageous effect is particularly preferable for the image display with a sensor according to the embodiment of the present invention from the viewpoint that a large eye movement and/or a fine movement of the pupil can be detected.

In this case, for example, in a case where the pancake lens system includes a ¼ wave plate, even in a case where the near infrared light 8a emitted from the near infrared light source 9 through the emission surface 6 is polarized light, the polarized state of the near infrared light 8a may changes at the eyeball 309 due to the effect of the ¼ wave plate or the like. In order to improve the detection accuracy and to increase the amount of information acquired, an additional retardation layer may be provided at any position on the optical path of the near infrared light 8a from the near infrared polarizer 9b such that this change in polarized state is compensated for to obtain a desired polarized state at the eyeball. In addition, the additional near infrared polarizer 9b may be further provided on an eyeball 309 side surface of the reflective polarizer 311b of the pancake lens 311.

As the near infrared polarizer 9b that is provided on the eyeball 309 side surface, the near infrared polarizer described in the first embodiment can be used as long as it can compensate for the polarized state. The single plate transmittance of the near infrared polarizer 9b at 850 nm is preferably less than 55%, more preferably less than 50%, and still more preferably less than 47%. In this range, the detection accuracy in the light receiving section 4 can be improved.

As the half mirror, the reflective polarizer, and the ¼ wave plate in the pancake lens, those described above in the first embodiment can be used. It is more preferable that the reflective polarizer is a pancake lens formed of a cholesteric mirror from the viewpoint of reducing the effect on the polarized state of the near infrared flux.

As shown in FIG. 47, one preferable aspect of the head-mounted display according to the second embodiment of the present invention is a head-mounted display including an image display system 471, in which the image display system 471 includes an image display panel 472 and a light guide element 473 and emits the luminous flux (solid line) in a visible range and the luminous flux (broken line) in an invisible range emitted from the image display panel 472 to an eyeball 479 of an observer from the light emission surface (emission surface) 6 provided in the light guide element 473 through the light guide element 473, and eyeball sensing is performed by detecting near infrared light emitted from the image display system 471 to the eyeball 479 of the observer and reflected from an eyeball of the observer using the light receiving section 4. Examples of the information obtained by eyeball sensing include personal authentication by eye tracking or iris, vital information by detection of the surface state of an iris, a retina, or a cornea, and analysis information of a blood flow, a blood pressure, a heart beat, or a blood component obtained by detection of a blood vessel in the eyeball.

In general, in the display device where the luminous flux in a visible range emitted from the image display panel is emitted to the observer from the emission surface provided in the light guide element through the light guide element, the area of the face of the observer that is covered can be reduced, and the light guide element has partial visible light transmittance such that image display can be performed while taking in an external field of view. Therefore, this display device is widely used as a head-mounted display for augmented reality. However, in a case where the sensing system is additionally provided while securing the above-described advantages, there is a restriction on space and design. In addition, the light guide element is positioned substantially in front of the eyeball. Therefore, in a case where the sensing system is provided separately from the light guide element, it is necessary to emit or detect the luminous flux at a large angle with respect to the eyeball, and there is a limit on the selection of the emitted beam angle or the detection accuracy.

In the head-mounted display including the image display system according to the embodiment of the present invention, a part of the optical system of the sensing system is embedded in the display optical system. Therefore, the restriction on space and design is small. In addition, the luminous flux in an invisible range emitted from the light guide element positioned substantially in front of the eyeball can be emitted to the eyeball. Therefore, sensing having excellent detection accuracy at an appropriate emitted beam angle can be performed.

In the head-mounted display where the luminous flux in a visible range emitted from the image display panel is emitted to the observer from the emission surface provided in the light guide element through the light guide element, the image display panel is concentrated in a very small space in many cases. Therefore, the concepts of the image display panel described herein include not only the form of a panel but also the entire image forming mechanism including pixels in a visible range and pixels in an invisible range.

As the light guide element, a light guide element that guides light using total internal reflection and includes a diffraction element for light incidence and light emission as shown in FIG. 47, or a light guide element for a head-mounted display, such as a prism mirror having a mirror-surfaced surface, that is well-known in the related art can be applied. The light guide element allows transmission of the luminous flux in an invisible range. Therefore, it is preferable that a main material for forming the light guide element is transparent in an invisible range, in particular, in a wavelength range of 800 to 1800 nm. In a case where the wavelength range used for sensing is narrow, it is preferable that the main material is transparent in a range of 100 nm with respect to a peak wavelength. As this material, glass, a resin, or the like can be used.

The configuration of the light guide element may have a monolithic structure as in the light guide element 473 in FIG. 47 or may have a combination of a plurality of members. In addition, a light guide path may be divided depending on the wavelengths of the luminous fluxes. In a case where the light guide path is divided depending on the wavelengths of the luminous fluxes, with a light guide direction as a main surface, the light guide path may be divided in an in-plane direction or may be divided in an out-of-plane direction (in particular, in a case where the light guide element is a flat plate, a thickness direction of the flat plate). For example, in the light guide element on the flat plate that guides light using total internal reflection and includes a diffraction element for light incidence and light emission, the luminous flux in a visible range may be guided using a first flat plate, and the luminous flux in an invisible range may be a guided using a second flat plate provided on the first flat plate.

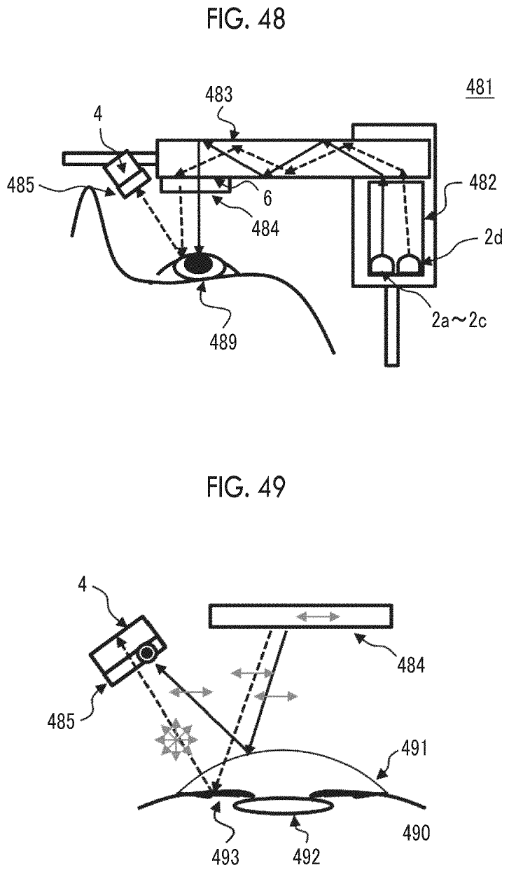

In still another aspect, as shown in FIG. 48, additional near infrared polarizers 484 and 485 can be provided between the light emission surface of the light guide element and the eyeball of the observer and between the light receiving section and the eyeball of the observer, respectively. As described above using FIG. 31, by providing the additional near infrared polarizer, the polarized state of the near infrared light 8a can be compensated for. As the additional near infrared polarizer, the near infrared polarizer described in the first embodiment can be used as long as it can compensate for the polarized state. The single plate transmittance of the near infrared polarizer at 850 nm is preferably less than 55%, more preferably less than 50%, and still more preferably less than 47%.

By providing the above-described near infrared polarizer, noise generated by external light or diffused reflected light can be reduced, and the detection accuracy can be improved.

In particular, in the near infrared polarizer 484 that is provided between the light emission surface of the light guide element and the eyeball of the observer, in order to minimize the effect on a display image formed by the luminous flux in a visible range and an external scenery that can be observed through the light guide element, it is preferable that the near infrared polarizer 484 is transparent in a visible range.

From this viewpoint, an average transmittance of the near infrared polarizer 484 in a visible range is preferably 90% or more, more preferably 92% or more, and still more preferably 95% or more.

On the other hand, in order to exhibit the effect of reducing noise, it is desirable that the polarization degree of the near infrared polarizer 484 provided between the light emission surface of the light guide element and the eyeball of the observer is high. From this viewpoint, a polarization degree of the near infrared polarizer 484 at 850 nm is preferably 90% or more, more preferably 92% or more, and still more preferably 95% or more.

In addition, from the viewpoint of reducing the noise, in the near infrared polarizer 485 provided between the light receiving section 4 and an eyeball 489 of the observer, a polarization degree of the near infrared polarizer 485 at 850 nm is preferably 90% or more, more preferably 92% or more, and still more preferably 95% or more.

Examples of the near infrared polarizers 484 and 485 include a polarizer obtained by adsorbing and aligning a dichroic dye having absorption in a near infrared range to a polyvinyl alcohol resin film, a polarizer obtained by dissolving or dispersing a dichroic dye having absorption in a near infrared range in a liquid crystal composition to form an alignment state and immobilizing the alignment state, a polarizer obtained by polyene formation with an iodine polarizing plate, a polarizer obtained by application of a wire grid, a reflective polarizer formed of a cholesteric liquid crystal or a dielectric multi-layer film, and a polarizer having a surface microstructure such as a metasurface. From the viewpoint that the productivity in a thin film is excellent and design with high transmittance to visible light can be implemented, a polarizer obtained by dissolving or dispersing a dichroic dye having absorption in a near infrared range in a liquid crystal composition to form an alignment state and immobilizing the alignment state is preferable.

An absorption axis direction of the near infrared polarizer 484 that is provided between the light emission surface of the light guide element and the eyeball of the observer and an absorption axis direction of the near infrared polarizer 485 provided between the light receiving section and the eyeball of the observer may be freely disposed depending on the design. In a preferable example, as shown in FIG. 49, assuming that specular reflection occurs on a cornea 491 of an eyeball 490 of an observer, it is preferable that the near infrared polarizers are disposed in a crossed nicols relationship.

In eye tracking of a type where iris recognition or the position or size of a pupil is specified or the sensing system of a type where the state of the inside of the eyeball such as a retina is detected, a reflection component from the cornea surface becomes noise and inhibits the measurement. Assuming that specular reflection occurs on the eyeball 489 of the observer, in a case where the absorption axis direction of the near infrared polarizer 484 that is provided between the light emission surface 6 of the light guide element 483 and the eyeball 489 of the observer and the absorption axis direction of the near infrared polarizer 485 provided between the light receiving section 4 and the eyeball 489 of the observer are disposed in a crossed nicols relationship, the reflection from the surface of the cornea 491 having reflection characteristic similar to those of a mirror surface is substantially removed. In this case, reflected light from an internal structure such as an iris 493, a pupil 492, or a retina (not shown) changes in polarization, and can be detected by the light receiving section 4. A surface reflection component from the cornea 491 is removed, and a signal can be detected.

In addition, in another preferable example for noise reduction, the near infrared polarizers 484 and 485 are combined with a retardation element that acts as a ¼ wave plate at the wavelength to form a circular polarization plate. As a result, the configuration for removing a reflection component from the cornea surface can also be implemented. As the ¼ wave plate to be used, a well-known retardation material can be used. For example, from the viewpoint of suppressing the influence on another wavelength, the application of a metasurface material is preferable.

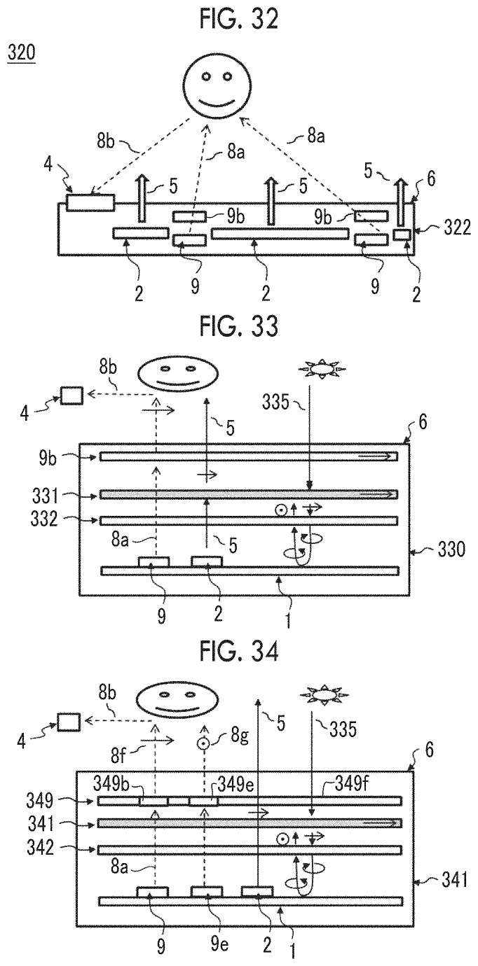

FIG. 32 shows one preferable aspect of the image display system according to the second embodiment of the present invention. An image display system 320 according to the embodiment of the present invention shown in FIG. 32 includes: a display device (image display apparatus) 322; and a face recognition system or a facial expression recognition system that detects the incidence light (reflected light) 8b obtained by causing the near infrared light 8a emitted from the light emitting section 9, which is disposed in the image display panel in the display device 322 and emits near infrared light, to be reflected from a face of a user using the light receiving section 4.

The observer can use the above-described face recognition system or the facial expression recognition system while watching an image that is formed of the luminous flux 5 of visible light formed from the plurality of pixels 2, and the obtained information is processed using an arithmetic circuit (not shown) and can be used for releasing a security lock of a device or a service, recognizing a user, or providing a service corresponding to the state of the detected facial expression and/or face or for active control of the device.

As facial expression sensing or face recognition system in the related art, an imaging element and a light source provided in a side edge portion of a mobile display are used. The light source has small output and is limited in directivity. Therefore, in order to obtain the amount of information acquired required for recognition, the user needs to move the face largely multiple times for the imaging element and the light source. In a case where a combination of the imaging element and the light source is provided in a plurality of side edge portions of a mobile display in order to solve this problem, the space for the imaging elements causes a problem in device size or design.

However, with the image display system according to the embodiment of the present invention, a plurality of light emitting sections can be provided to be integrated with the display screen. Therefore, there is no problem in size and design, a necessary number of light emitting sections including a necessary number of light emitting elements can be provided, and a sufficient amount of information can be acquired.

Examples of the image display panel in the display device 20 to be used include the OLED display panel shown in FIG. 26 or 28, a light emitting panel such as a LED array, a micro LED panel, or a mini LED panel, and the display device formed of a liquid crystal cell.

As described above, the image display panel can include a polarizer in order to form an image or to improve the image quality.

As the image display panel, regarding a configuration including the OLED display panel and a circular polarization plate that is provided on a surface of the OLED display panel to reduce external light reflection, a configuration for reducing interference between the near infrared light 8a and the visible flux 5 will be described using a conceptual diagram shown in each of FIGS. 33 and 34.

FIG. 33 shows the image display system of FIG. 32 in more detail.

A display device (image display apparatus) 330 includes the near infrared polarizer 9b, a visible light polarizer 331, a retardation plate 332 as a ¼ wave plate having a slow axis at 45° or 135° with respect to a transmission axis of the visible light polarizer 331, and the substrate 1 including the pixels 2 and the light emitting section 9 in this order from the emission surface 6 to the substrate 1.

The near infrared light 8a emitted from the light emitting section 9 is polarized by the near infrared polarizer 9b, is emitted from the emission surface 6 to a measurement target, is reflected from the measurement target, and is detected by the light receiving section 4. As described above, by emitting polarized light, the detection accuracy can be improved to increase the amount of information acquired. By adjusting light emitted from another light emitting section (not shown) to have the same polarized state or a different polarized state, further improvement of the detection accuracy and the amount of information acquired can be implemented. The near infrared polarizer may be a polarizer having a uniform transmission axis direction in a plane or may be a patterned polarizer in which regions having different transmission axes are distributed in a patterned manner.

The single plate transmittance of the near infrared polarizer at 850 nm is preferably less than 55%, more preferably less than 50%, and still more preferably less than 47%. In a case where the near infrared polarizer is the patterned polarizer, it is preferable that the patterned polarizer has the above-described single plate transmittance in a region having polarization selectivity in a near infrared range.

In addition, regarding the polarization degree, P(850) is preferably 0.80 or more, more preferably 0.85 or more, still more preferably 0.90 or more, and still more preferably 0.95 or more. In addition, P(950) is preferably 0.80 or more, more preferably 0.85 or more, still more preferably 0.90 or more, and still more preferably 0.95 or more. The upper limits of P(850) and P(950) are theoretically 1.00 and are in a range of less than 1.00 in practice.

The action of the visible light polarizer 331 and the retardation plate 332 as the ¼ wave plate on the visible flux 5 emitted from the pixels 2 and external light 335 is known as an internal antireflection mechanism of an OLED panel and improves the display contrast.

In a case where the visible light polarizer 331 and the retardation plate 332 as the ¼ wave plate have near infrared transmittance and the near infrared polarizer 9b has visible light transmittance, the actions of visible light and near infrared light do not interfere with each other in this arrangement, and the improvement of the detection accuracy and the amount of information acquired in the image display system and the improvement of the contrast in the image display apparatus can be achieved at the same time.

FIG. 34 is a conceptual diagram showing a case where the near infrared polarizer is a patterned polarizer where regions having different transmission axes are distributed in a patterned manner. The arrangement and the action of a visible light polarizer 341 and a retardation plate 342 as a ¼ wave plate are the same as those of the example shown in FIG. 33.

A patterned polarizer 349 includes a region 349b having a transmission axis parallel to the paper plane and a region 349e having a transmission axis perpendicular to the paper plane. Light components released from the light emitting sections 9 and 9e corresponding to the region 349b and the region 349e are emitted from emission surface 6 to the face of the user as linearly polarized light 8f parallel to the paper plane and linearly polarized light 8g perpendicular to the paper plane, respectively. In this example, the two regions having different polarization directions are patterned. However, three or more regions having different transmission axes may also be patterned. In addition, a region 349f corresponding to a non-emission region where the light emitting sections 9 and 9e are not provided may be a region having any transmission axis and may be a region not having polarization selectivity.

Examples of the patterned polarizer include a near infrared polarizer described below where a liquid crystal compound immobilized in an alignment state includes a dichroic compound having absorption in a near infrared range and the alignment state and the alignment direction of the liquid crystal compound changes depending on regions and are patterned.

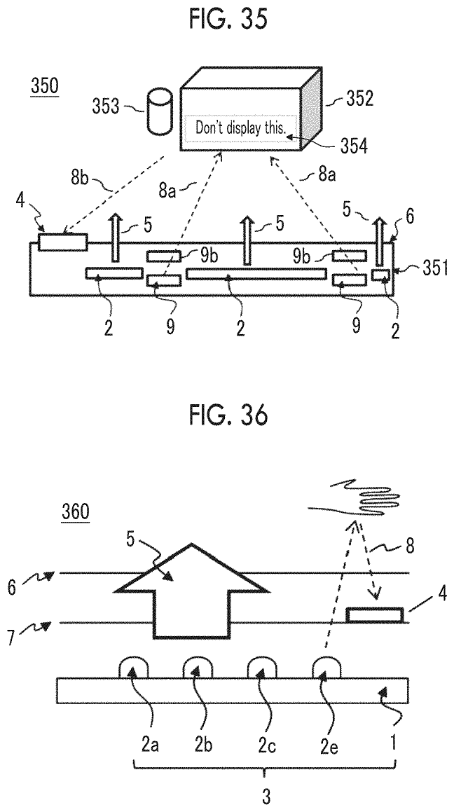

FIG. 35 shows another preferable aspect of the image display system according to the second embodiment of the present invention. An image display system 350 shown in FIG. 35 includes: a display device (image display apparatus) 351; and a LIDAR system or an object recognition system that is capable of emitting the near infrared light 8a to measurement targets 352 and 353 and detects the incidence light 8b obtained by causing the near infrared light 8a to be reflected from the measurement targets 352 and 353 using the light receiving section 4. The user can use the above-described LIDAR system or the object recognition system while watching an image that is formed of the luminous flux 5 of visible light formed from the plurality of pixels 2, the obtained information is processed through an arithmetic circuit (not shown), and two-way communication where the acquired information is mounted on the display image in real time or various services using an invisible marking 354 given to the measurement target can be provided.

As in the problem of the above-described facial expression sensing or the face recognition system, in the image display system including the LIDAR system or the object recognition system, an imaging element and a light source provided in a side edge portion are used. The light source has narrow directivity per element or is limited in output. Therefore, a plurality of light sources needs to be provided at different positions in order to obtain a necessary amount of information acquired for recognition, and there is a problem in size, weight, and design.

However, with the image display system according to the embodiment of the present invention, a plurality of light emitting sections can be provided to be integrated with the display screen. Therefore, there is no problem in size and design, a number of light emitting sections including a necessary output can be provided, and a sufficient amount of information can be acquired.

As a specific configuration for simultaneously achieving the improvement of the contrast in the image display apparatus and the improvement of the detection accuracy and the amount of information acquired by patterning the polarization direction of the near infrared flux from the light emitting section in various ways, the same configuration as that shown in FIGS. 33 and 34 can be used. In particular, from the viewpoint of emitting structured light from the emission surface 6 and improving the detection accuracy and the amount of information acquired, it is preferable that a patterned polarizer where regions having different transmission axes are distributed in a patterned manner is provided as the near infrared polarizer. In addition, it is preferable that a display device (image display apparatus) 351 includes the near infrared polarizer 9b, a visible light polarizer, a retardation plate as a ¼ wave plate having a slow axis at 45° or 135° with respect to a transmission axis of the visible light polarizer, and a substrate including the pixels 2 and the light emitting section 9 in this order from the emission surface 6 to the substrate. In addition, the single plate transmittance of the near infrared polarizer at 850 nm is preferably less than 55%, more preferably less than 50%, and still more preferably less than 47%.

The structured light described herein refers to light obtained by modulating light emitted to an object such that at least any of a phase, an amplitude, a wavelength, or a polarized state thereof changes in a plane. In the structured light, the state of the modulated emitted light is predetermined and forms a predetermined pattern. By calculating an in-plane distribution to which a signal detected through a target changes with respect to the predetermined pattern, the distance and/or shape and the surface state of the object can be measured more accurately within a shorter period of time as compared to the related art.

### Third Embodiment

An image display apparatus according to a third embodiment of the present invention includes: a light receiving section having sensitivity in an invisible range; an image display panel including a substrate and a plurality of pixels; and an emission surface that emits a luminous flux in a visible range formed from the plurality of pixels, in which the light receiving section is provided between the emission surface and the image display panel, on the image display panel, or on a side of the image display panel opposite to the emission surface, the plurality of pixels include a pixel group that forms a luminous flux in a visible range and a pixel that forms a luminous flux in an invisible range to which the light receiving section has sensitivity, the light receiving section is disposed at a position overlapping the image display panel in a view from a direction perpendicular to the emission surface, in which the light receiving section receives only invisible light in light incident into the image display apparatus through the emission surface, and a near infrared polarizer having polarization selectivity in a near infrared range is provided between the pixel forming the luminous flux in an invisible range and the emission surface.

One preferable aspect of the above-described third embodiment will be described using FIG. 36. An image display apparatus 360 includes an image display panel 3 that includes a substrate 1 and a plurality of pixels 2a to 2c and 2e disposed on the substrate 1, in which the luminous flux 5 in a visible range is formed from the pixels 2a to 2c, and the invisible light 8 is formed from the invisible light pixel 2e. The luminous flux 5 in a visible range is emitted from an emission surface 6 to be recognized as image light by a user or to irradiate an object. Here, the light receiving section 4 having sensitivity only in an invisible range can be provided between the emission surface 6 and the image display panel 3. The light receiving section 4 may be provided on, for example, a substrate 7 having transmittance to the luminous flux 5. In addition, as shown in FIG. 36, the light receiving section 4 is disposed at a position overlapping the image display panel 3 in the plane direction. The light receiving section 4 receives and converts invisible light 8 incident from the outside into an electrical signal, and can output information detected through an arithmetic circuit (not shown).

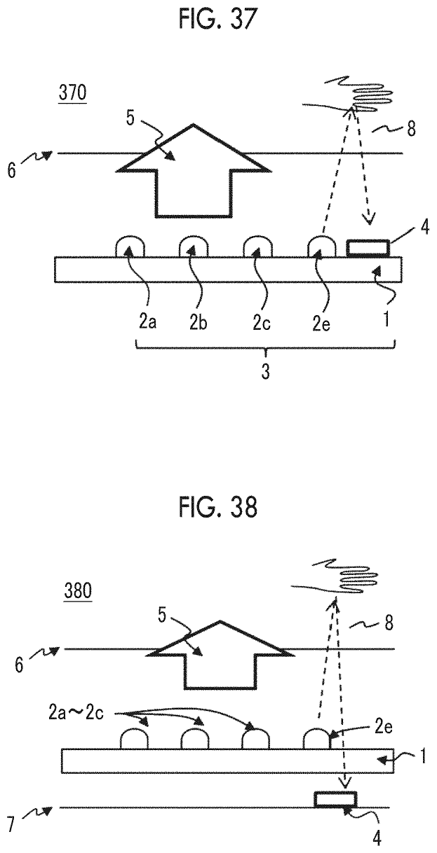

In the image display apparatus 360 shown in FIG. 36, the near infrared polarizer is not shown. Regarding this point, the same can also be applied to FIGS. 37 and 38.

In addition, one preferable aspect of the third embodiment will be described using FIG. 37. The light emitting panel 3 and the emission surface 6 in an image display apparatus 370 are the same as those of FIG. 36. The light receiving section 4 having sensitivity in an invisible range is provided on the image display panel 3. “Being provided on the image display panel 3” described herein is not limited to being simply provided on the emission surface 6 side of the image display panel 3, and represents being integrated with the image display panel by being provided over or below an electrode layer, a passivation layer, an insulating layer, or the like provided in the image display panel.

Still another preferable aspect of the third embodiment will be described using FIG. 38. The image display panel 3 and the emission surface 6 in an image display apparatus 380 are the same as those of FIG. 36. The light receiving section 4 having sensitivity in an invisible range is provided on a surface of the image display panel 3 opposite to the emission surface 6. The light receiving section 4 may be provided on the substrate 7 that is provided separately from the image display panel 3, or may be provided adjacent to the surface of the image display panel 3 opposite to the emission surface 6 side.

In addition, as in the example shown in FIGS. 37 and 38, the light receiving section 4 is disposed at a position overlapping the image display panel 3 in the plane direction.

As the above-described image display panel, a light emitting panel such as a LED array, an OLED panel, a micro LED panel, or a mini LED panel can be applied. In addition, the image display panel may be a combination of a transmission type liquid crystal panel and a backlight unit.

As the light emitting panel and the substrate and the pixels in the image display panel, those described above in the first embodiment can be applied. In addition, as the examples of the emission surface 6, those described above in the first embodiment can be applied. The visible flux released to the outside of the system is used, for example, for illuminating an object and provides visual information to an observer. In one preferable aspect of the present invention, the image display apparatus displays an image and/or information using the luminous flux in a visible range emitted from the image display panel.

As the pixel that forms invisible light, the pixel described in the second embodiment can be applied. It is preferable that the pixel that forms invisible light has an emission band in a near infrared range.

As the light receiving section, a photodetection element such as a photodiode or a phototransistor having sensitivity in an invisible range and not having sensitivity to visible light can be applied. It is preferable that the light receiving section is a photodiode or a phototransistor having sensitivity only in a near infrared range and not having sensitivity in a visible range. As the photodetection element, an organic photodiode (OPD) or an organic phototransistor (OPT) may be applied.

The light receiving section detects a target by receiving invisible light reflected from a detection target.

As the target detected by the light receiving section, the light receiving section can detect a three-dimensional shape of an object, a surface state of the object, and at least one selected from an eye movement, an eye position, a facial expression, a face shape, a vein pattern, a blood flow, a pulse, a blood oxygen saturation level, a fingerprint, or an iris of a user. It is preferable that the light receiving section is provided at a position suitable for the measurement target.

As the near infrared polarizer having polarization selectivity in a near infrared range, those described in the first embodiment can be used. In addition, as in the first embodiment, in the near infrared polarizer having polarization selectivity in a near infrared range, a single plate transmittance at a wavelength of 850 nm is preferably less than 50%.

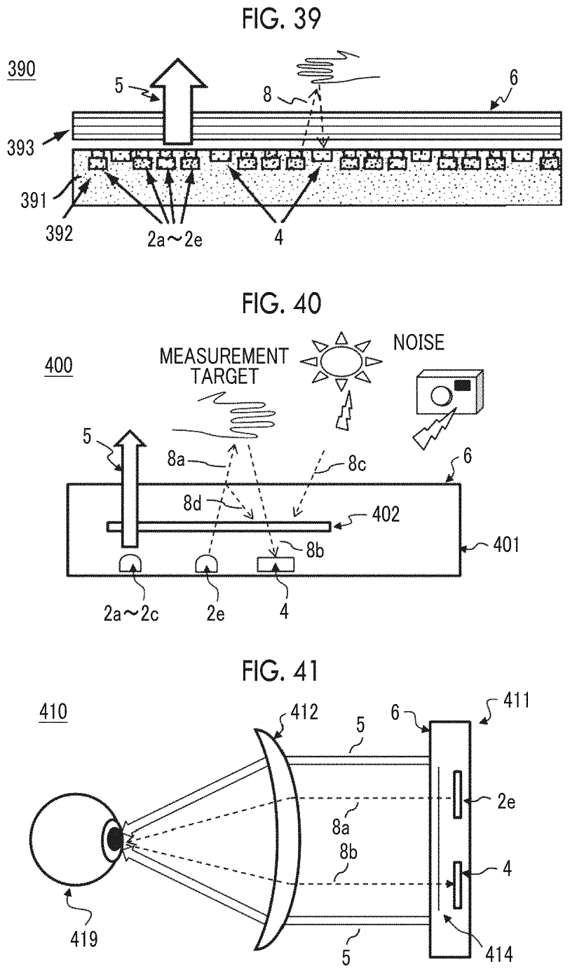

As one example of the image display apparatus according to the third embodiment of the present invention, FIG. 39 shows an OLED display device (image display apparatus) 390 including an image display panel 391 including: pixels (visible light pixels) 2a to 2c that form a visible flux on a substrate 392; a pixel (invisible light pixel) 2e that forms an invisible flux; and the light receiving section 4. It is preferable that the invisible light pixel 2e and the light receiving section 4 of the image display apparatus according to the embodiment of the present invention have an emission band and sensitivity to near infrared light. In the following description, it is assumed that the invisible light pixel 2e is a near infrared light emitting element and the light receiving section 4 is a near infrared light-receiving element.

A transistor layer (not shown) is provided on a substrate 392 to form a drive circuit, and each of the pixels 2a to 2c and 2e includes a lower electrode, an EL light emitting layer, and a transparent electrode. In addition, the light receiving section 4 connected to a circuit (not shown) is formed in a non-pixel region. A cover plate 393 can be provided on the visible side of the image display panel 391, and the light emitting panel is protected with the cover plate 393. In the configuration of FIG. 39, the visible side surface of the cover plate 393 is the emission surface 6.

Although not shown in the drawing, an insulating layer, an adhesive layer, and the like can be provided between the cover plate 393 and the image display panel 391. In addition, a color filter layer for improving the color purity or a circular polarization plate for internal antireflection may be provided.

The visible flux 5 formed from the visible light pixels 2a to 2c is recognized as a display image to an observer. The near infrared flux 8 released from the invisible light pixel 2e is emitted to a detection target and is detected by the light receiving section 4 such that various kinds of sensing can be performed. The visible light pixels 2a to 2c and the invisible light pixel 2e may form one pixel unit.

The action of the image display apparatus according to the embodiment of the present invention will be described using FIG. 40.

An image display apparatus 400 includes an image display panel including the visible light pixels 2a to 2c, the invisible light pixel 2e, and the light receiving section 4. The visible flux 5 released from the visible light pixels 2a to 2c is emitted to the emission surface 6 and is recognized as a display image. The near infrared light 8a released from the invisible light pixel 2e is emitted to a measurement target, transmits through the emission surface 6 from the measurement target, and is detected by the light receiving section 4 such that the sensor functions.

It is preferable that the image display apparatus 400 includes a near infrared polarizer 402 having polarization selectivity in a near infrared range that is provided between the emission surface 6 and the invisible light pixel 2e. This way, the near infrared light 8a emitted from the emission surface 6 becomes polarized light, and the detection accuracy and the amount of information acquired can be improved. In addition, the near infrared light noise 8c from the outside is incident through the emission surface 6 as noise and is in an unpolarized state or in a polarized state different from that of the near infrared light 8a emitted from the invisible light pixel 2e. Therefore, most of the external near infrared light noise 8c is absorbed by the near infrared polarizer 402 and does not reach the light receiving section 4. Accordingly, the noise can be removed, and the detection accuracy can be improved.

In addition, in the emission surface 6, a part of the light emitted from the invisible light pixel 2e is reflected, and the near infrared flux 8d that travels to the inside is generated, which may cause erroneous detection in the light receiving section 4. In order to prevent this erroneous detection, it is preferable that the luminous flux that is emitted from the invisible light pixel 2e and is incident into the emission surface 6 through the near infrared polarizer 402 has circular polarization properties. More specifically, the near infrared polarizer 402 has circular polarization selective transmittance as in a cholesteric mirror, or the near infrared polarizer 402 is a near infrared linear polarizer and a retardation plate functioning as a ¼ wave plate in a near infrared range can be further provided between the near infrared polarizer 402 and the emission surface 6 such that a slow axis is disposed at 45° or 135° with respect to the transmission axis of the near infrared polarizer 402. This way, regarding the luminous flux reflected from the emission surface 6, the rotation direction of circularly polarized light is reversed, and the luminous flux is blocked by the near infrared polarizer 402 on an optical path toward the light receiving section 4. Therefore, the luminous flux cannot reach the light receiving section 4, and the detection accuracy can be secured.

In addition, the measurement target of the image display apparatus 400 may be any target. Examples of the measurement target include a portion of a biological body of a user such as a hand, a finger, a palm, or a skin, a vein pattern, a face, an eyeball, a lip, and a limb of a user, motions or gestures thereof, an object such as a specific interface device or a surrounding object, and a state of a surrounding environment such as a temperature, a humidity, or a composition of particles or gas.

As the near infrared polarizer having polarization selectivity in a near infrared range, various polarizers described in the first embodiment can be used. In addition, regarding the wavelength selectivity, various wavelength selectivity described in the first embodiment can be applied depending on the purposes.

It is preferable that the near infrared polarizer does not have a polarization property in a visible range or has transmittance in a visible range. As described below, even in a case where the near infrared polarizer is a patterned polarizer including a plurality of regions having different types of polarization selectivity in a patterned manner, it is preferable that the near infrared polarizer does not have a polarization property in a visible range or has transmittance in a visible range. As a result, excellent display performance and high accuracy measurement can be simultaneously achieved without interference between near infrared light for sensing and visible light for image display.

The image display apparatus can be applied to, for example, a wearable device such as a head-mounted display, a mobile display device such as a smartphone or a tablet, or a stationary display device such as a television or a lighting.

Preferable aspects of the devices will be described using the following specific examples.

One preferable aspect of the image display system including the image display apparatus according to the third embodiment of the present invention is a head-mounted display 410 including, as shown in FIG. 41, an image display apparatus 411 according to the embodiment of the present invention, an eyepiece 412, and an eye tracking system that performs emission of near infrared light to an eyeball 419 and detection of the near infrared light using the image display apparatus 411. An action of the eyepiece 412 is the same as described above in the first embodiment. Information regarding an eye position and a visual line obtained from the eye tracking can be used for rendering the projected image or for an operation of a graphic interface embedded in a display image.

As described above in the first embodiment and the second embodiment, the problem in the weight, size, and space of the head-mounted display and the problem of securing the detection accuracy and the amount of information acquired are contradictory to each other. In the embodiment, by integrating both of the light emitting section and the light receiving section with the visible optical system, both of the light emitting section and the light receiving section can be disposed in a direction confronting the eyeball. Therefore, the problem in the space can be solved, the degree of freedom for optical design increases largely, and the eye tracking system that is excellent in the detection accuracy and the amount of information acquired can be constructed.

As described above using FIG. 40, in order to remove the component that is emitted from the invisible light pixel 2e and is reflected from the emission surface 6 to be directly incident into the light receiving section 4 and to remove stray light in the visible optical system, it is preferable that a near infrared polarizer 414 is provided between the invisible light pixel 2e and the emission surface 6 of the image display apparatus 411. It is preferable that the near infrared polarizer 414 is any one of a cholesteric mirror or a laminate where a near infrared linear polarizer and a retardation plate are laminated in this order from the invisible light pixel 2e side, the retardation plate functioning as a ¼ wave plate in a near infrared range and having a slow axis at 45° or 135° with respect to a transmission axis direction of the near infrared linear polarizer.

From the viewpoint of increasing the amount of information acquired, the polarized light of the near infrared light 8a emitted from the invisible light pixel 2e may be emitted to the eyeball 419 and detected by the light receiving section 4 while making the direction or the state of the polarized light to vary. In order to make the direction or the state of the polarized light of the near infrared light 8a emitted from the invisible light pixel 2e to vary, the near infrared polarizer 414 can be made to be a patterned polarizer where regions having different transmission axes or different types of polarization selectivity for corresponding pixels are disposed in a patterned manner.

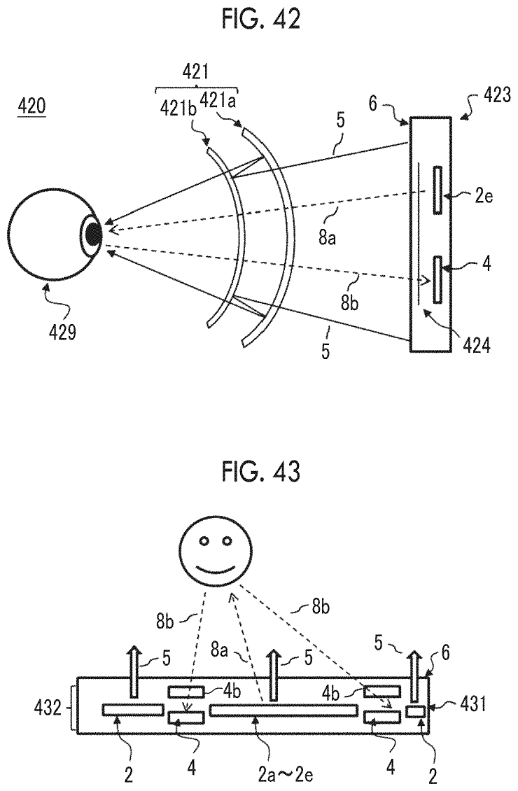

In addition, a case where a so-called pancake lens including a half mirror and a reflective polarizer is used as the eyepiece will be described using FIG. 42. The structure, the action, and the gain of the pancake lens are the same as described above in the first embodiment.

In one preferable aspect of the third embodiment of the present invention, a reflective polarizer 421b and a half mirror 421a can have transmittance in a near infrared range. In the reflective polarizer 421b and the half mirror 421a, a single plate transmittance at 850 nm is preferably 80% or more, more preferably 85% or more, and still more preferably 90% or more.

With this configuration, the near infrared light 8a that is emitted from the invisible light pixel 2e to an eyeball 429 and the incidence light 8b that is reflected from the eyeball 429 to be incident into the light receiving section 4 are not reflected from a pancake lens 421. Therefore, the degree of freedom for the optical design of the eye tracking system can be further improved without being restricted by an opening or an eye box of the pancake lens. This advantageous effect is particularly preferable for the image display with a sensor according to the embodiment of the present invention from the viewpoint that a large eye movement and/or a fine movement of the pupil can be detected.

As the half mirror, the reflective polarizer, and the ¼ wave plate in the pancake lens, those described above in the first embodiment can be used. It is more preferable that the reflective polarizer is a pancake lens formed of a cholesteric mirror from the viewpoint of reducing the effect on the polarized state of the near infrared flux.

In an image display apparatus 423, a near infrared polarizer 424 is provided between the emission surface 6 and the invisible light pixel 2e. The reason for this, the gain, and a preferable configuration are the same as described above using FIG. 41.

A second retardation plate may be further provided between the image display apparatus 423 and a pancake lens 421 in order to cancel out an optical effect on the near infrared light 8a and the incidence light 8b, in particular, a change in polarized state with a factor that affects a phase difference and a polarized state of each of the optical components of the pancake lens 421 in a near infrared range such that the emission to the eyeball and the detection using the light receiving section 4 can be performed in a desired polarized state.

FIG. 43 shows one preferable aspect of the image display apparatus according to the third embodiment of the present invention. The image display apparatus shown in FIG. 43 is an image display apparatus 431 including a face recognition system or a facial expression recognition system that detects the incidence light 8b obtained by causing the near infrared light 8a emitted from the invisible light pixel 2e of an image display panel 432 in the image display apparatus 431 to be reflected from a face of a user using the light receiving section 4.

The observer can use the above-described face recognition system or the facial expression recognition system while watching an image that is formed of the luminous flux 5 of visible light formed from the plurality of visible light pixels 2a to 2c, and the obtained information is processed using an arithmetic circuit (not shown) and can be used for releasing a security lock of a device or a service, recognizing a user, or providing a service corresponding to the state of the detected facial expression and/or face or for active control of the device.

As facial expression sensing or face recognition system in the related art, an imaging element and a light source provided in a side edge portion of a mobile display are used. However, recently, in a mobile display, an image display panel where the entire display surface is set as an image display region such that a so-called frame portion is minimized is required for design, and a space where an imaging element and a light source are provided is extremely small and is not present at all.

On the other hand, in order to provide a high service to a user, an attempt to directly sense personal authentication, a health status, a mental state, or the like of a user using a mobile display has been made such that an appropriate service can be provided using a displayed image or a voice. A large amount of information is required for sensing personal authentication, a health status, a mental state, or the like of a user, and the detection accuracy thereof needs to be high.

However, with the image display apparatus according to the embodiment of the present invention, a plurality of light emitting sections and light receiving sections can be provided to be integrated with the display screen. Therefore, there is no problem in size and design, necessary numbers of light emitting sections and light receiving sections can be provided, and a sufficient amount of information can be acquired.

Examples of the image display panel in the image display apparatus 431 include the OLED display panel shown in FIG. 39, a light emitting panel such as a LED array, a micro LED panel, or a mini LED panel, and the display device formed of a liquid crystal cell.

As described above, the image display panel can include a polarizer in order to form an image or to improve the image quality.

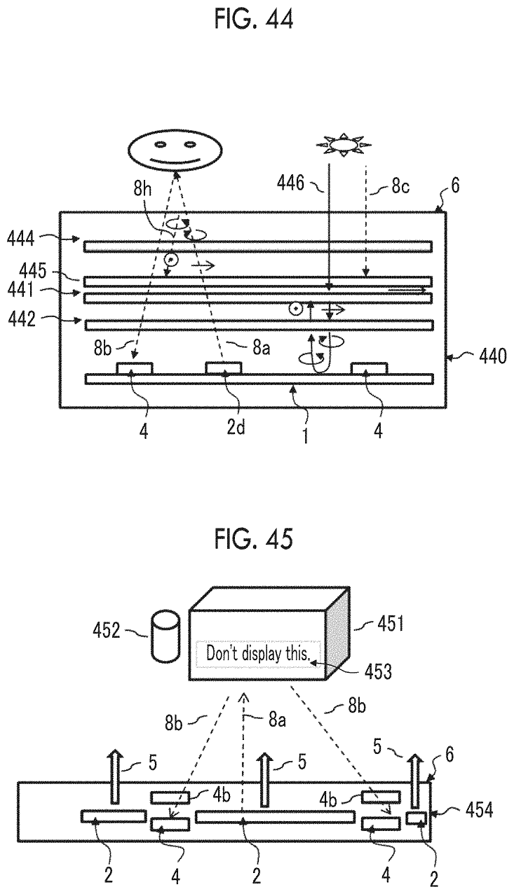

As the image display panel, regarding a configuration including the OLED display panel and a circular polarization plate that is provided on a surface of the OLED display panel to reduce external light reflection, a configuration for reducing noise of each of the near infrared light and the visible light will be described using a conceptual diagram shown in FIG. 44.

FIG. 44 shows the image display apparatus of FIG. 43 in more detail. An image display apparatus 440 includes, in order from the emission surface 6 to the substrate 1: a retardation plate 444 having ¼ wave plate characteristics in a near infrared range; a near infrared polarizer 445 having a transmission axis at 45° or 135° with respect to a slow axis of the retardation plate 444; a visible light polarizer 441; a retardation plate 442 as a ¼ wave plate having a slow axis at 45° or 135° with respect to a transmission axis of the visible light polarizer 441; and the substrate 1 including the visible light pixels (not shown), the invisible light pixel 2e, and the light receiving section 4.

The near infrared light 8a emitted from the invisible light pixel 2c is polarized by the near infrared polarizer 445, is emitted from the emission surface 6 to a measurement target, and is detected by the light receiving section 4. As described above, by emitting polarized light, the detection accuracy can be improved to increase the amount of information acquired. By adjusting light emitted from another invisible light pixel (not shown) to have the same polarized state or a different polarized state, further improvement of the detection accuracy and the amount of information acquired can be implemented. The near infrared polarizer may be a polarizer having a uniform transmission axis direction in a plane or may be a patterned polarizer in which regions having different transmission axes are distributed in a patterned manner.

The near infrared light noise 8c from the outside is incident through the emission surface 6 and is unpolarized light or is in a polarized state different from that of the incidence light 8b to be detected. Therefore, most of the near infrared light noise 8c is absorbed by the near infrared polarizer 445 and does not reach the light receiving section 4. In addition, in a case where a luminous flux 8h that is reflected from the emission surface 6 without being emitted from the emission surface 6, the luminous flux 8h is converted into circularly polarized light having a direction opposite to that of circularly polarized light converted by the retardation plate 444. The circularly polarized light is incident into the retardation plate 444 to be converted into linearly polarized light perpendicular to a transmission axis of the near infrared polarizer 445. Therefore, the linearly polarized light does not reach the light receiving section 4. This way, the noise can be removed, and the detection accuracy can be secured.

The action of the visible light polarizer 441 and the retardation plate 442 as the ¼ wave plate on the visible light (not shown) emitted from the visible light pixel and external light 446 is known as an internal antireflection mechanism of an OLED panel and has the effect of improving the display contrast.

In a case where the visible light polarizer 441 and the retardation plate 442 as the ¼ wave plate have near infrared transmittance and the near infrared polarizer 9b has visible light transmittance, the actions of visible light and near infrared light do not interfere with each other in this arrangement, and the improvement of the detection accuracy and the amount of information acquired in the image display apparatus and the improvement of the contrast in the image display apparatus can be achieved at the same time.

FIG. 45 shows another preferable aspect of the image display apparatus according to the third embodiment of the present invention. An image display apparatus 454 according to the embodiment of the present invention includes a LIDAR system or an object recognition system that is capable of emitting the near infrared light 8a to measurement targets 451 and 452 and detects the incidence light 8b obtained by causing the near infrared light 8a to be reflected from the measurement targets 451 and 452 using the light receiving section 4. The user can use the above-described LIDAR system or the object recognition system while watching an image that is formed of the luminous flux 5 of visible light formed from the plurality of pixels 2, the obtained information is processed through an arithmetic circuit (not shown), and two-way communication where the acquired information is mounted on the display image in real time or various services using an invisible marking 453 given to the measurement target can be provided.

As in the problem of the above-described facial expression sensing or the face recognition system, in the display device including the LIDAR system or the object recognition system, an imaging element and a light source provided in a side edge portion are used. The light source has narrow directivity per element or is limited in output. Therefore, a plurality of light sources needs to be provided at different positions in order to obtain a necessary amount of information acquired for recognition, and there is a problem in size, weight, and design.

However, with the image display apparatus according to the embodiment of the present invention, a plurality of light emitting sections (invisible light pixels) and light receiving sections can be provided to be integrated with the display screen. Therefore, there is no problem in size and design, necessary numbers of light emitting sections and light receiving sections including a necessary output can be provided, and a sufficient amount of information can be acquired.

As a specific configuration for simultaneously achieving the improvement of the contrast in the image display apparatus and the improvement of the detection accuracy and the amount of information acquired by patterning the polarization direction of the near infrared flux from the light emitting section in various ways, the same configuration as that shown in FIG. 44 can be used. In particular, from the viewpoint of emitting structured light from the emission surface 6 and improving the detection accuracy and the amount of information acquired, it is preferable that a patterned polarizer where regions having different transmission axes are distributed in a patterned manner is provided as the near infrared polarizer.

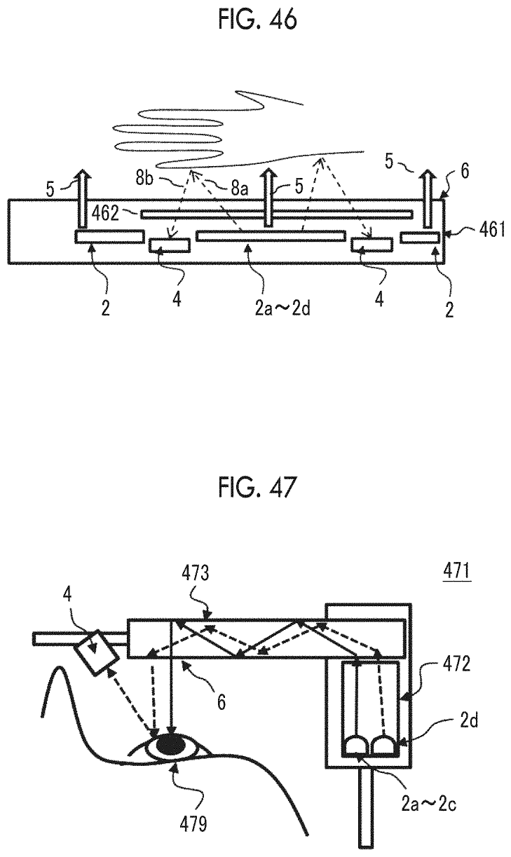

As one aspect of the image display apparatus according to the third embodiment of the present invention, an example of an image display apparatus including a biological sensing function such as a fingerprint sensor, a vein recognition system, or a blood flow sensor will be described using FIG. 46.

FIG. 46 shows one preferable aspect of the image display apparatus according to the third embodiment of the present invention. An image display apparatus 461 according to the third embodiment of the present invention includes: the invisible light pixel 2e that is capable of emitting the near infrared light 8a to a portion of a body of a user such as a hand, a finger, a palm, or a skin; the light receiving section 4; the visible light pixels 2a to 2c; and a fingerprint sensor, a vein recognition system, and a blood flow sensor that detect the incidence light 8b obtained by causing the near infrared light 8a emitted from the invisible light pixel 2e to transmit through or to be reflected from the portion of the body of the user using the light receiving section 4 through the near infrared polarizer 4b.

The observer can use the fingerprint sensor, the vein recognition system, or the blood flow sensor by bringing the portion of body into contact with the image display apparatus or making the portion of the body approach the image display apparatus, and the obtained information is processed using an arithmetic circuit (not shown) and can be used for releasing a security lock of a device or a service or providing a service corresponding to the detected blood flow state or the state of the skin, and/or for active control of the device.

In the image display apparatus having the biological sensing function in the related art, a dedicated detection element provided in a side edge portion of the device is used. However, since the measurement target is a portion of a body such as a hand, a finger, a palm, or a skin that requires a predetermined area or more, a space required for the detection element needs to be increased, and there is an unavoidable problem in device layout, weight, space, or design. In addition, for the fingerprint recognition, a system that recognizes a plurality of fingers at the same time in order to further improve the security level is disclosed. There is an unavoidable problem in weight, space, or design in that the dedicated detection element is provided at a plurality of positions for fingerprint recognition.

However, with the image display apparatus according to the embodiment of the present invention, a plurality of light receiving sections can be provided to be integrated with the display screen. Therefore, there is no problem in size and design, and a sufficient area for facing or contacting the portion of the body can be secured. In addition, a plurality of contact portions can be provided can be provided at any positions on the display screen.

In the image display apparatus 461, a near infrared polarizer 462 for polarizing the light released from the invisible light pixel 2e can be provided. By providing the near infrared polarizer 462, noise generated by stray light can be reduced, and the effect of improving the detection accuracy can be obtained. In addition, in a case where the near infrared polarizer 462 is a patterned polarizer including a plurality of regions having different types of polarization selectivity in a patterned manner, a plurality of polarized light components can be emitted to a measurement target, and the amount of information acquired can be improved.

The various examples described in the first embodiment, the second embodiment, and the third embodiment are examples of the preferable aspects. In addition, the preferable aspects described in the embodiments can also be combined.

Patterned Polarizer

In order to improve the detection accuracy and the amount of information acquired in the above-described image display apparatus and the image display system and the head-mounted display including the image display apparatus, it is preferable to apply a patterned polarizer. Accordingly, another embodiment of the present invention is a patterned polarizer in which at least a region having polarization selectivity to light in a near infrared range is provided, and a plurality of regions having different types of polarization selectivity in a near infrared range are provided in a patterned manner.

One example of the patterned polarizer is a patterned polarizer including a layer having polarization selectivity, in which a first region having a first polarization selectivity and a second region not having polarization selectivity that is provided to be surrounded by the region having the first polarization selectivity are provided in a plane of the layer having polarization selectivity. Alternatively, another example of the patterned polarizer is a patterned polarizer where a first region having at least a first polarization selectivity and a second region having a second polarization selectivity are provided in a plane of the layer having polarization selectivity. It is preferable that the patterned polarizer has a structure of any one selected from the examples.

Examples of the layer having polarization selectivity include a polarizer obtained by adsorbing and aligning a dichroic dye having absorption in a near infrared range to a polyvinyl alcohol resin film, a polarizer obtained by dissolving or dispersing a dichroic dye having absorption in a near infrared range in a liquid crystal composition to form an alignment state and immobilizing the alignment state, a polarizer obtained by polyene formation with an iodine polarizing plate, a polarizer obtained by application of a wire grid, a reflective polarizer formed of a cholesteric liquid crystal or a dielectric multi-layer film, and a polarizer having a surface microstructure such as a metasurface. From the viewpoint that the productivity in a thin film is excellent and the patterning accuracy is high, a polarizer obtained by dissolving or dispersing a dichroic dye having absorption in a near infrared range in a liquid crystal composition to form an alignment state and immobilizing the alignment state is preferable.

In the layer having polarization selectivity, a single plate transmittance at a wavelength of 850 nm in the region having polarization selectivity is preferably less than 50% and more preferably less than 47%. In addition, likewise, a single plate transmittance at a wavelength of 950 nm is preferably less than 55%, more preferably less than 50%, and still more preferably less than 47%.

In addition, in a case where the polarization degree is measurable, P(850) is preferably 0.80 or more, more preferably 0.85 or more, still more preferably 0.90 or more, and still more preferably 0.95 or more. In addition, P(950) is preferably 0.80 or more, more preferably 0.85 or more, still more preferably 0.90 or more, and still more preferably 0.95 or more. The upper limits of P(850) and P(950) are theoretically 1.00 and are in a range of less than 1.00 in practice.

Liquid Crystal Composition

As the liquid crystal composition, any composition can be used without any particular limitation as long as it includes a polymerizable liquid crystal compound, the polymerizable liquid crystal compound can be made to enter an alignment state, and the alignment can be immobilized by heating, cooling, or a polymerization reaction. As a specific example of the present invention, the liquid crystal composition includes a polymerizable liquid crystal compound and a dichroic dye having absorption in a near infrared range and optionally may further include other components.

Polymerizable Liquid Crystal Compound

As the polymerizable liquid crystal compound in the liquid crystal composition, any one of a polymer polymerizable liquid crystal compound or a low molecular weight polymerizable liquid crystal compound can be used, and it is preferable to use a polymer polymerizable liquid crystal compound from the viewpoint that the alignment degree can be increased.

Here, “polymer polymerizable liquid crystal compound” refers to a polymerizable liquid crystal compound including a repeating unit in a chemical structure.

In addition, “low molecular weight polymerizable liquid crystal compound” refers to a polymerizable liquid crystal compound not including a repeating unit in a chemical structure.

In addition, as the polymerizable liquid crystal compound, the polymer polymerizable liquid crystal compound and the low-molecular-weight polymerizable liquid crystal compound may be used in combination.

The low molecular weight polymerizable liquid crystal compound can be found in, for example, paragraphs “0042” to “0053” of WO2019/235355A.

Dichroic Coloring Agent Compound

A dichroic coloring agent compound having absorption in a near infrared range that is used for the patterned polarizer according to the embodiment of the present invention is not particularly limited, and examples thereof include a visible light absorbing material (dichroic coloring agent), a light emitting material (a fluorescent material or a phosphorescent material), an ultraviolet absorbing material, an infrared absorbing material, a nonlinear optical material, carbon nanotubes, and an inorganic material (for example, a quantum rod). A well-known dichroic coloring agent compound (dichroic coloring agent) in the related art can be used.

Other Components

As the other components, a solvent, a leveling agent, a polymerization initiator, and other additives can be included.

The solvent is not particularly limited as long as it can dissolve a liquid crystal compound and the dichroic coloring agent. In addition, from the viewpoint of manufacturing suitability, a solvent having a boiling point of 40° C. to 150° C. is preferably used. Specifically, a ketone (in particular, cyclopentanone or cyclohexanone), an ether (in particular, tetrahydrofuran, cyclopentyl methyl ether, tetrahydropyran, or dioxolane), or an amide (in particular, dimethylformamide, dimethylacetamide, N-methylpyrrolidone, or N-ethylpyrrolidone) is preferable.

The polymerization initiator is not particularly limited and is preferably a compound having photosensitivity, that is, a photopolymerization initiator.

As the photopolymerization initiator, various compounds can be used without any particular limitation. Examples of the photopolymerization initiator include an α-carbonyl compound (described in U.S. Pat. Nos. 2,367,661A and 2,367,670A), an acyloin ether (described in U.S. Pat. No. 2,448,828A), an α-hydrocarbon-substituted aromatic acyloin compound (described in U.S. Pat. No. 2,722,512A), a polynuclear quinone compound (described in U.S. Pat. Nos. 3,046,127A and 2,951,758A), a combination of a triaryl imidazole dimer and p-aminophenyl ketone (described in U.S. Pat. No. 3,549,367A), an acridine compound and a phenazine compound (described in JP1985-105667A (JP-S60-105667A) and U.S. Pat. No. 4,239,850A), an oxadiazole compound (described in U.S. Pat. No. 4,212,970A), an o-acyloxime compound (paragraph “0065” of JP2016-27384A), and an acylphosphine oxide compound (described in JP1988-40799B (JP-S63-40799B), JP1993-29234B (JP-H5-29234B), JP1998-95788A (JP-H10-95788A), and JP1998-29997A (JP-H10-29997A)).

As the photopolymerization initiator, a commercially available product can be used, and examples thereof include IRGACURE-184, IRGACURE 907, IRGACURE 369, IRGACURE 651, IRGACURE 819, IRGACURE OXE-01, and IRGACURE OXE-02 manufactured by BASF SE.

It is preferable that the liquid crystal composition includes a surfactant.

By including the surfactant, the smoothness of the coating surface is further improved, the alignment degree is improved, cissing and unevenness are suppressed, and the effect of improving in-plane uniformity is expected.

As the surfactant, a surfactant that makes the dichroic coloring agent compound and the liquid crystal compound to be parallel to or perpendicular to each other on the coating surface side may be used. For example, a compound described in paragraphs “0155” to “0170” of WO2016/009648A, a compound (horizontal alignment agent) described in paragraphs “0253” to “0293” of JP2011-237513A, or a compound (vertical alignment agent) described in paragraphs “0071” to “0097” of WO2019/235355A can be used.

The thickness of the layer having polarization selectivity is not particularly limited, and the thickness for obtaining a required polarization property may be appropriately set depending on the forming material and the like.

Specifically, the thickness of the layer having polarization selectivity include is preferably 0.1 μm to 5 μm and more preferably 0.3 μm to 2.5 μm. As described below, in a case where the layer having polarization selectivity has a step (thickness distribution), the above-described thickness refers to the thickness of the thickest portion.

Method of Forming Layer Having Polarization Selectivity

A method of forming the layer having polarization selectivity formed of the above-described liquid crystal composition is not particularly limited, and various well-known film forming methods using a composition can be used.

Examples of the method of forming the layer having polarization selectivity include a method including, in the following order: a step of applying the above-described liquid crystal composition to a support to form a coating film; and a step of aligning the liquid crystal compound in the coating film.

In a case where the dichroic coloring agent compound is liquid crystalline, the liquid crystal component is a component including a dichroic coloring agent compound having liquid crystal properties in addition to the above-described liquid crystal compound.

As a method of providing the plurality of regions having different types of polarization selectivity, the regions can be formed in the layer, for example, using a method of controlling the alignment in advance during the formation of the layer. In addition, the regions may be formed, for example, using a method of controlling the alignment to be uniform during the formation of the layer and performing peeling, removal, or the like after the formation of the layer.

For example, by using a support including an alignment film and providing a plurality of regions of the alignment film having different alignment restriction forces in a patterned manner, the plurality of regions having different types of polarization selectivity can be formed. In addition, a photoreactive additive may be added to the liquid crystal composition, alignment may be induced by polarized light irradiation during the formation of an alignment state, and an alignment treatment may be performed to exhibit different types of polarization selectivity for the regions.

In addition, in another example, by using a support including an alignment film and removing or deforming a part of the alignment film, a difference in peeling strength may be made between the regions, and some of the regions may be removed from the layer having polarization selectivity during the peeling and transfer of the layer having polarization selectivity.

Examples of the above-described support include: a polycarbonate polymer; a polyester polymer such as polyethylene terephthalate (PET) or polyethylene naphthalate; an acrylic polymer such as polymethyl methacrylate; a styrene polymer such as polystyrene or an acrylonitrile-styrene copolymer (AS resin); a polyolefin polymer such as polyethylene, polypropylene, or an ethylene-propylene copolymer; a vinyl chloride polymer; an amide polymer such as nylon or an aromatic polyamide; an imide polymer; a sulfonic polymer; a polyethersulfone polymer; a polyether ether ketone polymer; a polyphenylene sulfide polymer; a vinylidene chloride polymer; a vinyl alcohol polymer; a vinyl butyral polymer; an arylate polymer; a polyoxymethylene polymer; and an epoxy polymer.

Examples of the alignment film include a photoalignment layer and a rubbed alignment layer. In particular, from the viewpoint of further improving the effects of the present invention, a photoalignment layer is preferable. Examples of the photoalignment layer include examples described in paragraphs “0018” to “0078” of WO2020/179864A.

By incorporating the above-described patterned polarizer into the image display apparatus according to the embodiment of the present invention, the detection accuracy and the amount of information acquired can be improved. In addition, since the patterned polarizer has a function of integrating a plurality of polarizers, the problem in size, weight, and design can be solved. The image display apparatus including the patterned polarizer according to the embodiment of the present invention and the image display system and the head-mounted display including the image display apparatus are as described above in the first embodiment, the second embodiment, and the third embodiments as the preferable embodiments of the present invention.

### EXPLANATION OF REFERENCES

1, 1a 7, 392: substrate
1b: color filter substrate
2: pixel
2a to 2d: pixel (visible light pixel)
2e: invisible light pixel
3, 121, 261, 322, 391, 432, 472: image display panel (light emitting panel)
4: light receiving section
4b, 9b, 122, 402, 414, 424, 445, 462, 484, 485: near infrared polarizer
4e: imaging element
5: luminous flux (visible flux)
5d: visible flux
6: emission surface (light emission surface)
8: invisible light (near infrared flux)
8a, 8e: near infrared light
8b: incidence light (detection luminous flux)
8c: near infrared light noise
8d: near infrared flux
8f, 8g: linearly polarized light
8h: luminous flux
9, 9e: light source (near infrared light source, light emitting section)
10, 20, 30, 70, 91, 111, 120a, 120b, 120c, 131, 150, 160, 170, 281, 301, 321, 330, 351, 360, 370, 380, 401, 411, 423, 431, 440, 451, 461: image display apparatus (display device)
40, 60, 390: OLED display device
41: OLED unit
41a: organic light emitting layer
41b: upper electrode
41c, 262a, 264a: lower electrode
42: driving unit
42a, 42b: transistor array
43: sensor unit
47: interlayer insulating film
48: interlayer
49, 267, 283, 393: cover plate
71: liquid crystal layer
72: color filter layer
73: surface
74: light guide portion
74a: side surface
79: backlight unit
90, 100, 110, 130, 300, 310, 410: head-mounted display
92, 302, 412: eyepiece
99, 309, 419, 429, 479, 489, 490: eyeball
101, 311, 421: pancake lens
101a, 112, 126, 132, 311a, 421a: half mirror
101b, 311b, 421b: reflective polarizer
113: ¼ wave plate
114: reflective linear polarizer
115: polarizer
123: second retardation plate
124, 151, 161, 331, 341, 441: visible light polarizer
125: first retardation plate
127, 171, 349: patterned polarizer
127a, 171a: near infrared polarizer region
127b, 171b: visible light linear polarizer region
133: circular polarization plate
134: circularly polarized light selectivity reflective polarizer
119, 139: eye
140, 180, 200, 210, 220, 230, 240, 250, 260, 280, 290, 320, 350, 471, 481: image display system
152, 162, 172, 332, 342, 442, 444: retardation plate
155, 446: external light
165: external visible light
171c: visible light transmitting unit
181, 182, 213, 352, 353, 451, 452: measurement target
183, 193, 354, 453: invisible marking
191: first measurement target
192: second measurement target
194: blocked region
211: light guide plate
212: diffraction function layer
214: finger
262b: visible EL light emitting layer
262c, 264c: transparent electrode
262d, 264d: transparent electrode layer
263a, 263d: transistor layer
264b: near infrared EL light emitting layer
265: insulating layer
266a, 266d: colored layer
268: pixel unit
282: OLED panel
284: second substrate
285: circuit layer
288: spacer
349b, 349e, 349f: region
473, 483: light guide element
491: cornea
492: pupil
493: iris

What is claimed is:

1. An image display apparatus comprising:
a light receiving section having sensitivity in an invisible range;
an image display panel that includes a substrate and a plurality of pixels disposed on the substrate; and
an emission surface that emits a luminous flux in a visible range formed from the plurality of pixels,
wherein the light receiving section receives only invisible light in light incident into the image display apparatus through the emission surface,
the light receiving section is provided between the emission surface and the image display panel, on the image display panel, or on a side of the image display panel opposite to the emission surface,
the light receiving section is disposed at a position overlapping the image display panel in a view from a direction perpendicular to the emission surface, and
a near infrared polarizer having polarization selectivity in a near infrared range is provided between the light receiving section and the emission surface.

2. The image display apparatus according to claim 1,
wherein the light receiving section has sensitivity in a near infrared range.

3. The image display apparatus according to claim 1,
wherein the light receiving section receives invisible light reflected from a detection target, and
as the target detected by the light receiving section, the light receiving section detects a three-dimensional shape of an object, a surface state of the object, and at least one selected from an eye movement, an eye position, a facial expression, a face shape, a vein pattern, a blood flow, a pulse, a blood oxygen saturation level, a fingerprint, or an iris of a user.

4. The image display apparatus according to of claim 1,
wherein in the near infrared polarizer having polarization selectivity in a near infrared range, a single plate transmittance at a wavelength of 850 nm is less than 55%.

5. A head-mounted display comprising:
the image display apparatus according to claim 1;
an eyepiece that is disposed between the image display apparatus and an eyeball of an observer,
a light source that is capable of emitting near infrared light to the eyeball; and
an eye tracking system that detects reflected light obtained by causing the near infrared light emitted from the light source to be reflected from the eyeball using the light receiving section through the near infrared polarizer.

6. The head-mounted display according to claim 5,
wherein the eyepiece has near infrared transmittance.

7. The head-mounted display according to claim 5,
wherein the eyepiece includes a half mirror having near infrared transmittance and a reflective polarizer having near infrared transmittance.

8. The head-mounted display according to claim 5, further comprising:
a visible light polarizer that has a polarization property in visible light and is provided between the eyepiece and the plurality of pixels of the image display apparatus,
wherein the visible light polarizer has transmittance in a near infrared range.

9. The head-mounted display according to claim 5,
wherein the near infrared polarizer does not have a polarization property in a visible range or has transmittance in a visible range.

10. The head-mounted display according to claim 5,
wherein the near infrared polarizer is a patterned polarizer including a near infrared polarizer region having polarization selectivity to near infrared light and a visible light linear polarizer region having polarization selectivity to visible light in the same plane.

11. The head-mounted display according to claim 9,
wherein in the near infrared polarizer region having polarization selectivity to near infrared light, a single plate transmittance at a wavelength of 850 nm is less than 55%.

12. An image display system comprising:
the image display apparatus according to claim 1;
a light source that is capable of emitting near infrared light to a face of a user; and
a face recognition system or a facial expression recognition system that detects reflected light obtained by causing the near infrared light emitted from the light source to be reflected from a face of an observer using the light receiving section through the near infrared polarizer.

13. The image display system according to claim 12,
wherein the image display panel includes an OLED display panel and a light emitting panel selected from a LED array, a micro LED panel, or a mini LED panel,
the image display apparatus includes a circular polarization plate that is provided on the emission surface to reduce external light reflection,
the circular polarization plate is a laminate in which a visible light polarizer and a retardation plate are laminated, and
the image display apparatus includes the visible light polarizer, the retardation plate, and the substrate in this order from the emission surface to the substrate.

14. The image display system according to claim 13,
wherein the near infrared polarizer is provided between the visible light polarizer and the retardation plate,
the near infrared polarizer has transmittance in a visible range, and
a laminate including the retardation plate and the near infrared polarizer has an action of a ¼ wave plate with respect to light having a wavelength of 550 nm.

15. The image display system according to claim 14,
wherein a transmission axis of the near infrared polarizer is disposed parallel to or perpendicular to a transmission axis of the visible light polarizer, or
the transmission axis of the near infrared polarizer is disposed at 45° or 135° with respect to the transmission axis of the visible light polarizer and a phase difference Re(550) of the near infrared polarizer in a visible range is ½ wavelength.

16. The image display system according to claim 14,
wherein a transmission axis of the near infrared polarizer is at 75°±10° with respect to a transmission axis of the visible light polarizer and a phase difference Re(550) of the near infrared polarizer in a visible range is in a range from 180 nm to 360 nm, and
a slow axis of the retardation plate is at 15°±10° with respect to a transmission axis of the visible light polarizer and a phase difference Re(550) of the retardation plate is in a range from 115 nm to 155 nm.

17. The image display system according to claim 13,
wherein the visible light polarizer, the retardation plate, and the near infrared polarizer are provided in this order,
the near infrared polarizer has transmittance in a visible range,
a slow axis of the retardation plate is at 75°±10° with respect to a transmission axis of the visible light polarizer,
a phase difference Re(550) of the retardation plate is in a range from 180 nm to 360 nm,
a slow axis of the near infrared polarizer is at 15°±10° with respect to the transmission axis of the visible light polarizer, and
a phase difference Re(550) of the near infrared polarizer in a visible range is in a range from 115 nm to 155 nm.

18. An image display system comprising:
the image display apparatus according to claim 1;
a light source that is capable of emitting near infrared light to a measurement target; and
a distance measurement system or an object recognition system that detects reflected light obtained by causing the near infrared light emitted from the light source to be reflected from the measurement target using the light receiving section through the near infrared polarizer.

19. The image display system according to claim 18,
wherein the image display panel includes an OLED display panel and a light emitting panel selected from a LED array, a micro LED panel, or a mini LED panel,
the image display apparatus includes a circular polarization plate that is provided on the emission surface to reduce external light reflection,
the circular polarization plate is a laminate in which a visible light polarizer and a retardation plate are laminated, and
the image display apparatus includes the visible light polarizer, the retardation plate, and the substrate in this order from the emission surface to the substrate.

20. The image display system according to claim 19,
wherein the near infrared polarizer is provided between the visible light polarizer and the retardation plate,
the near infrared polarizer has transmittance in a visible range, and
a laminate including the retardation plate and the near infrared polarizer has an action of a ¼ wave plate with respect to light having a wavelength of 550 nm.

21. The image display system according to claim 20,
wherein a transmission axis of the near infrared polarizer is disposed parallel to or perpendicular to a transmission axis of the visible light polarizer, or
the transmission axis of the near infrared polarizer is disposed at 45° or 135° with respect to the transmission axis of the visible light polarizer and a phase difference Re(550) of the near infrared polarizer in a visible range is ½ wavelength.

22. An image display system comprising:
the image display apparatus according to claim 1;
a light source that is capable of emitting near infrared light to a portion of a biological body selected from a hand, a finger, a palm, or a skin; and
a fingerprint recognition system, a vein recognition system, or a biometric system that detects reflected light obtained by causing the near infrared light emitted from the light source to be reflected from the portion of the biological body selected from a hand, a finger, a palm, or a skin using the light receiving section through the near infrared polarizer.

23. The image display system according to claim 22, further comprising:
a light guide plate that guides the near infrared light emitted from the light source; and
a fingerprint recognition system that detects scattered near infrared light obtained by causing the near infrared light propagating in the light guide plate to be scattered from an interface between a finger and the light guide plate, using the light receiving section.

24. The image display system according to claim 22, further comprising:
a light guide plate that guides the near infrared light emitted from the light source,
wherein the light guide plate is provided with a scattering layer or a diffraction function layer and includes a vein recognition system or a biometric system that emits a part of the guided near infrared light from the emission surface to a measurement target and receives reflected light from the measurement target using the light receiving section.

25. An image display system comprising:
a light receiving section having sensitivity in an invisible range; and
an image display apparatus including an image display panel and an emission surface, the image display panel including a substrate and a plurality of pixels, and the emission surface emitting a luminous flux formed from the plurality of pixels,
wherein the plurality of pixels include a pixel group that forms a luminous flux in a visible range and a pixel that forms a luminous flux in an invisible range to which the light receiving section has sensitivity,
the plurality of pixels are disposed at positions overlapping the substrate in a view from a direction perpendicular to the emission surface,
the light receiving section is disposed to receive the invisible light that is emitted from the pixel forming the luminous flux in an invisible range to a detection target through the emission surface and is reflected or scattered from the target, and receives only the luminous flux in an invisible range, and
the image display apparatus includes a near infrared polarizer having polarization selectivity in a near infrared range that is provided between the pixel forming the luminous flux in an invisible range and the emission surface.

26. The image display system according to claim 25,
wherein the light receiving section has sensitivity in a near infrared range.

27. The image display system according to claim 25,
wherein the light receiving section receives invisible light reflected from a detection target, and
as the target detected by the light receiving section, the light receiving section detects a three-dimensional shape of an object, a surface state of the object, and at least one selected from an eye movement, an eye position, a facial expression, a face shape, a vein pattern, a blood flow, a pulse, a blood oxygen saturation level, a fingerprint, or an iris of a user.

28. The image display system according to claim 25,
wherein in the near infrared polarizer having polarization selectivity in a near infrared range, a single plate transmittance at a wavelength of 850 nm is less than 55%.

29. The image display system according to claim 25,
wherein the near infrared polarizer does not have a polarization property in a visible range or has transmittance in a visible range.

30. Ahead-mounted display comprising:
the image display system according to claim 25;
an eyepiece; and
an eye tracking system that detects near infrared light emitted from the image display apparatus an eyeball of an observer and reflected from the eyeball using the light receiving section.

31. The head-mounted display according to claim 30,
wherein the eyepiece includes a half mirror and a reflective polarizer.

32. The head-mounted display according to claim 31,
wherein a single plate transmittance of each of the reflective polarizer and the half mirror at 850 nm is 80% or more.

33. The head-mounted display according to claim 30, further comprising:
a near infrared polarizer that is provided on an eyeball side surface of the eyepiece,
wherein a single plate transmittance of the near infrared polarizer at 850 nm is less than 55%.

34. The image display system according to claim 25, further comprising:
a face recognition system or a facial expression recognition system that detects reflected light obtained by causing a luminous flux in a near infrared range emitted from the image display apparatus to be reflected from a face of a user using the light receiving section.

35. The image display system according to claim 25,
wherein the image display apparatus includes the near infrared polarizer, a visible light polarizer, and a retardation plate as a ¼ wave plate having a slow axis that is 45° or 135° with respect to a transmission axis of the visible light polarizer in this order from the emission surface to the substrate.

36. The image display system according to claim 35,
wherein the near infrared polarizer is a patterned polarizer where regions having different transmission axes are distributed in a patterned manner.

37. The image display system according to claim 25, further comprising:
a light detection and ranging system or an object recognition system that detects reflected light obtained by causing invisible light emitted from the image display apparatus to be reflected from a measurement target using the light receiving section.

38. The image display system according to claim 37,
wherein the image display apparatus includes the near infrared polarizer, a visible light polarizer, and a retardation plate as a ¼ wave plate having a slow axis that is 45° or 135° with respect to a transmission axis of the visible light polarizer in this order from the emission surface to the substrate.

39. The image display system according to claim 38,
wherein the near infrared polarizer is a patterned polarizer where regions having different transmission axes are distributed in a patterned manner.

40. A head-mounted display comprising:
the image display system according to claim 25,
wherein the image display apparatus includes a light guide element and emits the luminous flux in a visible range and the luminous flux in an invisible range emitted from the image display panel to an observer from an emission surface provided in the light guide element through the light guide element, and
eyeball sensing is performed by detecting near infrared light emitted from the image display apparatus to an eyeball of the observer and reflected from the eyeball of the observer using the light receiving section.

41. The head-mounted display according to claim 40, further comprising:
near infrared polarizers that are provided between the emission surface of the light guide element and the eyeball of the observer and between the light receiving section and the eyeball of the observer, respectively.

42. The head-mounted display according to claim 41,
wherein in the near infrared polarizer that is provided between the emission surface of the light guide element and the eyeball of the observer among the near infrared polarizers, an average transmittance of the near infrared polarizer in a visible range is 90% or more.

43. The head-mounted display according to claim 41,
wherein in the near infrared polarizer that is provided between the emission surface of the light guide element and the eyeball of the observer among the near infrared polarizers, a polarization degree of the near infrared polarizer at 850 nm is 90% or more.

44. The head-mounted display according to claim 41,
wherein in the near infrared polarizer that is provided between the light receiving section and the eyeball of the observer among the near infrared polarizers, a polarization degree of the near infrared polarizer at 850 nm is 90% or more.

45. The head-mounted display according to claim 41,
wherein in a case where an eyeball surface is a reflecting surface, the near infrared polarizer provided between the emission surface of the light guide element and the eyeball of the observer and the near infrared polarizer provided between the light receiving section and the eyeball of the observer are disposed in a crossed nicols relationship.

46. An image display apparatus comprising:
a light receiving section having sensitivity in an invisible range;
an image display panel including a substrate and a plurality of pixels; and
an emission surface that emits a luminous flux in a visible range formed from the plurality of pixels,
wherein the light receiving section is provided between the emission surface and the image display panel, on the image display panel, or on a side of the image display panel opposite to the emission surface,
the plurality of pixels include a pixel group that forms a luminous flux in a visible range and a pixel that forms a luminous flux in an invisible range to which the light receiving section has sensitivity,
the light receiving section is disposed at a position overlapping the image display panel in a view from a direction perpendicular to the emission surface,
the light receiving section receives only invisible light in light incident into the image display apparatus through the emission surface, and
a near infrared polarizer having polarization selectivity in a near infrared range is provided between the pixel forming the luminous flux in an invisible range and the emission surface.

47. The image display apparatus according to claim 46,
wherein the pixel that forms the luminous flux of invisible light has an emission band in near infrared light,
the light receiving section has sensitivity to near infrared light, and
the pixel group that forms the luminous flux of visible light performs image display.

48. The image display apparatus according to claim 46,
wherein a single plate transmittance of the near infrared polarizer at 850 nm is less than 55%.

49. The image display apparatus according to claim 46,
wherein the near infrared polarizer does not have a polarization property in a visible range or has transmittance in a visible range.

50. A head-mounted display comprising:
the image display apparatus according to claim 46; and
an eyepiece,
wherein eye tracking is performed by performing emission of near infrared light to an eyeball and detection of the near infrared light using the image display apparatus.

51. The head-mounted display according to claim 50,
wherein the near infrared polarizer is a patterned polarizer where regions having different transmission axes or different types of polarization selectivity for corresponding pixels are disposed in a patterned manner.

52. The head-mounted display according to claim 50,
wherein the eyepiece includes a half mirror and a reflective polarizer.

53. The head-mounted display according to claim 52,
wherein the reflective polarizer and the half mirror have transmittance in a near infrared range, and
a single plate transmittance of each of the reflective polarizer and the half mirror at 850 nm is 80% or more.

54. The image display apparatus according to claim 46, which is used as a face recognition system or a facial expression recognition system that detects reflected light obtained by causing the invisible light emitted from the pixel forming the luminous flux of invisible light to be reflected from a user a face of a user using the light receiving section.

55. The image display apparatus according to claim 54,
wherein the near infrared polarizer is a patterned polarizer where regions having different transmission axes are distributed in a patterned manner.

56. The image display apparatus according to claim 46, further comprising:
a light detection and ranging system or an object recognition system that detects reflected light obtained by causing invisible light emitted from the image display apparatus to be reflected from a measurement target using the light receiving section.

57. The image display apparatus according to claim 56,
wherein a patterned polarizer where regions having different transmission axes are distributed in a patterned manner is provided as the near infrared polarizer.

58. The image display apparatus according to claim 46, which is used as any one of a fingerprint sensor, a vein recognition system, or a blood flow sensor that detects light obtained by causing invisible light emitted from the image display apparatus to transmit through or to be reflected from a portion of a biological body of a user selected from a hand, a finger, a palm, or a skin using the light receiving section through the near infrared polarizer.

59. The image display apparatus according to claim 58,
wherein the near infrared polarizer is a patterned polarizer including a plurality of regions having different types of polarization selectivity in a patterned manner.

60. A patterned polarizer comprising:
a layer having polarization selectivity to light in a near infrared range,
wherein the layer includes at least a region having polarization selectivity in a near infrared range, and
the layer includes a plurality of regions having different types of polarization selectivity in a near infrared range in a patterned manner in a plane.

61. The patterned polarizer according to claim 60,
wherein the patterned polarizer has a structure selected from at least one of
a patterned polarizer where a first region having a first polarization selectivity and a second region not having polarization selectivity that is provided to be surrounded by the region having the first polarization selectivity are provided in a plane of the layer having polarization selectivity or
a patterned polarizer where a first region having at least a first polarization selectivity and a second region having a second polarization selectivity are provided in a plane of the layer having polarization selectivity.

62. The patterned polarizer according to claim 60,
wherein in the region having polarization selectivity, a single plate transmittance at a wavelength of 850 nm is less than 50%.

63. The patterned polarizer according to claim 60,
wherein a thickness of the layer having polarization selectivity in a near infrared range is 0.1 μm to 5 μm.

64. The patterned polarizer according to claim 60,
wherein the layer having polarization selectivity in a near infrared range is obtained by dissolving or dispersing a dichroic dye having absorption in a near infrared range in a liquid crystal composition to form an alignment state and immobilizing the alignment state.
